(19) United States
(12) Patent Application Publication
(10) Pub. No.: US 2005/0002474 A1
(43) Pub. Date: Jan. 6, 2005

(54) PAM radio signal receiver with phase-tracker succeeding adaptive FIR filtering and preceding adaptive IIR filtering

(76) Inventor: Allen LeRoy Limberg, Vienna, VA (US)

Correspondence Address: Allen LeRoy Limberg, 2500 Lakevale Drive, Vienna, VA, 22181-4028, US

(21) Appl. No.: 10/351,886

(22) Filed: Jan. 27, 2003

(51) Int. Cl. H03D 1/24

(52) U.S. Cl. 375/321; 375/232

(57) ABSTRACT

A PAM receiver for reproducing a baseband signal that symbol codes digital data is combined with an decision-feedback equalizer (DFE) incorporating first adaptive digital filtering as a feed-forward element and second adaptive digital filtering as a feedback element. The DFE response is supplied to symbol decoding circuitry for reproducing the digital data. A de-rotator re-samples the first adaptive digital filtering response before it is combined with the second adaptive digital filtering response to generate an equalizer response. The resulting baud-rate equalizer response is sampled at baud rate and quantized to generate baud-rate decisions that applied to the second adaptive digital filtering as input signal, for completing the decision-feedback loop. The re-sampling of the first adaptive digital filtering response by the de-rotator is controlled, so as to provide a phase-tracker that reduces phase noise and intersymbol interference, prior to the making of decisions for decision feedback.

The invention relates to adaptive equalization filtering in receivers for pulse-amplitude-modulation (PAM) radio signals subject to changing multipath distortion, such as receivers for vestigial-sideband amplitude-modulation (VSB AM) radio signals employed for digital television (DFTV) broadcasting.

### BACKGROUND OF THE INVENTION

DTV broadcasting in the United States of America bas been done in accordance with the ATSC Digital Television Standard published by the Advanced Television Systems Committee (ATSC) in September 1995 as Document A/53 and referred to simply as “A/53”. The construction of receivers for receiving DTV broadcast transmissions is described in Guide to the Use of the ATSC Digital Television Standard published ATSC in October 1995 as Document A/54 and referred to simply as “A/54”.

Customarily, the adaptive equalization filtering for a DTV receiver is digital filtering performed at baseband after the VSB AM signals are demodulated. The adaptive equalization filtering is done for suppressing multipath responses in the received signal, which multipath responses arrive via various-length transmission paths with varying amounts of attenuation. The digital filtering weights the baseband demodulation result as variously delayed and then combines the weighting results, so as to select a stronger principal one of the multipath responses that arrives via a transmission path relatively free of attenuation. The resulting equalizer response better corresponds to the modulating signal sent by the transmitter than does the baseband demodulation result supplied to the adaptive equalization filtering as its input signal. The weighting of each of the variously delayed responses that are combined to generate the equalizer response is carried forward by digital multiplication. Read-only memory can be used to implement the digital multiplications in order to achieve faster multiplication speed.

Multipath responses (or “echoes”) that precede the principal response in the received signal are referred to as “pre-echoes”, and multipath responses that succeed the principal response in the received signal are referred to as “post-echoes”. The use of finite-impulse-response (FIR) adaptive equalization filtering to suppress echoes generates “repeat echoes” with greater differential delay respective to the principal response and with reduced amplitude respective to the original echoes giving rise to them. Each repeat echo arises because the original echo is suppressed using the full spectrum of the filter input signal as differentially delayed respective to the principal response, rather than using just differentially delayed principal response. Each repeat echo of significant energy requires further respective digital multiplication for its suppression and give rise to a still further repeat echo. Infinite-impulse-response (IIR) adaptive equalization filtering is preferred for suppressing substantial delayed post-echoes. Such recursive filtering reduces the generation of “repeat echoes” because the original post-echo is suppressed using the response of the IIR adaptive equalization filtering, rather than using the full spectrum of the filter input signal. It is customary to cascade the IIR filtering used for suppressing substantially delayed post echoes after FIR filtering used for suppressing pre-echoes and short-delay post-echoes, to facilitate decision-feedback equalization (DFE) being used instead of linear-feedback equation (LFE). This preceding FIR filtering suppresses pre-echoes in the response of the subsequent IIR adaptive equalization filtering, which further reduces the generation of “repeat echoes” in the IIR filtering.

The VSB AM employed in DTV broadcasting is PAM of such a nature that the complex-quantity baseband demodulation results from synchronously detecting the VSB AM signal in two mutually orthogonal carrier phasings can be combined in a de-rotating procedure to generate a real-only baseband demodulation result. In some prior-art designs the de-rotation procedure is performed before real-only baseband equalization is performed. In other prior-art designs the de-rotation procedure is performed after baseband equalization of the complex-quantity baseband demodulation results is completed. In either case an equalized real-only baseband signal is provided to the symbol decoding circuitry, which in a DTV receiver comprises a trellis decoder, a data de-interleaver, a Reed-Solomon error correction circuit and a de-randomizer.

A design strategy that has been commonly used to reduce the amount of digital multiplication in the adaptive equalization filtering is to use a form of equalization known as “synchronous equalization”. The adaptive weighting coefficients in the kernel of a synchronous equalizer are located at successive taps spaced at symbol-epoch intervals. In accordance with the Sampling Theorem, this spaces the taps so as to avoid severe intersymbol interference (ISI). In the early prior art, synchronous equalization was implemented in a digital filter that is clocked at baud rate, with the real-only baseband demodulation result being decimated to baud rate before its application to that filter as input signal. Such a digital filter has no “excess” bandwidth extending beyond tie Nyquist minimum bandwidth required sampling a PAM signal of prescribed baud rate, and the frequencies above half baud rate are aliased, introducing intersymbol interference (ISI).

A procedure known as “fractional equalization” provides an equalizer response that has “excess” bandwidth that avoids the aliasing of frequencies above one-half baud rate. In fractional equalization the input signal to the equalizer is over-sampled, so there is more than one sample per symbol epoch. Fractional equalization in which the input signal to the equalizer is sampled at twice baud rate supports procedures for symbol synchronization of pulse-amplitude-modulation signals, which procedures are of the type S. U. H. Qureshi describes in his paper “Timing Recovery for Equalized Partial-Response Systems” published December 1976 in IEEE Transactions on Communications, pp. 1326-1330. In a Qureshi type of symbol synchronization procedure, a set of odd alternate samples of signal has the absolute values of their departures from the closest of the prescribed symbol values that might have been transmitted subjected to lowpass filtering procedure. A set of even alternate samples of signal has the absolute values of their departures from the closest of prescribed symbol values that might have been transmitted subjected to a similar lowpass filtering procedure. The difference between the lowpass filtering results is indicative of the error in symbol synchronization and is used for degenerating that error. The conventional adaptive fractional equalizer sampling at twice baud rate has weighting coefficients for both the odd and even sets of alternate samples of equalizer input signal, double the number of weighting coefficients in a synchronous equalizer for suppressing the same range of echoes.

A. L. R. Limberg and C. B. Patel describe adaptive fractional equalization procedures in detail in U.S. Pat. No. 6,377,312 issued 23 Apr. 2002 and titled “ADAPTIVE FRACTIONALLY SPACED EQUALIZER FOR RECEIVED RADIO TRANSMISSIONS WITH DIGITAL CONTENT, SUCH AS DTV SIGNIALS”. This patent finds fault with a previous method of adapting the weighting coefficients of fractional equalizers using DFE. This previous method measured reception errors by comparing fractional equalizer response as decimated to baud rate with data-slicer response to that decimated fractional equalizer response. The weighting coefficients were computed for a synchronous equalizer and then expanded by interpolation to determine weighting coefficients for the supposedly fractional equalizer. This procedure does not determine the weighting coefficients for the fractional equalizer independently of each other, so the adaptation procedure compromises the performance possible from an actually fractional equalizer. U.S. Pat. No. 6,377,3124 indicates that loss in bandwidth in measuring reception errors is avoided by re-sampling the data-slicer response to the clock-through rate of the fractional equalizer and comparing the re-sampled data-slicer response with the undecimated fractional equalizer response. The resulting error measurements have the bandwidth required for determining the weighting coefficients for the fractional equalizer independently of each other, so true fractional equalizer operation is obtained.

A problem in DTV receiver design is impairment of the signal-to-noise ratio (SNR) of received DTV signals caused by phase noise or symbol jitter. Generally, a major contributor to phase noise is the tuned first local oscillator used in the first conversion process in the DTV receiver. This process supplies a first intermediate-frequency (1^{st} IF) DTV signal in selective response to a radio-frequency (RF) DTV transmitted over one of a number of DTV broadcast channels in different portions of the RF spectrum. In DTV receiver designs for the consumer market, it is generally too expensive to select amongst a plurality of crystal-controlled first local oscillators for implementing the first conversion process. Generally, the first local oscillators are tuned LC oscillators, which because of lower Q than crystal oscillators are prone to phase noise. Usually these LC oscillators are not continuously tuned, but use switched-reactance tuning. Since in certain areas of the country the carrier frequencies of DTV signals depart from nominal values to avoid adjacent-channel interference problems, these LC oscillators are likely to use automatic fine tuning (AFT) in which a varacter diode adjusts the reactance timing. Additional phase noise can be introduced by such AFT arrangements. Phase noise is also generated when dynamic multipath signals are received. The speed at which an adaptive equalizer adjusts its weighting coefficients is too slow to degenerate phase noise except at frequencies less than one or two hundred hertz.

The SNR of received DTV signals can also be impaired by amplitude noise. When weak DTV signals are received, the primary source of amplitude noise may be Johnson noise or the thermal noise generated within the receiver components themselves with the noise from the early receiver stages being highly amplified together with the weakly received DTV signal. When stronger DTV signals are received, amplitude noise is generally significantly reduced, but phase noise is not. When stronger DTV signals are received a that are reasonably free of accompanying multipath, phase noise is not a problem with 8VSB modulation. However, pronounced multipath conditions can decrease the eye opening for data-slicing, so that phase noise causes a significant number of decision errors in the data-slicing procedure for 8VSB modulation.

A/54 describes the use of a de-rotator following a synchronous baseband equalizer in the DTV receiver, which de-rotator is used as a phase-tracker for degenerating phase noise at frequencies up to tens of kilohertz. U.S. Pat. No. 5,406,587 issued 11 Apr. 1995 to T. P. Horwitz et alii and titled “Error Tracking Loop” further describes this phase-tracker and its connection following an equalizer. U.S. Pat. No. 5,533,071 issued 2 Jul. 1996 to G. Krishnamurthy et alii and titled “Error Tracking Loop Incorporating Simplified Cosine Look-up Table” discloses another variant of this phase-tracker, also connected to follow an equalizer.

A basic concern in the IIR filtering used for suppressing post-echoes is to reduce delay in the recursion path(s) so that shorter-delay post-echoes can be suppressed. The circuitry for making the decisions fed back in a decision-feedback equalizer (DFE) should make these decisions in as short a time as possible to avoid such delay. The properties of trellis coding are exploited for making decisions within one sample epoch or less in a “smart” data-slicer described in U.S. Pat. No. 6,178,209 issued 19 Jun. 1998 to S. N. Hulyalkar et alii and titled “Method of Estimating Trellis Encoded Symbols Utilizing Simplified Trellis Decoding”.

A phase-tracker connected following a decision-feedback equalizer (DFE) does not suppress phase noise before the decisions are made that are fed back for suppressing post-echoes. Each of the phase-trackers described in U.S. Pat. Nos. 5,40,587 and 5,533,071 exhibits substantial latent delay because of the phase-splitting filtering used in their construction for converting real-only equalizer response to complex baseband signal used in de-rotation. This many-symbol-epoch latent delay makes the inclusion of the phase-tracker in the DFE feedback connection unfeasible.

Insertion of a phase-tracker before the DFE is also unfeasible because the signal for controlling de-rotation is not available until after the DFE. The inclusion of the DFE in the feedback-loop for controlling de-rotation introduces a many-symbol-epoch delay into that loop, undesirably requiring the loop frequency response to be curtailed in order to avoid instability.

The invention disclosed in this specification is based on the insight that the phase-tracker can be located before the IIR filtering used for implementing decision-feedback in the equalizer, but after the feed-forward FIR filter used for suppressing pre-echoes. Insertion of a phase-tracker before the DFE would be feasible if the problem of closing the feedback loop for controlling de-rotation could be solved. The order of arrangement of the phase-tracker and the feed-forward FIR filter in their cascade connection with each other does not affect the overall response of that cascade connection. Re-positioning the phase-tracker to follow the feed-forward FIR filter in their cascade connection with each other shortens the feedback loop for controlling de-rotation by removing the feed-forward FIR filter from that loop. The phase-splitting filtering used in construction of the phase-tracker is not included in the recursion paths of the IIR filtering used for implementing decision-feedback in the equalizer. This insight into the proper arrangement of the phase-tracker and the feed-forward FIR filter in their cascade connection with each other changed the nature of the inventive problem. The problem was changed to one closing the control loop of the phase-tracker.

### SUMMARY OF THE INVENTION

The invention is embodied in the combination of a PAM receiver for reproducing a baseband signal that symbol codes digital data, an improved decision-feedback equalizer (DFE), and circuitry for decoding the digital data from the DFE response to the baseband signal. The DFE incorporates first adaptive digital filtering as a feed-forward element and second adaptive digital filtering as a feedback element. Preferably, the first adaptive digital filtering and the second adaptive digital filtering operate at a clock rate that is twice the baud rate of the pulse-amplitude-modulation (PAM) signal being received. A primary distinguishing feature of the invention is a de-rotator that re-samples the first adaptive digital filtering response before it is combined with the second adaptive digital filtering response to generate an equalizer response. The equalizer response is sampled at baud rate and quantized to generate decision feedback signal. The decision feedback signal is sampled at the clocking rate of the second adaptive digital filtering and applied as input signal to the second adaptive digital filtering, completing the decision-feedback loop. The re-sampling of the first adaptive digital filtering response by the de-rotator is controlled by the equalizer response so as to provide a phase-tracker for reducing intersymbol interference (ISI) and phase noise prior to the making of decisions for decision feedback. This is done, while avoiding the introduction of appreciable delay into the decision feedback loop.

### BRIEF DESCRIPTION OF THE DRAWING

FIG. 1 is a schematic diagram of a receiver for pulse-amplitude-modulated (PAM) radio-frequency signals, which receiver includes adaptive digital filtering for providing fractional equalization of baseband digital modulation in accordance with the invention.

FIG. 2 is a schematic diagram showing detailed construction of phase-tracker circuitry suitable for inclusion within the adaptive digital filtering of the FIG. 1 receiver in accordance with the invention.

FIG. 3 is a schematic diagram showing details of the FIG. 1 receiver including the FIG. 2 phase-tracker, and further showing of a modification that is made to that receiver in certain embodiments of the invention.

FIG. 4 is a schematic diagram showing further detail of the FIG. 3 modification.

FIG. 5 is a schematic diagram showing details of a modification that in certain embodiments of the invention is made to the FIG. 1 receiver including the FIG. 2 phase-tracker.

FIG. 6 is a schematic diagram of a portion of a receiver that embodies the invention and that is a modification of the FIG. 1 receiver for PAM radio-frequency signals insofar as the phase-tracker shown in detail in FIG. 2 is concerned.

FIG. 7 is a schematic diagram of a portion of a receiver that embodies the invention and that is a modification of the FIG. 6 receiver operated at lower sampling rate.

FIG. 8 is a schematic diagram of slave phase-trackers used with the FIG. 6 and the FIG. 7 portions of receivers.

FIG. 9 is a schematic diagram of a phase-tracker modification that is made to the FIG. 1 receiver for PAM radio-frequency signals in another embodiment of the invention.

FIGS. 10 through 24 are schematic diagrams showing details of circuitry that is included in the FIG. 9 phase-tracker modification of the FIG. 1 receiver.

FIG. 25 is a schematic diagram of a slave phase-tracker used with the FIG. 1 receiver modified per FIG. 9.

FIGS. 26 through 40 are schematic diagrams showing details of further circuitry that can also be included in the FIG. 9 phase-tracker modification of the FIG. 1 receiver.

### DETAILED DESCRIPTION

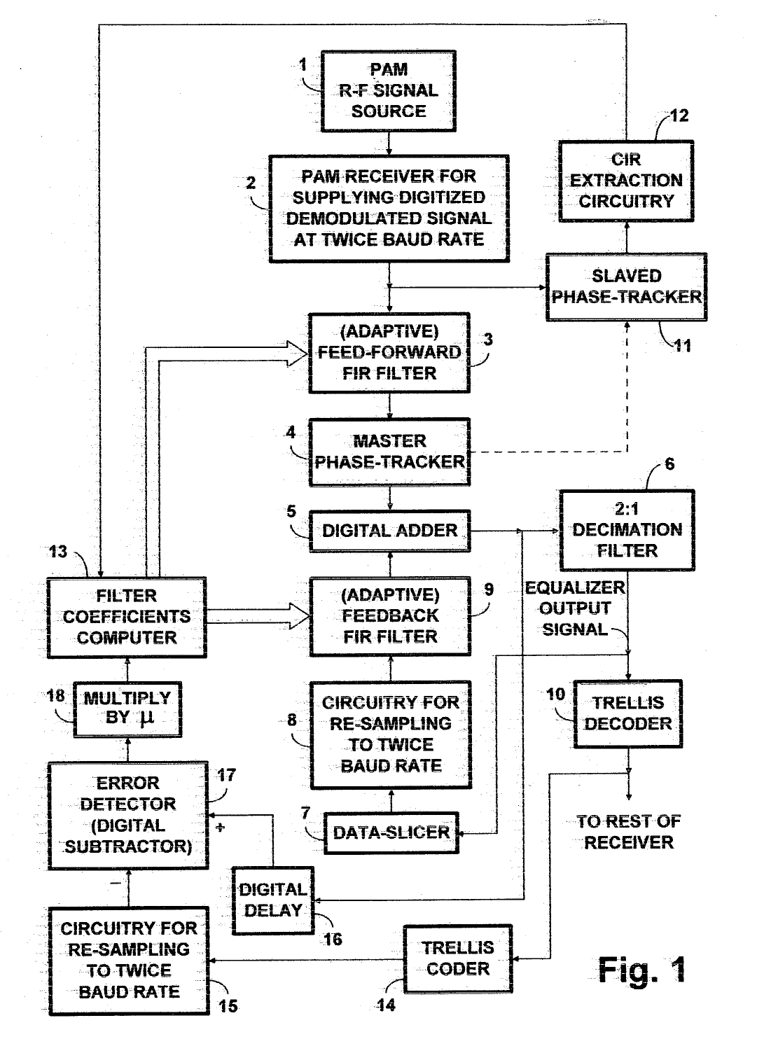

FIG. 1 shows a receiver for radio-frequency signals with digital modulation, which receiver is suitable for incorporation into a digital television (DTV) receiver. A source 1 of pulse-amplitude-modulated (PAM) radio-frequency signals, such as an antenna or a cable connection, is connected for supplying those signals to a PAM receiver 2 for supplying digital samples of a demodulated signal at twice baud rate. The PAM receiver 2 supplies this twice-baud-rate baseband signal to adaptive digital filtering operated to provide fractional channel-equalization including echo suppression. FIG. 1 shows the adaptive digital filtering comprising a feed-forward finite-impulse-response (FIR) filter 3 with adjustable weighting coefficients and an infinite-impulse-response (IIR) filter composed of elements 5-9. The response of the feed-forward FIR filter 3 is supplied as the phase-tracker 4 input signal, and the phase-tracker 4 output signal is supplied as the IIR filter input signal. This IIR filter input signal is applied as first summand input signal to a digital adder 5 in the IIR filter. A second summand input signal to the adder 5 is the response of a feedback FIR filter 9 with adjustable weighting coefficients. The adder 5 linearly combines the phase-tracker 4 output signal with the response of the feedback FIR filter 9 to generate a sum output signal supplied from the adder 5 as an over-sampled equalizers response. This over-sampled equalizer response is decimated by a 2:1 decimation filter 6 to provide baud-rate equalizer response, suitable for application to a data-slicer 7 as input signal thereto. Circuitry 8 re-samples the baud-rate data-slicer 7 response to twice baud rate to generate an over-sampled data-slicer response. This over-sampled data-slicer response is applied as input signal to the feedback FIR filter 9, thereby completing the feedback loops in the IIR filter composed of elements 5-9.

The 2:1 decimation filter 6 response is the IIR filter output signal, supplying baud-rate equalized baseband as input signal to a trellis decoder 10, which operates as a symbol decoder for supplying data to the rest of the receiver. FIG. 1 does not show the rest of the receiver, which can be of conventional construction. If it is a DTV receiver for DTV signals as prescribed by A/53, the typical construction of the rest of the receiver is as follows. A de-interleaver is connected for undoing the convolutional interleaving of the data output signal of the trellis decoder 16. Reed-Solomon error-correction circuitry is connected for correcting byte errors in the data output signal of the trellis decoder 10. The trellis decoder 10 can be constructed to finish information concerning the most likely locations of byte errors to the R-S error-correction circuitry so that circuitry can correct as many as twenty erroneous bytes per data packet. A de-randomizer is connected for responding to the error-corrected data output signal of the R-S error-correction circuit to recover a transport stream of data packets. A transport stream de-multiplexer is connected for sorting video packets to MPEG-2 video de-compression circuitry and solving audio packets to AC-3 audio de-compression circuitry.

FIG. 1 does not explicitly show the details of the construction of the FIR filters 3 and 9. The first FIR filter 3 includes a number of digital multipliers for multiplying differentially delayed responses to the adaptive equalizer input signal received as respective multiplicand input signals by respective weighting coefficients to respective generate product output signals that are summed to generate the FIR filter 3 response. The weighting coefficients that the digital multipliers in the FIR filter 3 use as multiplier input signals are stored in a weighting coefficients register for the FIR filter 3, which register is periodically updated. The second FIR filter 9 includes a number of digital multipliers for multiplying differentially delayed responses to the adaptive equalizer output signal received as respective multiplicand input signals by respective weighting coefficients to respective generate product output signals that are additively combined to generate the FIR filter 9 response. The weighting coefficients that the digital multipliers in the FIR filter 9 use as multiplier input signals are stored in a weighting coefficients register for the FIR filter 9, which register is periodically updated. Each of the digital multipliers in the FIR filters 3 and 9 use can be constructed as a read-only memory (ROM) to avoid the appreciable latent delay associated with a digital multiplier constructed as an arithmetic/logic unit (ALU).

The phase-tracker 4 is operated as a master phase-tracker with the control signal developed for controlling its operation also being used for controlling the operation of a slave phase-tracker 11 connected for receiving that control signal from the phase-tracker 4. The slave phase-tracker 11 de-rotates the twice-baud-rate baseband signal equalizer input signal supplied by the PAM receiver 2 in an amount similar to the amount that the master phase-tracker 4 de-rotates the twice-baud-rate response of the feed-forward FIR filter 3. The slave phase-tracker 11 response is supplied to CIR extraction circuitry 12 that measures the channel-impulse-response (CIR) of de-rotated equalizer input signal.

A small dedicated computer 13 computes weighting coefficients that are supplied to the weighting coefficient registers for the FIR filters 3 and 9. Normally, this filter coefficients computer 13 and the component computers thereof are constructed within integrated circuitry as a “microprocessor” type of computer. Whenever the DTV receiver is powered up after not receiving power for some time, whenever the reception channel is changed, or whenever the error-correction circuitry indicates a current set of weighting coefficients to be seriously in error, the computer 13 computes a set of initial weighting coefficients. This computation of initial weighting coefficients proceeds from the CIR information extracted by CIR extraction circuitry 12. This set of initial weighting coefficients is then supplied to the weighting coefficient registers for the FIR filters 3 and 9, as well as providing a basis for the computer 13 further adjusting the weighting coefficients by a data-directed method.

FIG. 1 shows the following apparatus for generating information concerning reception error arising from non-optimal equalization. This information is utilized by the computer 13 in the data-directed method for further adjusting the weighting coefficients of the FIR filters 3 and 9. A trellis coder 14 codes the data recovered by the trellis decoder 10 to generate symbols used as estimates of the symbols that the transmitter broadcast to receivers. The trellis coder 14 generates symbols at baud rate, and circuitry 15 re-samples the trellis coder 14 output signal to twice baud rate. The samples of equalizer response supplied at twice baud rate as sum output signal from the digital adder 5 are delayed by digital delay circuitry 16. Delay circuitry 16 compensates for the latent delay of the cascade connection of the 2:1 decimation filter 6, the trellis decoder 10, the trellis coder 14 and the circuitry 15 for re-sampling the trellis coder 14 output signal to twice baud rate. An error detector 17 is connected for generating reception error measurements by comparing the delayed twice-baud-rate equalizer response supplied by the delay circuitry 16 with the twice-baud-rate estimate of the symbol stream broadcast by the transmitter. This estimate is supplied by the circuitry 15 for re-sampling the trellis coder 14 output signal. The error detector 17 as shown in FIG. 1 is essentially a digital subtracter. This subtractor is connected to receive, as its minuend input signal, the delayed twice-baud-rate equalizer response supplied by the delay circuitry 16. This subtractor is connected to receive, as its subtrahend input signal, the twice-baud-rate estimate of the broadcast symbol stream supplied by the circuitry 15 for re-sampling the trellis coder 14 output signal. The subtractor is connected to supply its difference output signal as multiplicand input signal to a digital multiplier 18, for multiplication by a factor μ. The digital multiplier 18 is connected to supply its product output signal as a further input signal to the filter coefficients computer 13, which uses the error measurements in the data-directed method of computing adjustments to the weighting coefficients of the FIR filters 3 and 9. These adjustments can be made using the well-known LMS (least-mean-squares) algorithm, for example, with the multiplication by the factor μ in the digital multiplier 14 determining the step size used in executing the algorithm.

Although not explicitly shown in FIG. 1, the factor μ that the digital multiplier 14 uses as multiplier signal can be adjusted responsive to the confidence factors of the final decisions that the trellis decoder 10 makes concerning the received symbols. If there is high confidence that such a final decision is correct, the factor μ can be chosen to be higher. If there is low confidence that such a final decision is correct, the factor μ can be chosen to be lower. A succession of final decisions in which there is very little confidence probably is indicative of the reception of disruptive burst noise, and the factor can accordingly be set to zero.

While the trellis decoder 10 takes longer to make final decisions than the data-slicer 7, the decisions are less apt to be in error. The adaptation of the weighting coefficients of the FIR filters 3 and 9 normally takes hundreds of symbol epochs time in any case. The few tens of symbol epochs time taken for the trellis decoder 10 to supply final decisions that are less apt to be in error is rewarded by being able to use a larger factor μ determining the step size in the adaptation algorithm following error gradient. The larger step size reduces the overall time required for converging the weighting coefficients of the FIR filters 3 and 9 to correct values.

The interposition of delay between the output port of the FIR filter 3 and the summand input port of the digital adder 5 affects the phasing of symbols in each of these filters relative to the phasing of symbols in the other. However, the interposed delay affects neither the computation of the weighting coefficients of the FIR filter 3 nor the computation of the weighting coefficients of the FIR filter 9. This is the case presuming the FIR filters 3 and 9 have structures that are independent of each other. These observations are the basis for being able to introduce de-rotation after the FIR filter 3 to implement phase-tracking or symbol synchronization. The de-rotation phases symbols in the sum output signal from the digital adder 5 so as to minimize intersymbol interference in the decision-feedback signal generated by the data slicer 7.

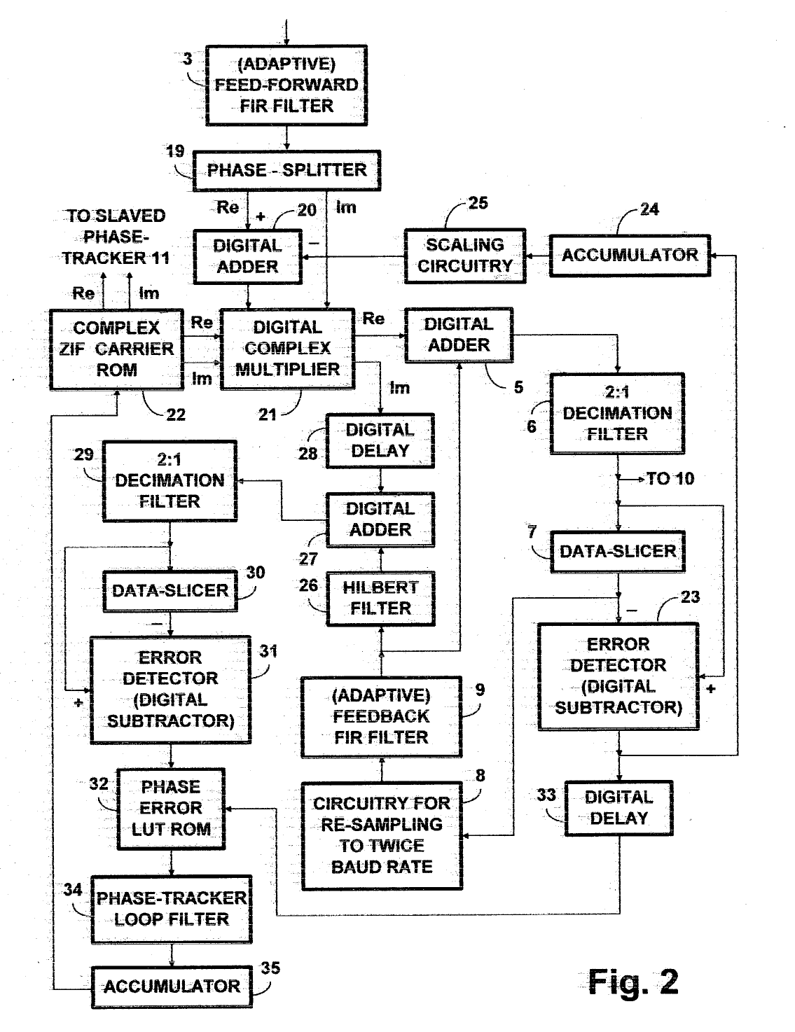

FIG. 2 illustrates how the master phase-tracker 4 is implemented. A phase-splitter 19 is connected to receive the read-only response of the feed-forward FIR filter 3 and to supply as the phase-splitter 19 response a complex delayed feed-forward FIR filter 3 response. For example, the phase-splitter 19 can constitute a Hilbert filter, for converting the real-only response of the feed-forward FIR filter 3 to an imaginary component of the complex delayed feed-forward FIR filter 3 response, and a digital delay circuit. This digital delay circuit delays the real-only response of the feed-forward FIR filter 3 in amount equal to the latent delay of the Hilbert filter, thereby generating the real component of the complex delayed feed-forward FIR filter 3 response. A digital adder 20 operated as a subtractor is connected to receive this real component as its minuend input signal and to receive a residual direct component of baseband signal as its subtrahend input signal. A digital complex multiplier 21 is connected for receiving, as the real component of its multiplicand input signal, the difference output signal of the subtractor 20. The complex multiplier 21 is connected for receiving, as the imaginary component of its multiplicand input signal, the imaginary component of the complex delayed feed-forward FIR filter 3 response from the phase-splitter 19. The complex multiplier 21 is connected for receiving digitized complex zero-intermediate-frequency (ZIF) carrier from read-only memory 22, as its multiplier input signal, which carrier is used for de-rotation that generates a complex product output signal from the complex multiplier 21 pursuant to a phase-tracking operation. The digital adder 5 is connected for receiving the real component of the complex product output signal as a real-only phase-tracker response to delayed feed-forward FIR filter 3 response. The digital adder 5 adds this real-only phase-tracker response to the real-only response of the feedback FIR filter 9 to generate a real-only sum output signal supplied to the 2:1 decimation filter 6.

The response of the 2:1 decimation filter 6 is the real-only baud-rate equalizer response, from which the data-slicer 7 generates decisions as to what symbols were broadcast to the receiver. As noted in the previous description of the FIG. 1 schematic diagram of the PAM receiver, circuitry 8 re-samples these decisions to twice baud rate and supplies the resulting decision-feedback signal to the feedback FIR filter 9 as its input signal. An error detector 23 is connected for comparing the baud-rate equalizer response from the 2:1 decimation filter 6 with the baud-rate decisions supplied from the data-slicer 7 to generate measurements of the reception error in the real-only baud-rate equalizer response. The error detector 23 as shown in FIG. 2 is essentially a digital subtractor. This subtractor is connected to receive, as its minuend input signal, the baud-rate real-only equalizer response supplied by the 2:1 decimation filter 6. This subtractor is connected to receive, as its subtrahend input signal, the baud-rate decisions supplied from the data-slicer 7. The subtractor is connected to supply its difference output signal as input signal to an accumulator 24, which accumulates the measurements of the reception error in the real-only baud-rate equalizer response. The automatic-gain-control (AGC) circuitry of the PAM receiver is designed to regulate the gain of the real-only baud-rate equalizer response so the data-slicing levels are optimal. So, if the real-only baud-rate equalizer response is free of direct component, the measurements supplied from the error detector 23 should average to arithmetic zero over time. Scaling circuitry 25 responds to the more significant bits of any departure of the accumulation result from arithmetic zero to supply a subtrahend input signal to the digital adder 20 operated as a subtractor. This subtrahend input signal adjusts the direct component of the real component of the digital adder 20 sum output signal to degenerate the direct component of the real-only baud-rate equalizer response.

The measurements the error detector 23 makes of the reception error in the real-only baud-rate equalizer response are also used in the phase-tracker. These measurements, together with measurements of the reception error in a delayed imaginary-only baud-rate equalizer response, are the basis for controlling the complex ZIF carrier that the digital complex multiplier 21 employs in the de-rotation of the complex delayed feed-forward FIR filter 3 response. That delayed imaginary-only baud-rate equalizer response is generated as follows. A Hilbert filter 26 is connected for receiving the real-only response of the feedback FIR filter 9 and for supplying the imaginary-only feedback FIR filter 9 response that the filter 26 synthesizes as one of two summand input signals of a digital adder 27. The imaginary component of the complex product output signal from the complex multiplier 21 is delayed by digital delay circuitry 28 to compensate for the latent delay in the Hilbert filter 26 plus any latent delay in the cascade connection of elements 5-8. The digital delay circuitry 28 is connected to apply the delayed imaginary component of the complex product output signal to the adder 27 as the other of its summand input signals. The sum output signal of the adder 27 is delayed imaginary-only equalizer response sampled at twice baud rate. A 2:1 decimation filter 29 similar in construction to the 2:1 decimation filter 6 is connected to receive the sum output signal from the adder 27 and to supply the delayed imaginary-only baud-rate equalizer response. Note that the delays associated with generating the delayed imaginary-only baud-rate equalizer response are not included within the decision-feedback loop(s), so the capability of the IIR filtering to suppress short-delay post-echoes is not compromised.

A data-slicer 30 similar in construction to the data-slicer 7 is connected for quantizing the delayed imaginary-only baud-rate equalizer response. An error detector 31 is connected for comparing the baud-rate delayed imaginary-only equalizer response from the 2:1 decimation filter 29 with the baud-rate decisions supplied from the data-slicer 30 to generate measurements of the reception error in the delayed imaginary-only baud-rate equalizer response. The error detector 31 as shown in FIG. 2 is essentially a digital subtractor that supplies, as its difference output signal, measurements of the reception error in the delayed imaginary-only baud-rate equalizer response. This subtractor is connected to receive, as its minuend input signal, the baud-rate delayed imaginary-only equalizer response supplied by the 2:1 decimation filter 29. This subtractor is connected to receive, as its subtrahend input signal, the baud-rate decisions supplied from the data-slicer 30. The subtractor is connected to supply its difference output signal as a portion of the input address of a read-only memory 32 that stores a look-up table (LUT) for phase error in the phase-tracker. A digital delay circuit 33 delays the measurements that the error detector 23 supplies of the reception error in the real-only baud-rate equalizer response, so as to be contemporaneous with the measurements of the reception error in the delayed imaginary-only baud-rate equalizer response. The digital delay circuit 33 is connected to supply the phase-error LUT ROM 32 delayed read-only baud-rate equalizer response as the remaining portion of the ROM 32 input address. The phase-error LUT ROM 32 is connected to supply phase-error input signal to a phase-tracker loop filter 34. The response of the phase-tracker loop filter 34 is supplied to an accumulator 35 that generates input addressing for the complex ZIF carrier ROM 21, completing the phase-tracker loop.

The phase-error LUT ROM 32 is similar in design to those used in the phase-trackers described in U.S. Pat. Nos. 5,406,587 and 5,533,071. The phase-tracker loop filter 34 determines the frequency response of the phase-tracker loop analogously to what a filter termed a “phase-lock loop filter” does in U.S. Pat. Nos. 5,406,587 and 5,533,071. The phase-tracker loop filter 34 is chosen to suppress phase noise as high as 30 kHz.

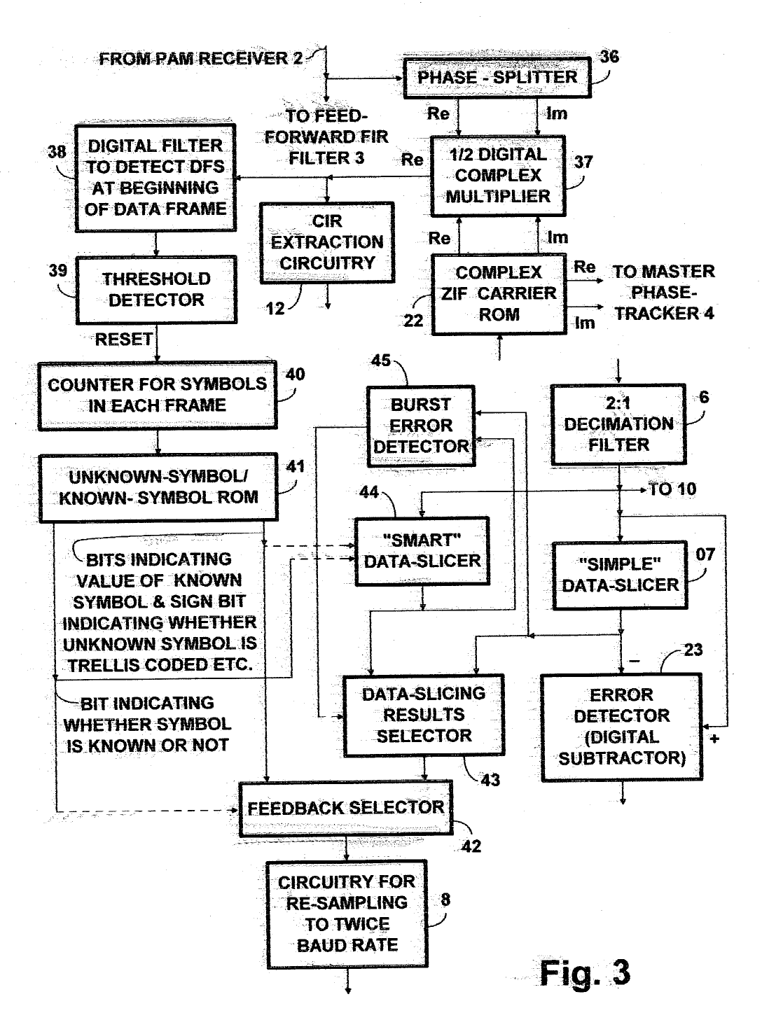

FIG. 3 shows details of the construction of the slaved phase-tracker 11 shown in FIG. 1 when the master phase-tracker is of the form shown in FIG. 2. Demodulated baseband signal from the PAM receiver 2, applied as input signal to the feed-forward FIR filter 4, is also applied as input signal to a phase-splitter 36 of construction similar to that of the phase-splitter 19. A half digital complex multiplier 37 is connected to receive the resulting complex baseband signal as a complex multiplicand input signal and to receive the complex ZIF carrier from the ROM 22 signal as a complex multiplicand input signal. The half digital complex multiplier 37 supplies a de-rotated real-only baseband signal as its product output signal, which the CIR extraction circuitry 12 is connected to receive as its input signal. The half of a complete digital complex multiplier that would supply an imaginary-only baseband signal as its product output signal is unnecessary and is omitted in the construction shown in FIG. 3.

A digital filter 38 is connected to detect data field synchronizing (DFS) signal occurring at the beginning of a data frame in the de-rotated read-only baseband signal that the half digital complex multiplier 37 supplies as its product output signal. A threshold detector 39 detects when a significant peak occurs in the response of the digital filter 38 to DFS signal at the beginning of a data frame to generate a reset signal for a counter 40 that counts the symbols in each data frame. The counter 40 does this symbol counting in response to a baud rate clock signal from a source of such signal, which connection is not explicitly shown in FIG. 3.

A read-only memory 41 receives as its input addressing the symbol count from the counter 40. The ROM stores a plurality of bits at each of its addressed storage locations. One of the bits indicates whether the corresponding symbol in the baud-rate equalizer response is known or unknown. The symbols in the data segment synchronizing sequences are known. The symbols in the PNS511 sequence and in the triple PN63 sequence in the initial data segment of each data field are known. If additional training signal is employed in the final data segment of each data field, the symbols in that additional training signal are known. The remaining bits at each of the addressed storage locations in the ROM 41 indicate the value of the corresponding symbol in the baud-rate equalizer response, if it is a known symbol. If the symbol is not known, the remaining bits indicate whether the unknown symbol is trellis-coded or not. E.g., the sign bit can indicate whether the unknown symbol is trellis-coded or not. If the symbol is not known, the remaining bits can also encode further trellis decoding instructions.

FIG. 3 also shows an improvement to the FIG. 2 circuitry for deriving the feedback signal supplied to the circuitry 8 for re-sampling to twice baud rate. A feedback selector 42 selects one of two signals as decision-feedback signal to the circuit 8, the selection being made responsive to the bit from the ROM 41 indicating whether the corresponding symbol in the baud-rate equalizer response is known or unknown. If the value of this selection-control bit indicates the symbol is known, the feedback selector 42 selects the known value of the symbol read from the ROM 41 to be the decision-feedback signal. If the value of this selection-control bit indicates the symbol is unknown, the feedback selector 42 selects an estimation of the symbol provided by a data-slicing results selector 43 to be the decision-feedback signal.

The data-slicing results selector 43 is connected for selecting between the data-slicing results supplied from a “simple” data-slicer 07 and a “smart” data-slicer 44, the selection being made responsive to the output signal of a burst error detector 45. When the burst error detector 45 output signal indicates absence of burst error, the data-slicing results selector 43 selects the data-slicing results supplied from the “smart” data-slicer 44 as the input signal that it supplies to the feedback selector 42. The “smart” data-slicer 44 is connected for receiving as its input signal the baud-rate equalizer response that the 2:1 decimation filter 6 supplies. The “smart” data-slicer 44 is of a type disclosed in U. S. Pat. No. 6,178,209. The “smart” data-slicer 44 uses prediction based on the properties of trellis decoding to improve the estimates of the transmitted symbol over those available from the “simple” data-slicer 07, which does not employ prediction in making symbol decisions. However, the “smart” data-slicer 44 is subject to running error when burst error occurs and for some time thereafter. So, when the burst error detector 45 output signal indicates the presence of burst error, the data-slicing results selector 43 selects the data-slicing results supplied from the “simple” data-slicer 07 as the input signal that it supplies to the feedback selector 42.

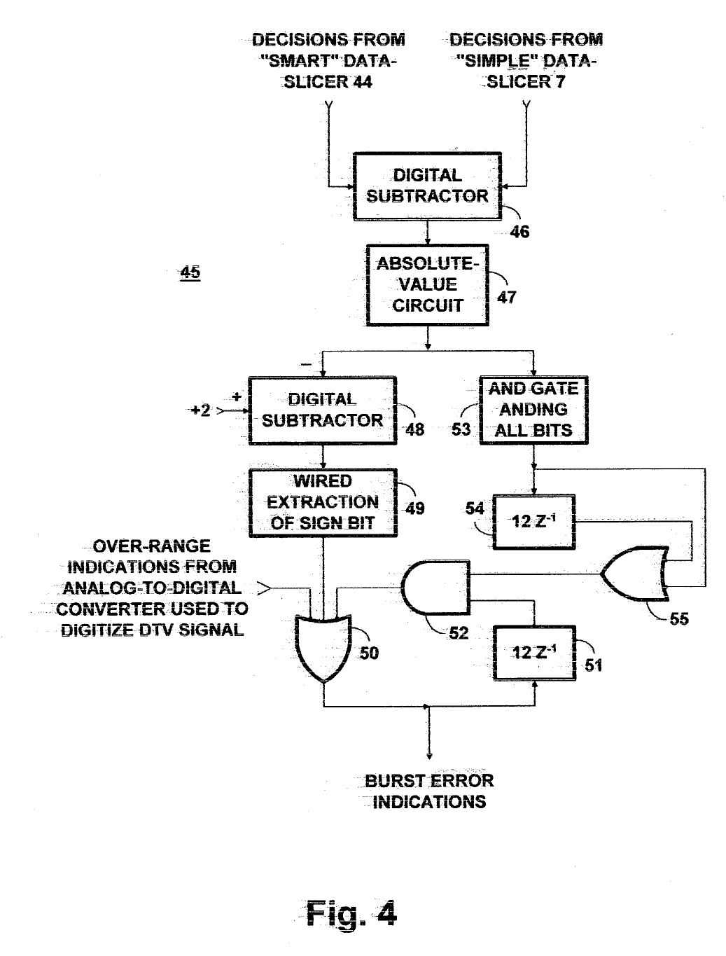

FIG. 4 shows in greater detail how the burst error detector 45 can be constructed. When the noise from the baud-rate equalizer response from the 2:1 decimation filter 6 is essentially all-white Gaussian noise (AWGN), the symbol decisions made by the “smart” data-slicer 44 will be as good as or better than the symbol decisions made by the “simple” data-slicer 07. When SNR falls to where noise peaks frequently exceed one to two times the energy difference between adjacent digital modulation levels, the symbol decisions made by the “smart” data-slicer 44 will be appreciably better than the symbol decisions made byte “simple” data-slicer 07. The symbol decisions made by the “simple” data-slicer 07 are apt to be in error by one digital modulation level. When SNR falls to where noise peaks frequently exceed twice the energy difference between adjacent digital modulation levels, the symbol decisions made by the “smart” data-slicer 44 are less likely to be so much better than the symbol decisions made by the “simple” data-slicer 7. Furthermore, the condition where the concurrent symbol decisions respectively made by the “smart” data-slicer 44 and by the “simple” data-slicer 07 differ by more than the energy difference between adjacent digital modulation levels is likely to be associated with the occurrence of burst noise, if AWGN rarely exceeds that energy difference.

Within the burst error detector 45, a digital subtractor 46 is connected for subtracting each symbol decision made by one of the data-slicers 07 and 44 from the symbol decision concurrently made by the other of the data-slicers 07 and 44. Per convention, the energy difference between adjacent digital modulation levels of an 8VSB signal is presumed to have a normalized amplitude value of two. An absolute-value circuit 47 is connected to receive as its input signal the difference output signal of the subtractor 46 and to supply a measure of the absolute difference between the symbol decisions made by the data-slicers 07 and 44. A digital subtractor 48 using two's complement arithmetic is connected to subtract this absolute difference from plus four, plus four being twice the energy difference between adjacent digital modulation levels of an 8VSB signal. The subtractor 48 functions as a comparator with the sign bit of its difference output signal being ZERO if the absolute difference between the symbol decisions made by the data-slicers 07 and 44 is no more than two digital modulation levels. The sign bit of the subtractor 48 difference output signal is ONE if the absolute difference between the symbol decisions made by the data-slicers 07 and 44 is more than two digital modulation levels. There is a wired extraction 49 of the sign bit of the subtractor 48 difference output signal for application to an OR gate 50 as one of the input signals thereof. The logic response of the OR gate 50 is the output signal from the burst error detector 45. The OR gate 50 logic response being ZERO conditions the data-slicing results selector 43 to select the data-slicing results from the “smart” data-slicer 44 to the feedback selector 42. A ONE logic response from the OR gate 50 conditions the data-slicing results selector 43 to select the data-slicing results from the “simple” data-slicer 07 to the feedback selector 42.

With the 12-phase trellis coding employed in HDTV signals when broadcasting is done in accordance with A/53, an error in any of the twelve phases of trellis coding results from the “smart” data-slicer 44 is likely to recur for some time at 12-symbol-epoch intervals. If the OR gate 50 response is a ONE, indicating, burst error, the data-slicing results from the “simple” data-slicer 07 will be selected to the feedback selector 42. Preferably, this selection is not only made during a current symbol epoch, but also every twelfth symbol epoch thereafter until it is ascertained that the “smart” data-slicer 44 has corrected any running error in its data-slicing results.

Accordingly, a 12-symbol-epoch digital delay circuit 51 is connected for delaying the logic response from the OR gate 50 by twelve symbol epochs, and a two-input AND gate 52 is connected for conditionally applying the delayed OR gate 50 response to the OR gate 50 as a second input signal. An AND gate 53 is connected for ANDing all the bits of the absolute-value circuit 47 response to generate a logic ONE if and only if that response is arithmetic zero. A 12-symbol-epoch digital delay circuit 54 is connected for delaying the logic response from the AND gate 53. An OR gate 55 is connected for responding to the AND gate 53 response and that response as delayed twelve symbol epochs by the digital delay circuit 54.

The AND gate 53 logic response being ONE indicates that the current decision made by the “smart” data-slicer 44 differs from the current decision made by the “simple” data-slicer 07. Presumably, this is an indication that any running error in decisions from the “smart” data-slicer 44 has not yet been corrected. If the delayed AND gate 53 logic response that the delay circuit 54 provides as its output signal is ONE, this indicates that the last previous decision made by the “smart” data-slicer 44 differs from the last previous decision made by the “simple” data-slicer 07. Presumably, this is an indication that any running error in decisions from the “smart” data-slicer 44 may not yet have been corrected. Responsive to either of these indications of running error in the data-slicing results from the “smart” data-slicer 44, the OR gate 55 supplies a logic ONE response as second input signal to the AND gate 52. This conditions the AND gate 52 to supply the OR gate 59 an input signal that reproduces the OR gate 50 response from twelve symbols previous.

The AND gate 53 logic response being ZERO indicates that the current decisions made by the “smart” data-slicer 44 and by the “simple” data-slicer 07 are the same. Presumably, this is an indication that any running error in decisions from the “smart” data-slicer 44 may have been corrected. If the delayed AND gate 53 logic response that the delay circuit 54 provides as its output signal is ZERO, this indicates that the last previous decision made by the “smart” data-slicer 44 was the same as the last previous decision made by the “simple” data-slicer 07. Presumably, this is a further indication that any running error in decisions from the “smart” data-slicer 44 may have been corrected. Responsive to both of these indications of any running error in the data-slicing results from the “smart” data-slicer 44 probably having been corrected, the OR gate 55 supplies a logic ZERO response as second input signal to the AND gate 52. The logic ZERO response from the OR gate 55 is considered to a conclusive indication that the data-slicing results from the “smart” data-slicer 44 are correct. The logic ZERO response from the OR gate 55 conditions the AND gate 52 to generate a ZERO logic response of its own. The AND gate 52 supplies its ZERO logic response to the OR gate 50 as an input signal thereto, rather than supplying the OR gate 50 with an input signal that reproduces the OR gate 50 response from twelve symbols previous.

The PAM receiver 2 can be arranged to supply other indications that running error is quite likely in the data-slicing results from the “smart” data-slicer 44, which indications are applied to the OR gate 50 as another input signal thereto. E.g., FIG. 4 shows indication of over-ranging in the analog-to-digital converter used in the PAM receiver 2 to digitize DTV signal being applied to the OR gate 50 as another input signal thereto. Such over-ranging is a likely consequence of impulse noise that will cause burst noise in the baud-rate equalizer response and that will quite likely cause running error in the data-slicing results from the “smart” data-slicer 44.

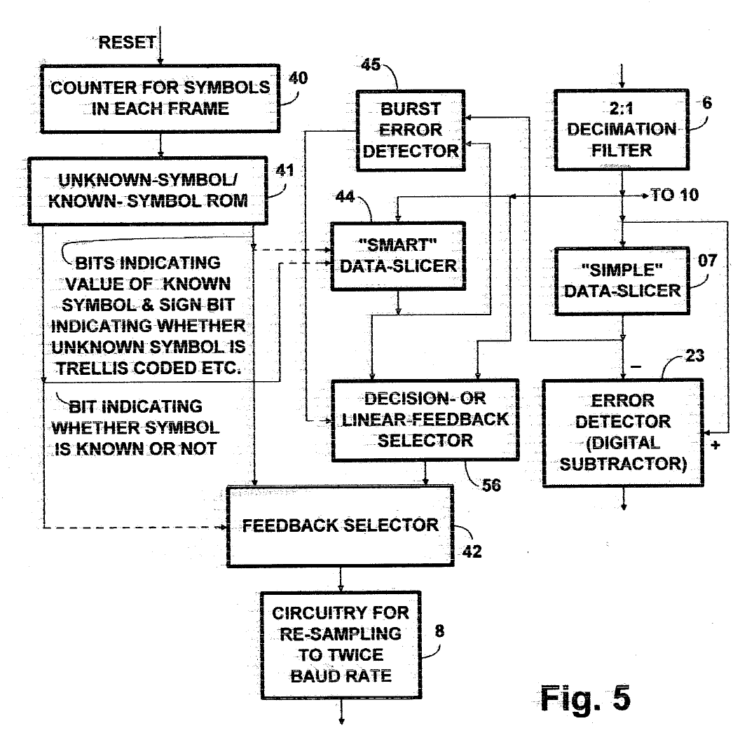

FIG. 5 shows a modification of the FIG. 3 improvement to the FIG. 2 circuitry for deriving the feedback signal supplied to the circuitry 8 for re-sampling to twice baud rate. The data-slicing results selector 43 of FIG. 3 is replaced by a decision- or linear-feedback selector 56 connected for selecting one of two signals as the feedback signal supplied to the circuitry 18 for re-sampling to twice baud rate. The selection is controlled by the output signal from the burst error detector 45. If the burst error detector 45 supplies a logic ZERO response indicating the data-slicing results from the “smart” data-slicer 44 are free from running error, the selector 56 selects these data-slicing results to be an input signal to the feedback selector 42. This selection implements decision-feedback equalization in the IIR filtering comprising the feedback FIR filter 9. If the burst error detector 45 supplies a logic ONE response, indicating the data-slicing results from the “smart” data-slicer 44 are likely to contain running error, the selector 56 selects the baud-rate equalizer response from the 2:1 decimation filter 6 to be an input signal for the feedback selector 42. This selection implements linear-feedback equalization in the IIR filtering comprising the feedback FIR filter 9.

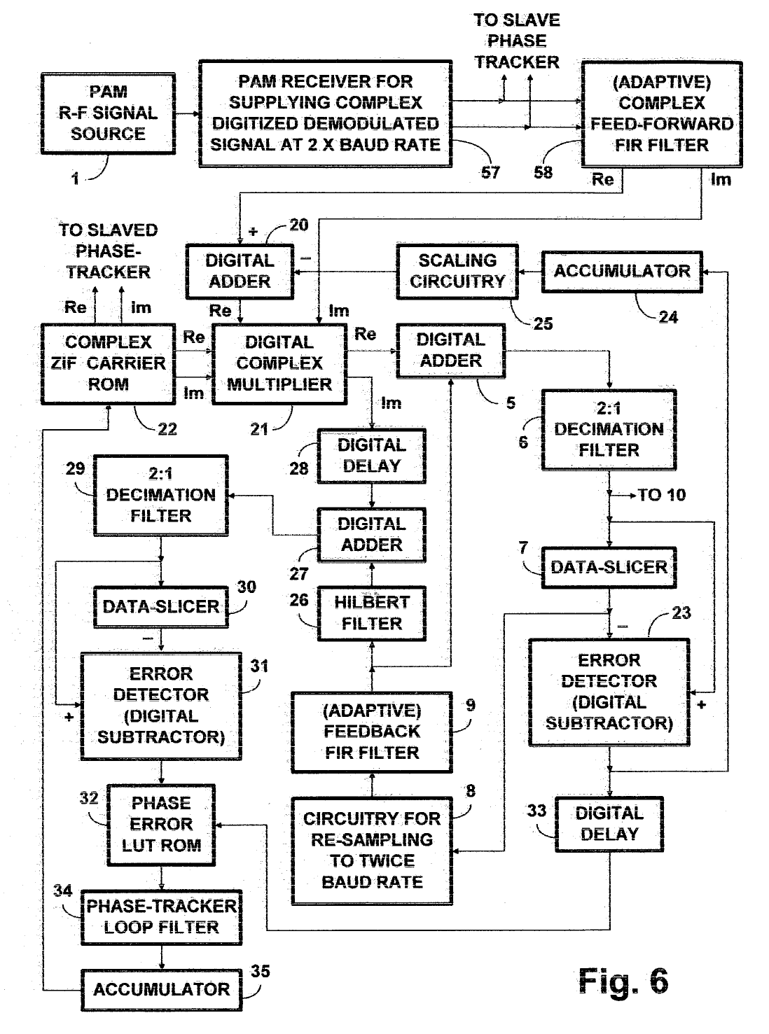

FIG. 6 shows a portion of a receiver that is a modification of the FIG. 1 receiver for PAM radio-frequency signals. The source 1 of PAM radio-frequency signals is connected for supplying those signals to a PAM receiver 57 for supplying a complex demodulated signal. The digital samples in the real component of this complex demodulated signal are supplied at twice baud rate, and so are the digital samples in the imaginary component of this complex demodulated signal. The PAM receiver 57 supplies this twice-baud-rate complex baseband signal to adaptive digital filtering operated to provide fractional channel-equalization including echo suppression. FIG. 6 shows the adaptive digital filtering comprising a complex feed-forward finite-impulse-response (FIR) filter 58 with adjustable weighting coefficients and an infinite-impulse-response (IIR) filter composed of elements 5-9. The response of the complex feed-forward FIR filter 58 is supplied as the phase-tracker input signal.

The phase-tracker in FIG. 6 differs from that shown in FIG. 2 in that the phase-splitter 19 is dispensed with. The digital adder 20 operated as a subtractor is connected to receive the real component of the complex feed-forward FIR filter 58 response as its minuend input signal. The complex multiplier 21 is connected for receiving, as the imaginary component of its multiplicand input signal, the imaginary component of the complex feed-forward FIR filter 58 response. The rest of the FIG. 6 phase-tracker is the same in construction and operation as the FIG. 2 phase-tracker. The real component of the complex product output signal from the digital complex multiplier 21 is the phase-tracker output signal applied as first summand input signal to the digital adder 5 in the IIR filter.

The second summand input signal to the adder 5 is the response of the feedback FIR filter 9 with adjustable weighting coefficients. The adder 5 linearly combines the response of the feedback FIR filter 9 with the phase-tracker output signal received as IIR filter input signal, to generate a sum output signal supplied from the adder 5 as an over-sampled equalizer response. This over-sampled equalizer response is decimated by a 2:1 decimation filter 6 to provide baud-rate equalizer response, suitable for application to a data-slicer 7 as input signal thereto. Circuitry 8 re-samples the baud-rate data-slicer 7 response to twice baud rate to generate an over-sampled data-slicer response. This over-sampled data-slicer response is applied as input signal to the feedback FIR filter 9, thereby completing the feedback loops in the IIR filter composed of elements 5-9.

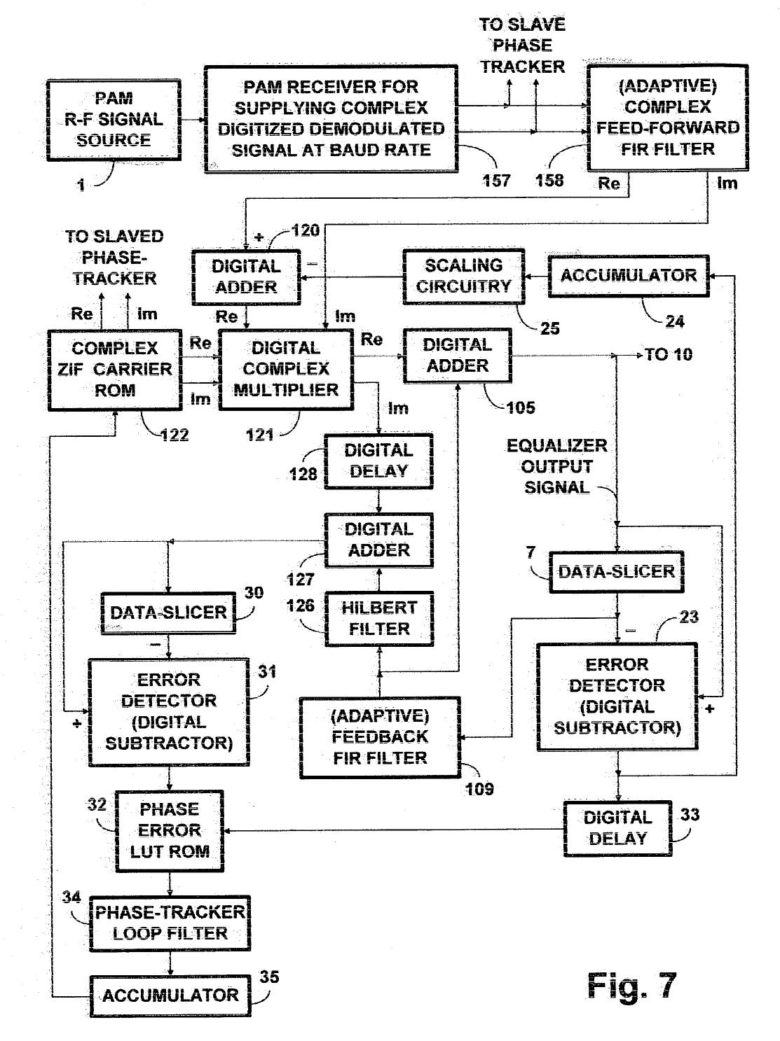

FIG. 7 shows modifications that can be made to the FIG. 6 portion of a receiver for PAM radio-frequency signals. These modifications include the PAM receiver 57 being replaced by a PAM receiver 157 for supplying a complex demodulated signal sampled at baud rate, rather than at twice baud rate. The digital adder 20 is replaced in FIG. 7 by a digital adder 120 operated as a digital subtractor for generating difference output signal sampled at baud rate, rather than at twice baud rate. The digital complex multiplier 21 is replaced in FIG. 7 by a digital complex multiplier 121 operated for generating a product output signal sampled at baud rate, rather than at twice baud rate. The read-only memory 22 for supplying samples of digitized complex ZIF carrier at twice baud rate to the complex multiplier 21 is replaced by read-only memory 122 for supplying samples of digitized complex ZIF carrier at baud rate to the complex multiplier 121. The digital adder 5 is replaced in FIG. 7 by a digital adder 105 that is operated for generating as a sum output signal sampled at baud rate, rather than at twice baud rate. The 2:1 decimation filter 6 is not used in FIG. 7 receiver circuitry, since the sum output signal from the adder 105 provides baud-rate equalizer output signal directly for application to the data-slicer 7 and to trellis coder 10 (not explicitly shown in FIG. 7). The feedback FIR filter 9 with adjustable weighting coefficients at half-symbol-epoch intervals is replaced in FIG. 7 by a feedback FIR filter 109 with adjustable weighting coefficients at symbol-epoch intervals. The Hilbert filter 26, the digital adder 27 and the digital delay circuit 28 operated with twice baud rate clocking are replaced in FIG. 7 by a Hilbert filter 126, a digital adder 127 and a digital delay circuit 128, respectively, operated with baud rate clocking. The 2:1 decimation filter 29 is not used in the FIG. 7 receiver circuitry, since the sum output signal from the adder 127 being baud-rate does not require decimation before being data sliced by the data-slicer 30.

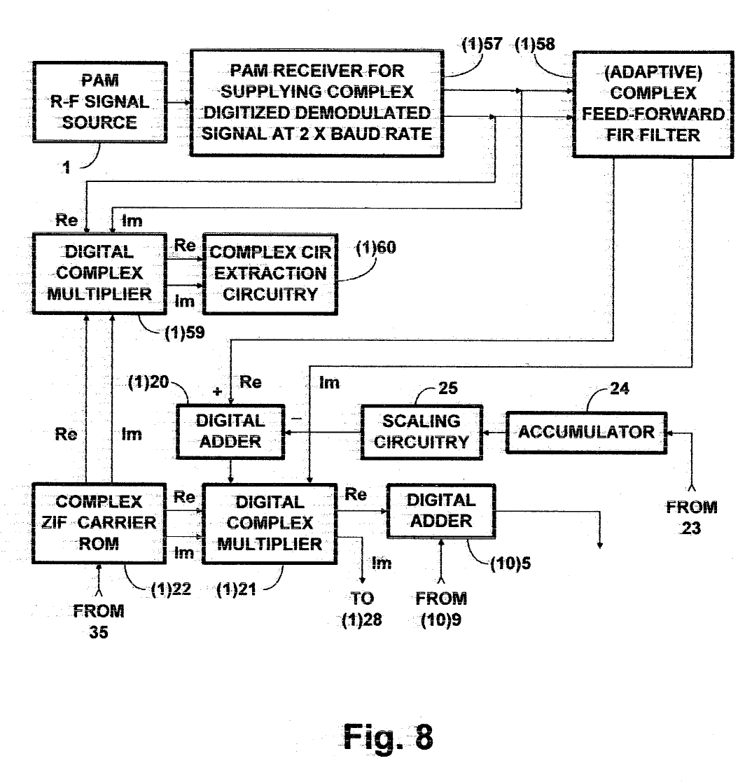

FIG. 8 shows how the slave phase-tracker is connected for the receiver portions shown in FIGS. 6 and 7. The portions of the element identification numbers in parentheses are omitted with reference to the slave phase-tracker for the FIG. 6 receiver portion, and the complete element identification numbers are applicable to the slave phase-tracker for the FIG. 7 receiver portion.

The slave phase-tracker for the FIG. 6 receiver portion essentially consists of a digital complex multiplier 59 for the complex demodulated signal sampled at twice baud rate that the PAM receiver 57 supplies by a complex ZIF carrier signal sampled at twice baud rate read from the ROM 22. The resulting complex product signal is supplied to complex CIR extraction circuitry 60 which measures the complex channel-impulse-response (CIR) of this de-rotated equalizer input signal. Initial weighting coefficients for the FIR filters 58 and 9 are computed from the complex CIR measurement, providing a basis for further adjustment of the weighting coefficients by a data-directed method.

The slave phase-tracker for the FIG. 7 receiver portion essentially consists of a digital complex multiplier 159 for multiplying the complex demodulated signal sampled at twice baud rate that the PAM receiver 157 supplies by a complex ZIF carrier signal sampled at twice baud rate read from the ROM 122. The resulting complex product signal is supplied to complex CIR extraction circuitry 160 which measures the complex channel-impulse-response (CIR) of this de-rotated equalizer input signal. Initial weighting coefficients for the FIR filters 158 and 109 are computed from the complex CIR measurement, providing a basis for further adjustment of the weighting coefficients by a data-directed method

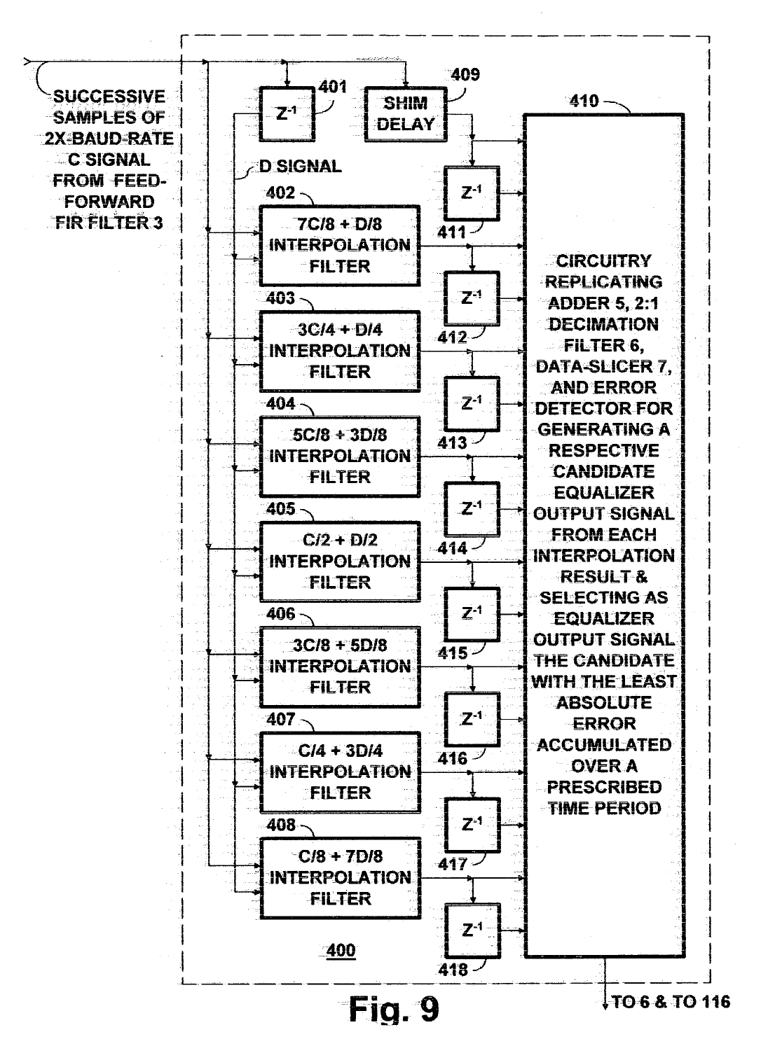

FIG. 9 shows phase-tracking circuitry 400 that in another embodiment of the invention replaces the phase-tracker 4, the digital adder 5, the 2:1 decimation 6 and the data-slicer 7 of the FIG. 1 receiver for PAM radio-frequency signals. The twice-baud-rate response of the feed-forward FIR filter 3 is supplied as input signal C to the phase-tracking circuitry 400. A one-sample digital delay 401 in the phase-tracking circuitry 400 delays the twice-baud-rate response of the feed-forward FIR filter 3 by one-half a symbol epoch to generate a signal D. The C and D signals are applied as input signals to interpolation filters 402, 403, 404, 405, 406, 407 and 408. The C signal is applied as input signal to shim delay circuitry 409 that supplies delayed C signal as an input signal to circuitry 410 for selecting equalizer output signal. The delay in C signal introduced by the shim delay circuitry 409 compensates for the latent delay in each of the interpolation filters 402, 403, 404, 405, 406, 407 and 408. The shim delay circuitry 409 response is additionally delayed one-half a symbol epoch by a one-sample digital delay 411 and then is supplied as a further input signal to the circuitry 410. The interpolation filter 402 generates a 7C/8+D/8 response to the C and D signals, which response is supplied as a further input signal to the circuitry 410. The interpolation filter 402 response is delayed one-half a symbol epoch by a one-sample digital delay 412 and then is supplied as a further input signal to the circuitry 410. The interpolation filter 403 generates a 3C/4+D/4 response to the C and D signals, which, response is supplied as a further input signal to the circuitry 410. The interpolation filter 403 response is delayed one-half a symbol epoch by a one-sample digital delay 413 and then is supplied as a further input signal to the circuitry 410. The interpolation filter 404 generates a 5C/8+3D/8 response to the C and D signals, which response is supplied as a further input signal to the circuitry 410. The interpolation filter 404 response is delayed one-half a symbol epoch by a one-sample digital delay 41 and then is supplied as a further input signal to the circuitry 410. The interpolation filter 405 generates a C/2+D/2 response to the C and D signals, which response is supplied as a further input signal to the circuit 410. The interpolation filter 405 response is delayed one-half a symbol epoch by a one-sample digital delay 415 and then is supplied as a further input signal to the circuitry 410. The interpolation filter 406 generates a 3C/8+5D/8 response to the C and D signals, which response is supplied as a further input signal to the circuitry 410. The interpolation filter 406 response is delayed one-half a symbol epoch by a one-sample digital delay 416 and then is supplied as a further input signal to the circuitry 410. The interpolation filter 407 generates a C/4+3D/4 response to the C and D signals, which response is supplied as a further input signal to the circuitry 410. The interpolation filter 407 response is delayed one-half a symbol epoch by a one-sample digital delay 417 and then is supplied as a further input signal to the circuit 410. The interpolation filter 408 generates a 7C/8+D/8 response to the C and D signals, which response is supplied as a further input signal to the circuit 410. The interpolation filter 408 response is delayed one-half a symbol epoch by a one-sample digital delay 418 and then is supplied as a further input signal to the circuitry 410.

The circuitry 410 for selecting equalizer output signal receives sixteen input signals, each a differently phased sampling of the twice-baud-rate response of the feed-forward FIR filter 3. These sixteen input signals are candidate phase-tracker responses. The circuitry 410 includes a respective digital adder 5 for combining each of these candidate phase-tracker responses the response of the feedback FIR filter 9, a respective 2:1 decimation filter 6 for decimating the sum output signal of that adder, and a data-slicer 7 for quantizing the response of at decimation filter. The circuits 410 includes a respective error detector for the difference between the input and output signals of each data-slicer 7 and a respective accumulator for accumulating the detected errors over a prescribed time period. The output signal of the data-slicer 7 associated with the least accumulated error is selected as the decision-feedback signal applied to the circuitry 8 for re-sampling to twice baud rate, and the respective 2:1 decimation filter 6 response applied as input signal to that data-slicer 7 is selected as the equalizer out signal supplied to the trellis decoder 10.

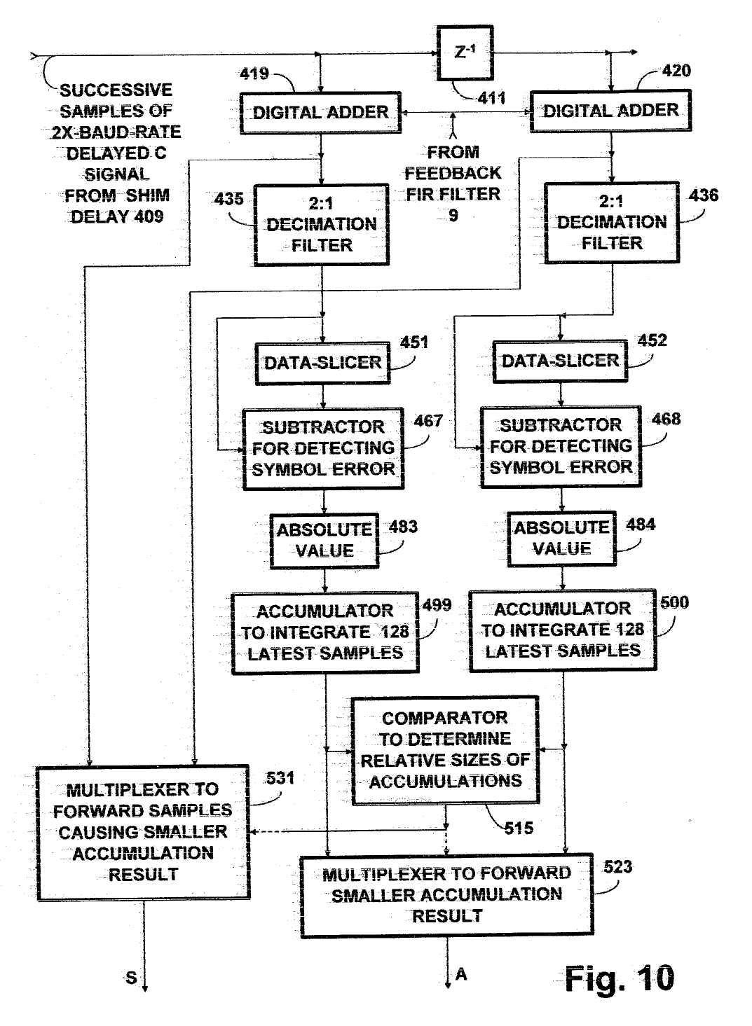

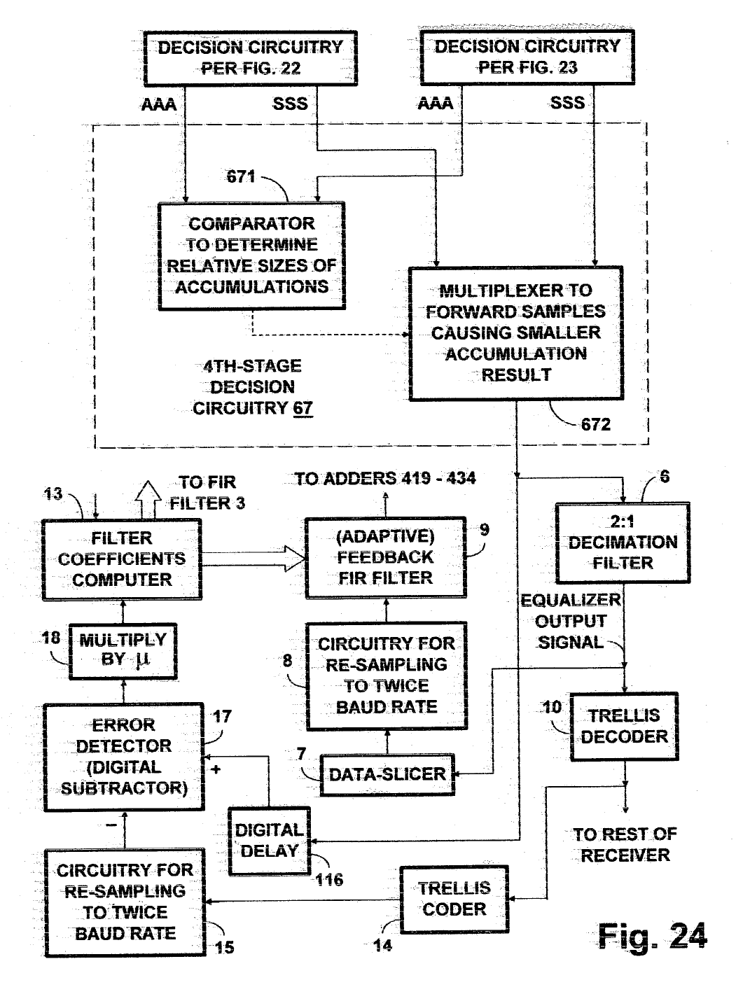

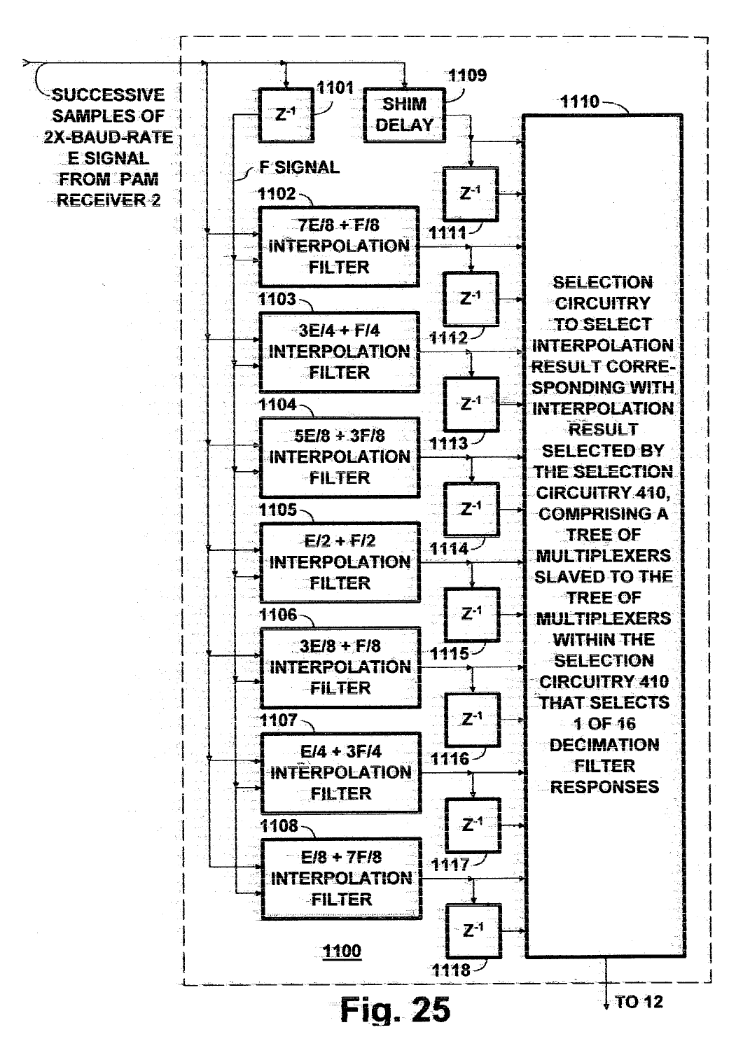

FIGS. 10 through 24 show in greater detail how the circuitry 410 for selecting equalizer output signal is implemented. The sixteen candidate phase-tracker responses the circuitry 410 receives as input signals are each combined with the feedback FIR filter 9 response in a respective one of digital adders 419-434 to generate a respective one of sixteen candidate equalizer output signals sampled at twice baud rate. The selection procedure is of tree type beginning from the top with a first stage of reducing the sixteen trial responses to eight trial responses, using first-stage decision circuitry shown in FIGS. 10, 11, 12, 13, 14, 15, 16 and 17. This first stage of reducing the number of trial responses is followed by a second stage of reducing the eight trial responses to four trial responses, using apparatuses shown in FIGS. 18, 19, 20 and 21. This second stage of reducing the number of trial responses is followed by a third stage of reducing the four trial responses to two trial responses, using apparatuses shown in FIGS. 22 and 23. This third stage of reducing the number of trial responses is followed by a fourth stage of reducing the two trial responses to a single final response, using apparatus shown in FIG. 24.

In FIG. 10 the digital adder 419 combines the feedback FIR filter 9 response with the delayed C signal supplied by the shim delay circuitry 409 to generate a first candidate equalizer output signal sampled at twice baud rate and applied as input signal to a 2:1 decimation filter 435. The response of the 2:1 decimation filter 435 is a first candidate equalizer output signal sampled at baud rate and applied as input signal to a data-slicer 451. The data-slicer 451 generates estimates of the symbols actually transmitted to give rise to the symbols in the first candidate equalizer output signal sampled at baud rate. A digital subtractor 467 differentially combines the symbols received in the first candidate equalizer output signal and the corresponding estimates of the symbols actually transmitted to give rise to those received symbols to determine the departures of the received symbols from symbols that could actually have been transmitted. An absolute-value circuit 483 determines the absolute value of each departure, which is supplied to an accumulator 499 that accumulates the absolute values of a prescribed number N of the most recent departures of the received symbols from symbols that could actually have been transmitted. By way of example, N is 128, as shown in FIG. 10.

Similarly, the digital adder 420 combines the feedback FIR filter 9 response with the delayed C signal supplied by the one-sample digital delay 411 to generate a second candidate equalizer output signal sampled at twice baud rate applied as input signal to a 2:1 decimation filter 436. The response of the 2:1 decimation filter 436 is a second candidate equalizer output signal sampled at baud rate and applied as input signal to a data-slicer 452. The data-slicer 452 generate estimates of the symbols actually transmitted to give rise to the symbols in the second candidate equalizer output signal sampled at baud rate. A digital subtractor 468 differentially combines the symbols received in the second candidate equalizer output signal and the corresponding estimates of the symbols actually transmitted to give rise to those received symbols to determine the departing of the received symbols from symbols that could actually have been transmitted. An absolute-value circuit 484 determines the absolute value of each departure, which is supplied to an accumulator 500 that accumulates the absolute values of the N most recent departures of the received symbols from symbols that could actually have been transmitted

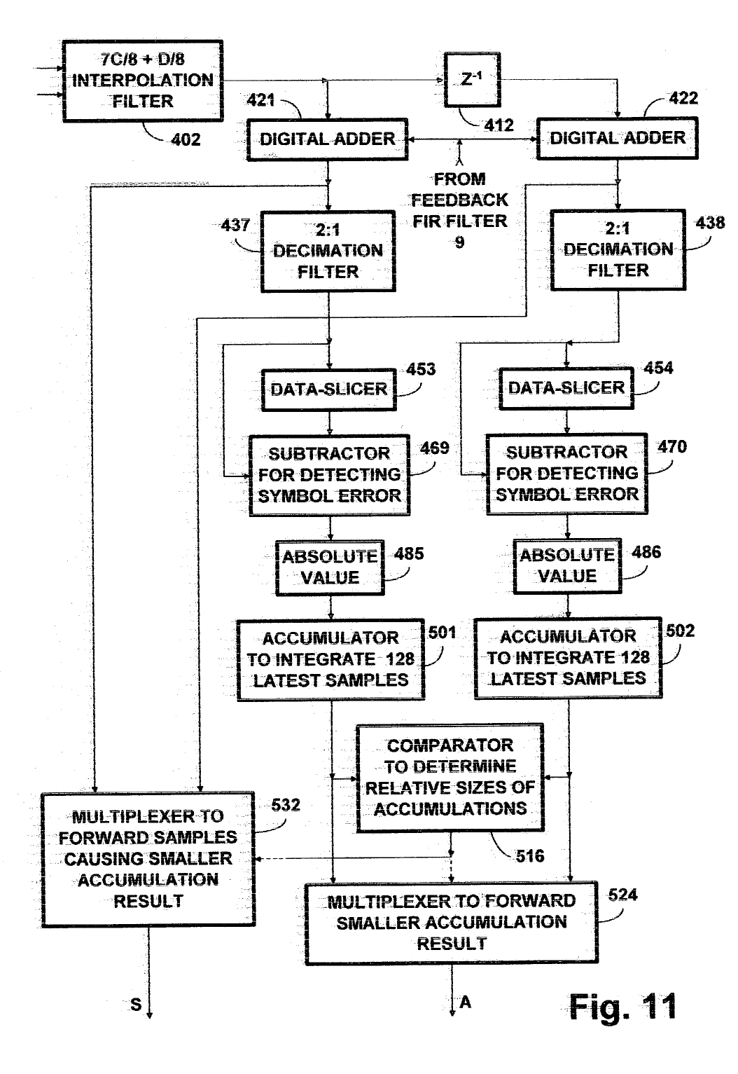

A comparator 515 compares the accumulation results from the accumulators 499 and 500 to generate a control bit that is a ZERO or a ONE depending whether or not the accumulation results arising from the first candidate equalizer output signal is judged to be smaller than the accumulation results arising from the second candidate equalizer output signal. A multiplexer 523 is connected for receiving as a first of two input signals thereto the accumulation results from the accumulator 499, for receiving as the second of the two input signals thereto the accumulation results from the accumulator 500, and for receiving the control bit from the comparator 515 as a control signal for determining which of the two input signals to the multiplexer 523 shall be reproduced in the output signal from the multiplexer 523. Responsive to the control bit from the comparator 523 being ZERO, the accumulation results from the accumulator 499 are reproduced in the multiplexer 523 output signal. Responsive to the control bit from the comparator 515 being ONE, the accumulation results from the accumulator 500 are reproduced in the multiplexer 523 output signal. The multiplexer 523 output signal is supplied as A (for accumulation) output signal from the FIG. 10 decision circuitry to be compared with the A output signal of the FIG. 11 decision circuitry in the second-stage decision circuitry shown in FIG. 18.

A multiplexer 531 connected for receiving as its two input signals the first candidate equalizer output signal from the digital adder 419 and the second candidate equalizer output signal from the digital adder 420. The multiplexer 531 is connected for receiving a control bit from the comparator 515 as a control signal, which control bit determines which of the input signals to the multiplexer 531 shall be reproduced in the output signal S (for samples) from the multiplexer 531. Responsive to the control bit from the comparator 515 being ZERO, the first candidate equalizer output signal from the digital adder 419 is reproduce in the multiplexer 531 output signal S. Responsive to the control bit from the comparator 515 being ONE, the second candidate equalizer output signal from the digital adder 420 is reproduced in the multiplexer 531 output signal S.

In FIG. 11 the digital adder 421 combines the feedback FIR filter 9 response with the interpolation filter 402 response to generate a third candidate equalizer output signal sampled at twice baud rate and applied as input signal to a 2:1 decimation filter 437. The response of the 2:1 decimation filter 437 is a third candidate equalizer output signal sampled at baud rate and applied as input signal to a data-slicer 453. The data-slicer 453 generates estimates of the symbols actually transmitted to give rise to the symbols in the third candidate equalizer output signal sampled at baud rate. A digital subtractor 469 differentially combines the symbols received in the third candidate equalizer output signal and the corresponding estimates of the symbols actually transmitted to give rise to those received symbols to determine the departures of the received symbols from symbols that could actually have been transmitted. An absolute-value circuit 485 determines the absolute value of each departure, which is supplied to an accumulator 501 that accumulates the absolute values of a prescribed number N of the most recent departures of the received symbols from symbols that could actually have been transmitted.

Similarly, the digital adder 422 combines the feedback FIR filter 9 response with the interpolation filter 402 response as delayed by the one-sample digital delay 412 to generate a fourth candidate equalizer output signal sampled at twice baud rate applied as input signal to a 2:1 decimation filter 438. The response of the 2:1 decimation filter 438 is a fourth candidate equalizer output signal sampled at baud rate and applied as input signal to a data-slicer 454. The data-slicer 454 generates estimates of the symbols actually transmitted to give rise to the symbols in the fourth candidate equalizer output signal sampled at baud rate. A digital subtractor 470 differentially combines the symbols received in the third candidate equalizer output signal and the corresponding estimates of the symbols actually transmitted to give rise to those received symbols to determine the departures of the received symbols from symbols that could actually have been transmitted. An absolute-value circuit 486 determines the absolute value of each departure, which is supplied to an accumulator 502 that accumulates the absolute values of the N most recent departures of the received symbols from symbols that could actually have been transmitted.

A comparator 516 compares the accumulation results from the accumulators 504 and 502 to generate a control bit that is a ZERO or a ONE depending on whether or not the accumulation results arising from the third candidate equalizer output signal is judged to be smaller than the accumulation results arising from the fourth candidate equalizer output signal. A multiplexer 524 is connected for receiving as a first of two input signal thereto the accumulation results from the accumulator 501, for receiving as the second of the two input signals thereto the accumulation results from the accumulator 502, and for receiving the control bit from the comparator 516 as a control signal for determining which of the two input signals to the multiplexer 524 shall be reproduced in the output signal from the multiplexer 524. Responsive to the control bit from the comparator 516 being ZERO, the accumulation results from the accumulator 501 are reproduced in the multiplexer 524 output signal. Responsive to the control bit from the comparator 516 being ONE, the accumulation results from the accumulator 502 are reproduced in the multiplexer 524 output signal. The multiplexer 524 output signal is supplied as A (for accumulation) output signal from the FIG. 11 decision circuitry to be compared with the A output signal of the FIG. 10 decision circuitry in the second-stage decision circuitry shown in FIG. 18.

A multiplexer 532 is connected for receiving as its two input signals the third candidate equalizer output signal from the digital adder 421 and the fourth candidate equalizer output signal from the digital adder 42. The multiplexer 532 is connected for receiving a control bit from the comparator 516 as a control signal, which control bit determines which of the input signals to the multiplexer 532 shall be reproduced in the output signal S (for samples) from the multiplexer 532. Responsive to the control bit from the comparator 516 being ZERO, the third candidate equalizer output signal from the digital adder 421 is reproduced in the multiplexer 532 output signal S. Responsive to the control bit from the comparator 516 being ONE, the fourth candidate equalizer output signal from the digital adder 422 is reproduced in the multiplexer 532 output signal S.

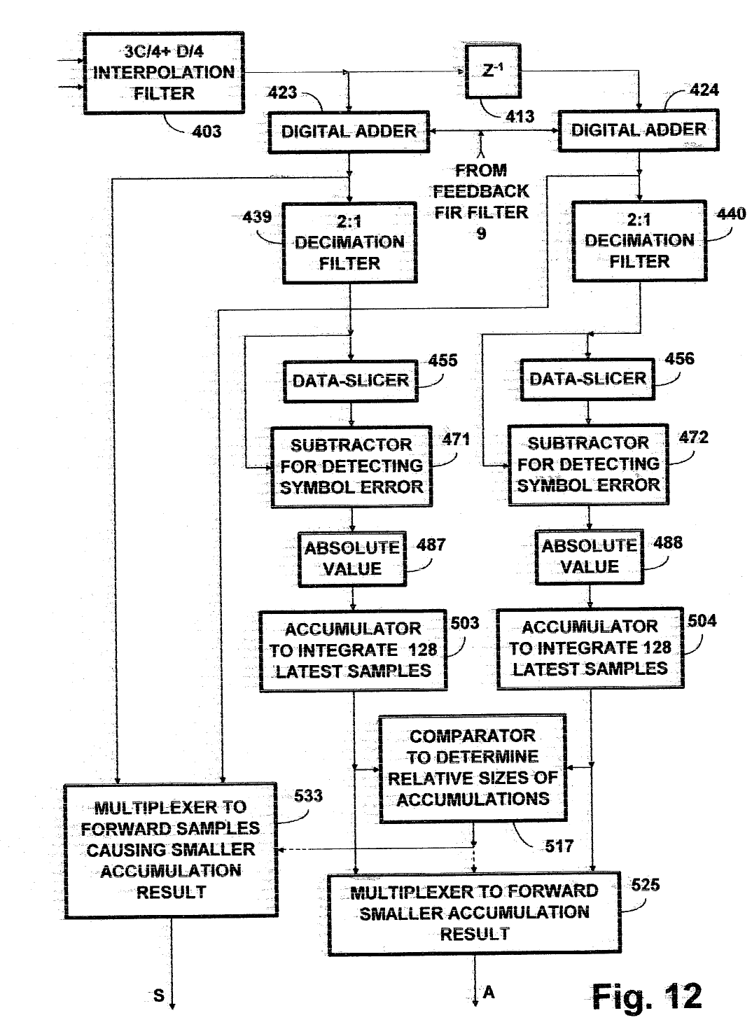

In FIG. 12 the digital adder 423 combines the feedback FIR filter 9 response with the interpolation filter 403 response to generate a fifth candidate equalizer output signal sampled at twice baud rate and applied as input signal to a 2:1 decimation filter 439. The response of the 2:1 decimation filter 439 is a fifth candidate equalizer output signal sampled at baud rate and applied as input signal to a data-slicer 455. The data-slicer 455 generates estimates of the symbols actually transmitted to give rise to the symbols in the fifth candidate equalizer output signal sampled at baud rate. A digital subtractor 471 differentially combines the symbols received in the fifth candidate equalizer output signal and the corresponding estimates of the symbols actually transmitted to give rise to those received symbols to determine the departures of the received symbols from symbols that could actually have been transmitted. An absolute-value circuit 487 determines the absolute value of each departure, which is supplied to an accumulator 503 that accumulates the absolute values of a prescribed number N of the most recent departures of the received symbols from symbols that could actually have been transmitted.

Similarly, the digital adder 424 combines the feedback FIR filter 9 response with the interpolation filter 403 response as delayed by the one-sample digital delay 413 to generate a sixth candidate equalizer output signal sampled at twice baud rate applied as input signal to a 2:1 decimation filter 440. The response of the 2:1 decimation filter 440 is a sixth candidate equalizer output signal sampled at baud rate and applied as input signal to a data-slicer 456. The data-slicer 456 generates estimates of the symbols actually transmitted to give rise to the symbols in the sixth candidate equalizer output signal sampled at baud rate. A digital subtractor 472 differentially combine the symbols received in the sixth candidate equalizer output signal and the corresponding estimates of the symbols actually transmitted to give rise to those received symbols to determine the departures of the received symbols from symbols that could actually have been transmitted. An absolute-value circuit 488 determines the absolute value of each departure, which is supplied to an accumulator 504 that accumulates the absolute values of the N most recent departures of the received symbols from symbols that could actually have been transmitted.

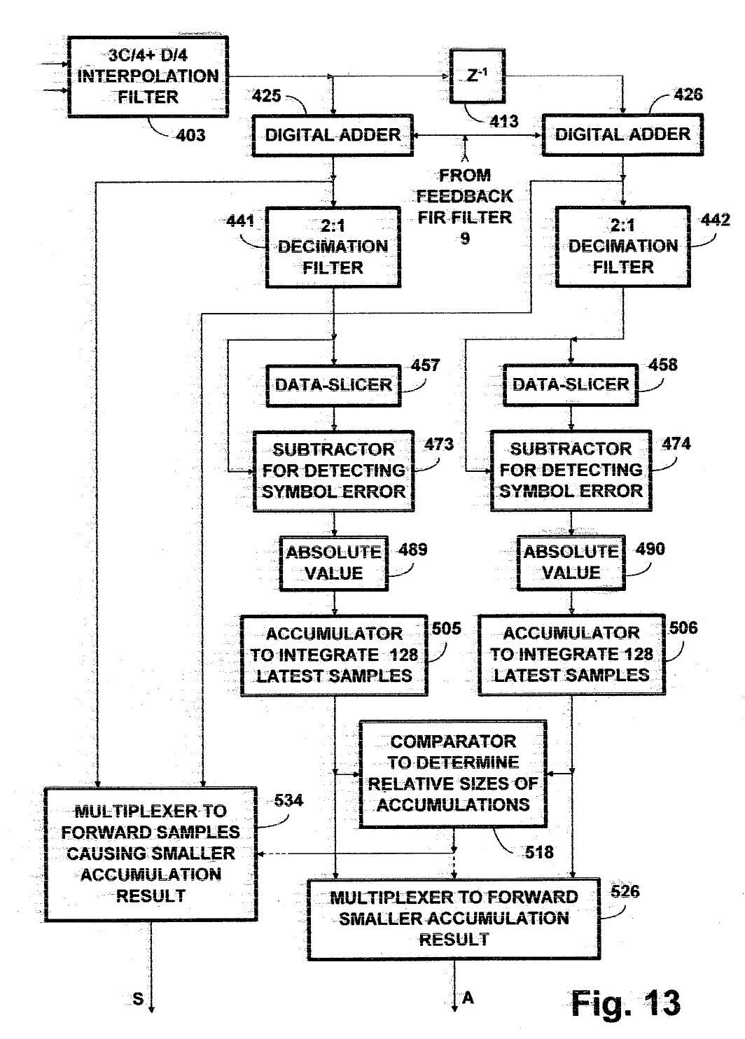

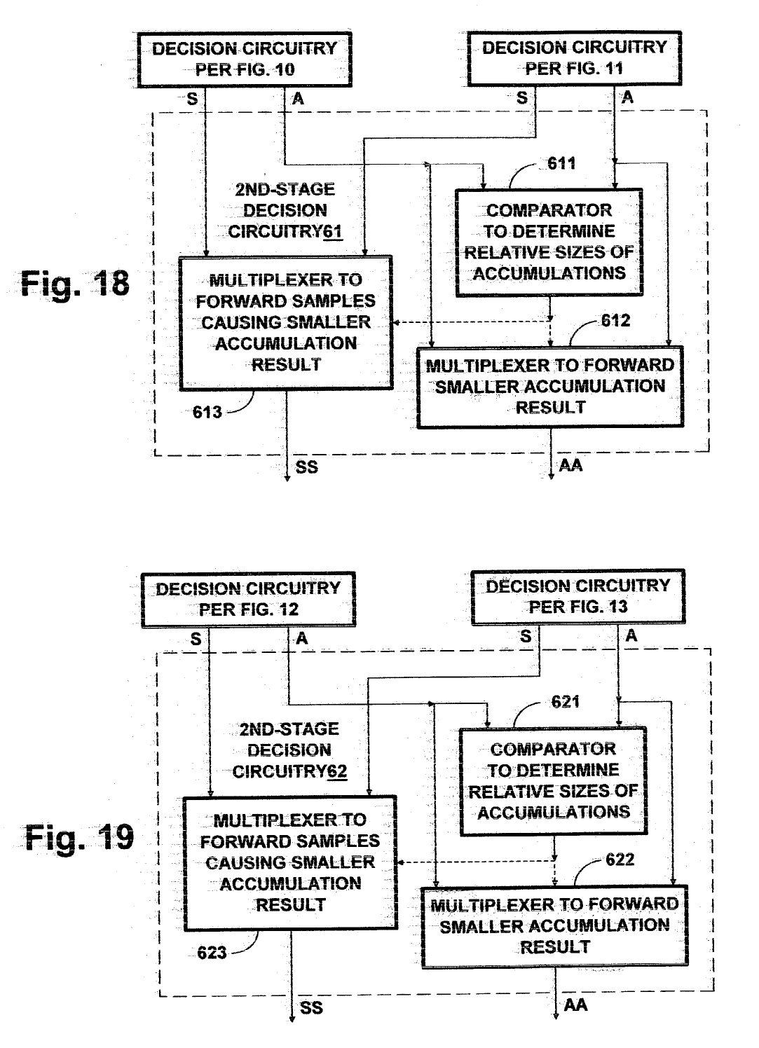

A comparator 517 compares the accumulation results of the accumulators 503 and 504 to generate a control bit that is a ZERO or a ONE depending on whether or not the accumulation results arising from the fifth candidate equalizer output signal is judged to be smaller than the accumulation results arising from the sixth candidate equalizer output signal. A multiplexer 525 is connected to receiving as a first of two input signals thereto the accumulation results from the accumulator 503, for receiving as the second of the two input signals thereto the accumulation results from the accumulator 504, and for receiving the control bit from the comparator 517 as a control signal for determining which of the two input signals to the multiplexer 525 shall be reproduced in the output signal from the multiplexer 525. Responsive to the control bit from the comparator 517 being ZERO, the accumulation results from the accumulator 503 are reproduced in the multiplexer 525 output signal. Responsive to the control bit from the comparator 517 being ONE, the accumulation results from the accumulator 504 are reproduced in the multiplexer 525 output signal. The multiplexer 525 output signal is supplied as A (for accumulation) output signal from the FIG. 12 decision circuitry to be compared with the A output signal of the FIG. 13 decision circuitry in the second-stage decision circuitry shown in FIG. 19.

A multiplexer 533 is connected for receiving as its two input signals the fifth candidate equalizer output signal from the digital adder 423 and the sixth candidate equalizer output signal from the digital adder 424. The multiplexer 533 is connected for receiving a control bit from the comparator 517 as a control signal, which control bit determines which of the input signals to the multiplexer 533 shall be reproduced in the output signal S (for samples) from the multiplexer 533. Responsive to the control bit from the comparator 517 being ZERO, the fifth candidate equalizer output signal from the digital adder 423 is reproduced in the multiplexer 533 output signal S. Responsive to the control bit from the comparator 517 being ONE, the sixth candidate equalizer output signal from the digital adder 424 is reproduced in the multiplexer 533 output signal S.

In FIG. 13 the digital adder 425 combines the feedback FIR filter 9 response with the interpolation filter 404 response to generate a seventh candidate equalizer output signal sampled at twice baud rate and applied as input signal to a 2:1 decimation filter 441. The response of the 2:1 decimation filter 441 is a seventh candidate equalizer output signal sampled at baud rate and applied as input signal to a data-slicer 457. The data-slicer 457 generates estimates of the symbols actually transmitted to give rise to the symbols in the seventh candidate equalizer output signal sampled at baud rate. A digital subtractor 473 differentially combines the symbols received in the seventh candidate equalizer output signal and the corresponding estimates of the symbols actually transmitted to the rise to those received symbols to determine the departures of the received symbols from symbols that could actually have been transmitted. An absolute-value circuit 489 determines the absolute value of each departure, which is supplied to an accumulator 505 that accumulates the absolute values of a prescribed number N of the most recent departures of the received symbols from symbols that could actually have been transmitted.

Similarly, the digital adder 426 combines the feedback FIR filter 9 response with the interpolation filter 404 response as delayed to the one-sample digital delay 414 to generate an eighth candidate equalizer output signal sampled at twice baud rate applied as input signal to a 2:1 decimation filter 442. The response of the 2:1 decimation filter 442 is an eighth candidate equalizer output signal sampled at baud rate and applied as input signal to a data-slicer 458. The data-slicer 458 generates estimates of the symbols actually transmitted to give rise to the symbols in the eighth candidate equalizer output signal sampled at baud rate. A digital subtractor 474 differentially combines the symbols received in the eighth candidate equalizer output signal and the corresponding estimates of the symbols actually transmitted to give rise to those received symbols to determine the departures of the received symbols from symbols that could actually have been transmitted. An absolute-value circuit 490 determines the absolute value of each departure, which is supplied to accumulator 506 that accumulates the absolute values of the N most recent departures of the received symbols from symbols that could actually have been transmitted.

A comparator 518 compares the accumulation results from the accumulators 505 and 506 to generate a control bit that is a ZERO or a ONE depending on whether or not the accumulation results arising from the seventh candidate equalizer output signal is judged to be smaller than the accumulation results arising from the eighth candidate equalizer output signal. A multiplexer 526 is connected for receiving as a first of two input signals thereto the accumulation results from the accumulator 505, for receiving as the second of the two input signals thereto the accumulation results from the accumulator 506, and for receiving the control bit from the comparator 518 as a control signal for determine which of the two input signals to the multiplexer 526 shall be reproduced in the output signal from the multiplexer 526. Responsive to the control bit from the comparator 518 being ZERO, the accumulation results from the accumulator 505 are reproduced in the multiplexer 526 output signal. Responsive to the control bit from the comparator 518 being ONE, the accumulation, results from the accumulator 506 are reproduced in the multiplexer 526 output signal. The multiplexer 526 output signal is supplied as A (for accumulation) output signal from the FIG. 13 decision circuitry to be compared with the A output signal of FIG. 12 decision circuitry in the second-stage decision circuitry shown in FIG. 19.

A multiplexer 534 is connected for receiving as its two input signals the seventh candidate equalizer output signal from the digital adder 425 and the eighth candidate equalizer output signal from the digital adder 426. The multiplexer 534 is connected for receiving a control bit from the comparator 518 as a control signal, which control bit determines which of the input signals to the multiplexer 534 shall be reproduced in the output signal S (for samples) from the multiplexer 534. Responsive to the control bit from the comparator 518 being ZERO, the seventh candidate equalizer output signal from the distal adder 425 is reproduced in the multiplexer 534 output signal S. Responsive to the control bit from the comparator 518 being ONE, the eighth candidate equalizer output signal from the digital adder 426 is reproduced in the multiplexer 534 output signal S.

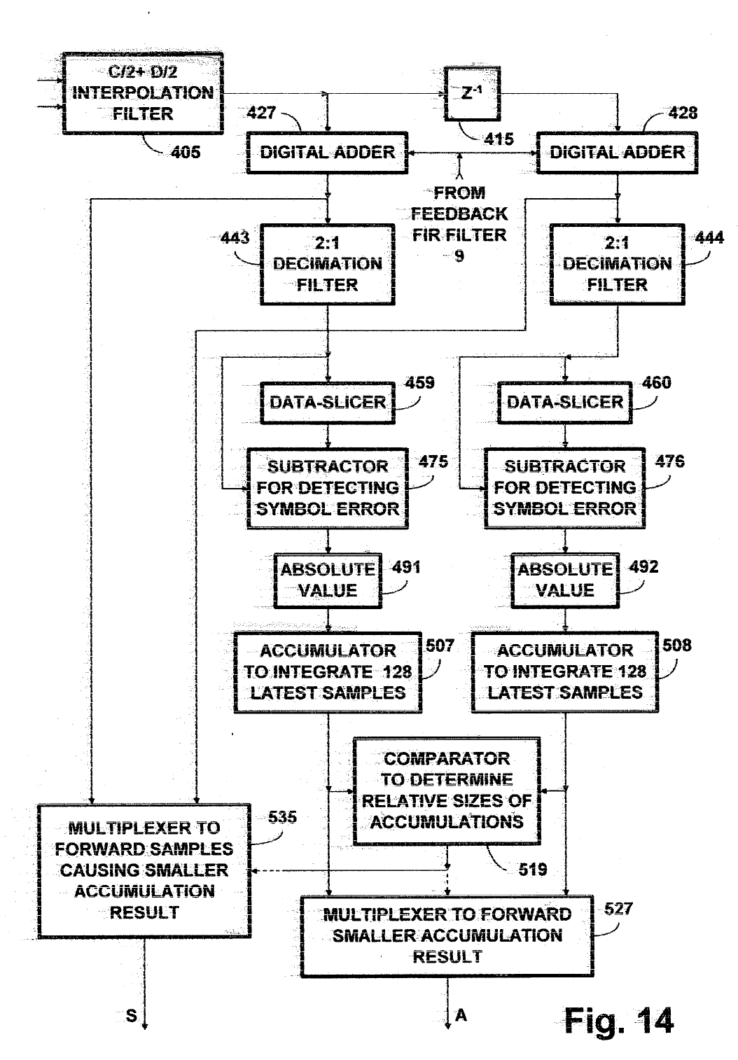

In FIG. 14 the digital adder 427 combines the feedback FIR filter 9 response with the interpolation filter 405 response to generate a ninth candidate equalizer output signal sampled at twice baud rate and applied as input signal to a 2:1 decimation filter 443. The response of the 2:1 decimation filter 443 is a ninth candidate equalizer output signal sampled at baud rate and applied as input signal to a data-slicer 459. The data-slicer 459 generates estimates of the symbols actually transmitted to give rise to the symbols in the ninth candidate equalizer output signal sampled at baud rate. A digital subtractor 475 differentially combines the symbols received in the ninth candidate equalizer output signal and the corresponding estimates of the symbols actually transmitted it give rise to those received symbols to determine the departure of the received symbols from symbols that could actually have been transmitted. An absolute-value circuit 491 determines the absolute value of each departure, which is supplied to an accumulator 507 that accumulates the absolute values of a prescribed number N of the most recent departures of the received symbols from symbols that could actually have been transmitted.

Similarly, the digital adder 428 combines the feedback FIR filter 9 response with the interpolation filter 405 response as delayed by the one-sample digital delay 415 to generate a tenth candidate equalizer output signal sampled at twice baud rate applied as input signal to a 2:1 decimation filter 444. The response of the 2:1 decimation filter 444 is a tenth candidate equalizer output signal sampled at baud rate and applied as input signal to a data-slicer 460. The data-slicer 460 generate estimates of the symbols actually transmitted to give rise to the symbols in the tenth candidate equalizer output signal sampled at baud rate. A digital subtractor 476 differentially combines the symbols received in the tenth candidate equalizer output signal and the corresponding estimates of the symbols actually transmitted to give rise to those received symbols to determine the departures of the received symbols that could actually have been transmitted. An absolute-value circuit 492 determines the absolute value of each departure, which is supplied to an accumulator 508 that accumulates the absolute values of the N most recent departures of the received symbols from symbols that could actually have been transmitted.

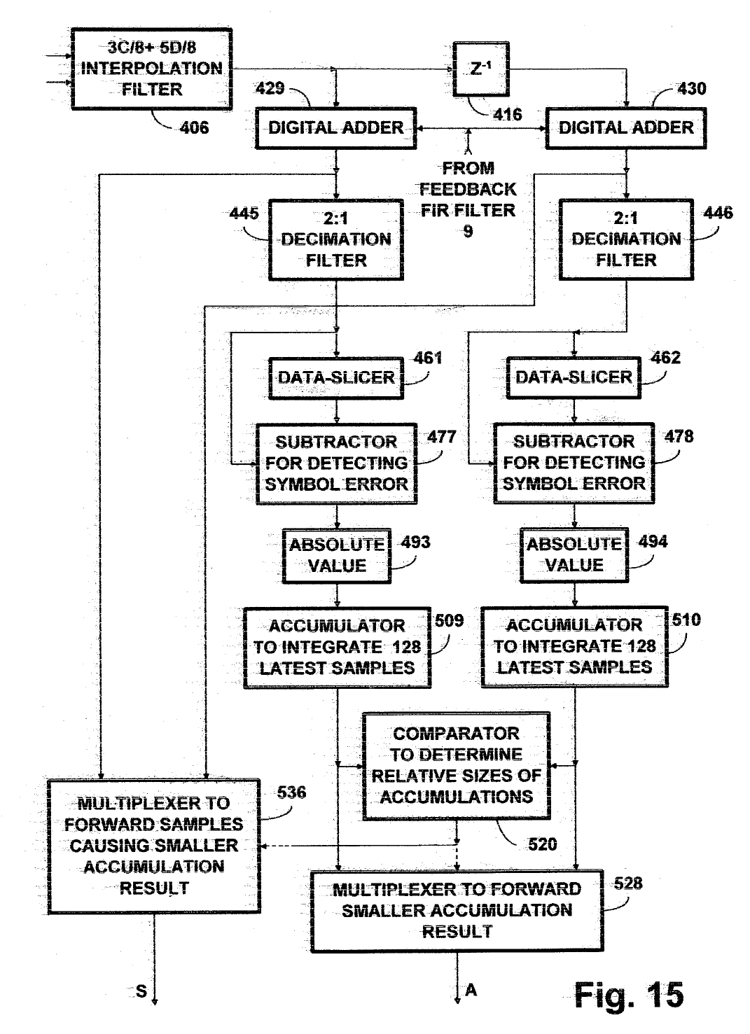

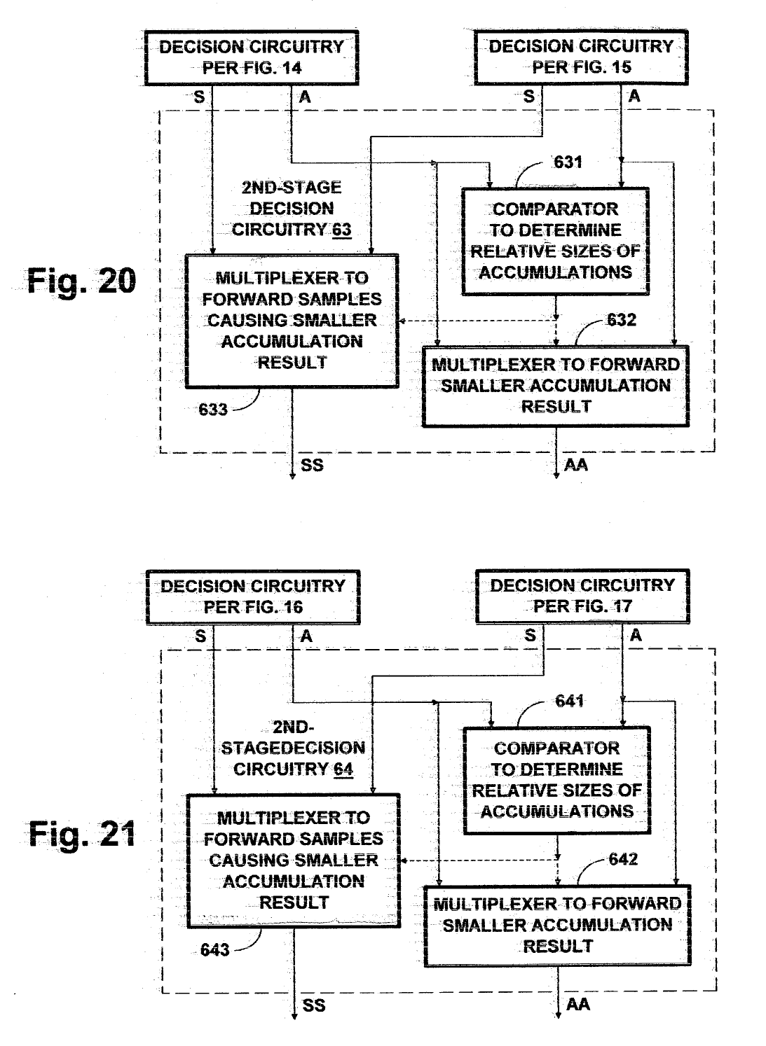

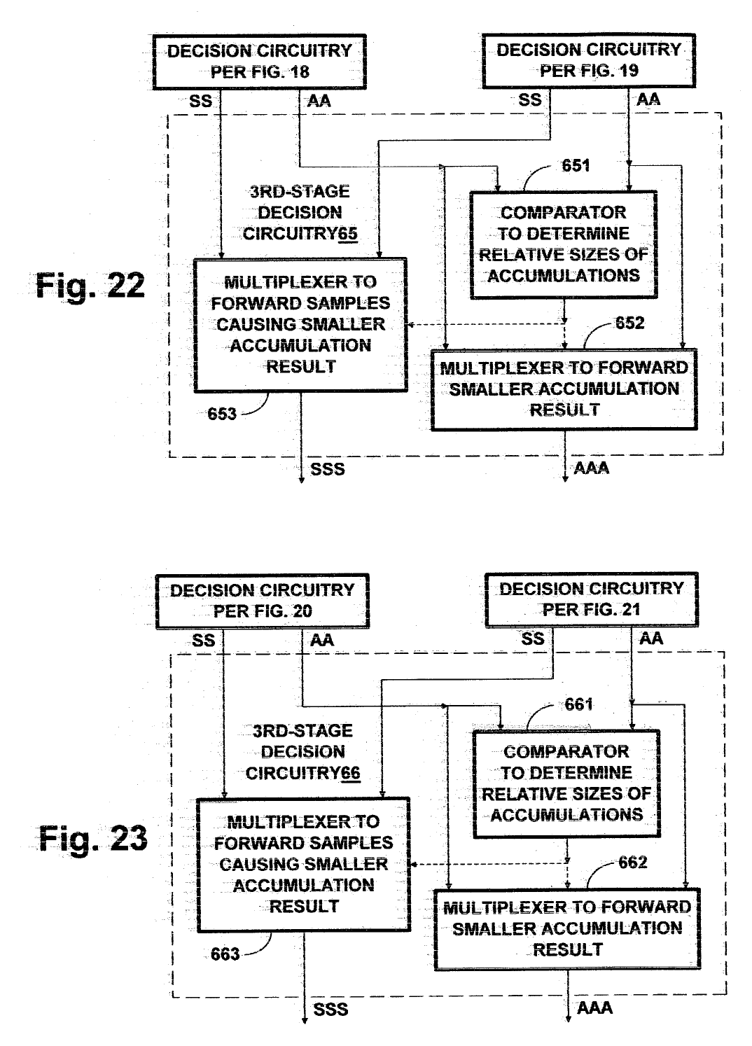

A comparator 519 compares the accumulation results from the accumulators 507 and 508 to generate a control bit that is a ZERO or a ONE depending on whether or not the accumulation results arising from the ninth candidate equalizer output signal is judged to be smaller than the accumulation results arising from the tenth candidate equalizer output signal. A multiplexer 527 is connected for receiving as a first of two input signals thereto the accumulation results from the accumulator 507, for receiving as the second of the two input signals thereto the accumulation results from the accumulator 508, and for receiving the control bit from the comparator 519 as a control signal for determining which of the to input signals to the multiplexer 527 shall be reproduced in the output signal from the multiplexer 527. Responsive to the control bit from the comparator 519 being ZERO, the accumulation results from the accumulator 507 are reproduced in the multiplexer 527 output signal. Responsive to the control bit from the comparator 519 being ONE, the accumulation results from the accumulator 508 are reproduced in the multiplexer 527 output signal. The multiplexer 527 output signal is supplied as A (for accumulation) output signal from the FIG. 14 decision circuitry to the compared with the A output signal of the FIG. 15 decision circuitry in the second-stage decision circuitry shown in FIG. 20.

A multiplexer 535 is connected for receiving as its two input signals the ninth candidate equalizer output signal from the digital adder 427 and the tenth candidate equalizer output signal from the digital adder 428. The multiplexer 535 is connected for receiving a control bit from the comparator 519 as a control signal, which control bit determines which of the input signals to the multiplexer 535 shall be reproduced in the output signal S (for samples) from the multiplexer 535. Responsive to the control bit from the comparator 519 being ZERO, the ninth candidate equalizer output signal from the digital adder 427 is reproduced in the multiplexer 535 output signal S. Responsive to the control bit from the comparator 519 being ONE, the tenth candidate equalizer output signal from the digital adder 428 is reproduced in the multiplexer 535 output signal S.

In FIG. 15 the digital adder 429 combines the feedback FIR filter 9 response with the interpolation filter 406 response to generate an eleventh candidate equalizer output signal sampled at twice baud rate and applied as input signal to a 2:1 decimation filter 445. The response of the 2:1 decimation filter 445 is an eleventh candidate equalizer output signal sampled at baud rate and applied as input signal to a data-slicer 461. The data-slicer 461 generates estimates of the symbols actually transmitted to give rise to the symbols in the eleventh candidate equalizer output signal sampled at baud rate. A digital subtractor 477 differently combines the symbol receives in the eleventh candidate equalizer output signal and the corresponding estimates of the symbols actually transmitted to give rise to those received symbols to determine the departures of the received symbols from symbols that could actually have been transmitted. An absolute-value circuit 493 determines these absolute value of each departure, which is supplied to an accumulator 509 that accumulates the absolute values of a prescribed number N of the most recent departures of the received symbols from symbols that could actually have been transmitted.

Similarly, the digital adder 430 combines the feedback FIR filter 9 response with the interpolation filter 406 response as delayed by the one-sample digital delay 416 to generate a twelfth candidate equalizer output signal sampled at twice baud rate applied as input signal to a 2:1 decimation filter 446. The response of the 2:1 decimation filter 446 is a twelfth candidate equalizer output signal sampled at baud rate and applied as input signal to a data-slicer 462. The data-slicer 462 generates estimates of the symbols actually transmitted to give rise to the symbols in the twelfth candidate equalizer output signal sampled at baud rate. A digital subtractor 478 differentially combines the symbols received in the twelfth candidate equalizer output signal and the corresponding estimates of the symbols actually transmitted to give rise to those received symbols to determine the departures of the received symbols from symbols that could actually have been transmitted. An absolute-value circuit 494 determines the absolute value of each departure, which is supplied to an accumulator 510 that accumulates the absolute values of the N most recent departures of the received symbols from symbols that could actually have been transmitted.

A comparator 520 compares the accumulator results from the accumulators 509 and 510 to generate a control bit that is a ZERO or a ONE depending on whether or not the accumulation results arising from the eleventh candidate equalizer output signal is judged to be smaller than the accumulation results arising from the twelfth candidate equalizer output signal. A multiplexer 528 is connected for receiving as a first of two input signals thereto the accumulation results from the accumulator 509, for receiving as the second of the two input signals thereto the accumulation results from the accumulator 510, and for receiving the control bit from the comparator 520 as a control signal for determining which of the two input signals to the multiplexer 528 shall be reproduced in the output signal from the multiplexer 528. Responsive to the control bit from the comparator 520 being ZERO, the accumulation results from the accumulator 509 are reproduced in the multiplexer 528 output signal. Responsive to the control bit from the comparator 520 being ONE, the accumulation results from the accumulator 510 are reproduced in the multiplexer 528 output signal. The multiplexer 528 output signal is supplied as A (for accumulation) output signal from the FIG. 15 decision circuitry to be compared with the A output signal of the FIG. 14 decision circuitry in the second-stage decision circuitry shown in FIG. 20.

A multiplexer 536 is connected for receiving as its two input signals the eleventh candidate equalizer output signal from the digital adder 429 and the twelfth candidate equalizer output signal from the digital adder 430. The multiplexer 536 is connected for receiving a control bit from the comparator 520 as a control signal, which control bit determines which of the input signals to the multiplexer 536 shall he reproduced in the output signal S (for samples) from the multiplexer 536. Responsive to the control bit from the comparator 520 being ZERO, the eleventh candidate equalizer output signal from the digital adder 429 is reproduced in the multiplexer 536 output signal S. Responsive to the control bit from the comparator 520 being ONE, the twelfth candidate equalizer output signal from the digital adder 430 is reproduced in the multiplexer 536 output signal S.

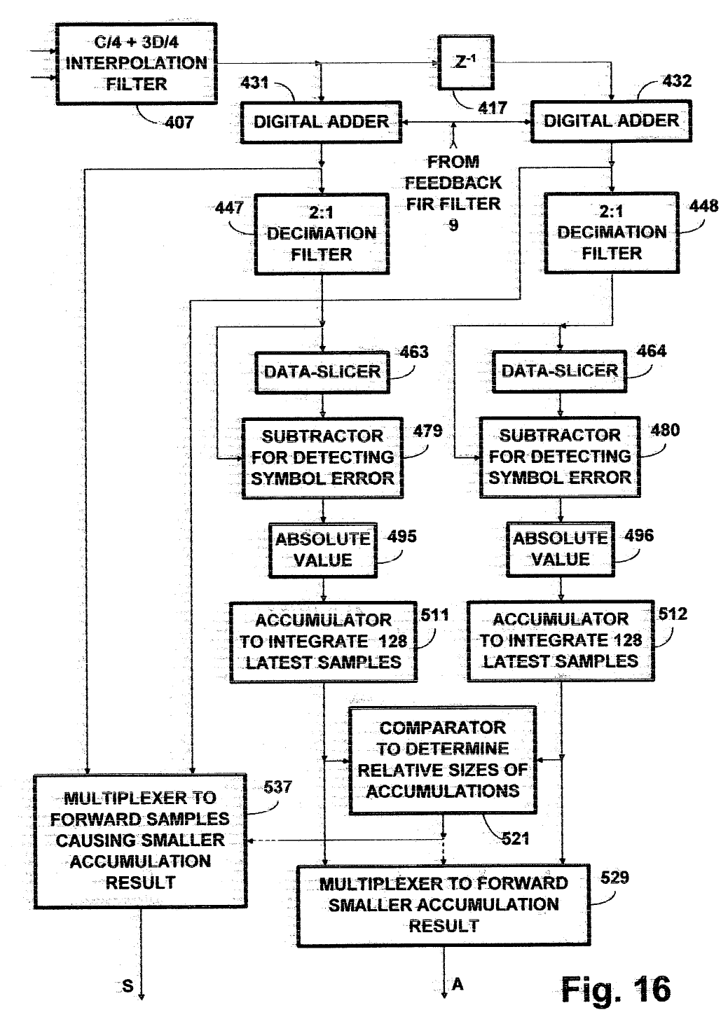

In FIG. 16 the digital adder 431 combines the feedback FIR filter 9 response with the interpolation filter 407 response to generate a eleventh candidate equalizer output signal sampled at twice baud rate and applied as input signal to a 2:1 decimation filter 447. The response of the 2:1 decimation filter 447 is a thirteenth candidate equalizer output signal sampled at baud rate and applied as input signal to a data-slicer 463. The data-slicer 463 generates estimates of the symbols actually transmitted to give rise to the symbols in the thirteenth candidate equalizer output signal sampled at baud rate. Additional subtractor 479 differentially combines the symbols receiving in the thirteenth candidate equalizer output signal and the corresponding estimates of the symbols actually transmitted to give rise to those received symbols to determine the departure of the received symbols from symbols that could actually have been transmitted. An absolute-value circuit 495 determines the absolute value of each departure, which is supplied to an accumulator 511 that accumulates the absolute values of a prescribed number N of the most recent departures of the recent symbols from symbols that could actually have been transmitted.

Similarly, the digital adder 432 combines the feedback FIR filter 9 response with the interpolation filter 407 responds as delayed by the one-sample digital delay 417 to generate a fourteenth candidate equalizer output signal sampled at twice baud rate applied as input signal to a 2:1 decimation filter 448. The response of the 2:1 decimation filter 448 is a fourteenth candidate equalizer output signal sampled at baud rate and applied as input signal to a data-slicer 464. The data-slicer 464 generates estimates of the symbols actually transmitted to give rise to the symbols in the fourteenth candidate equalizer output signal sampled at baud rate. A digital subtractor 480 differentially combines the symbols received in the fourteenth candidate equalizer output signal and the corresponding estimates of the symbols actually transmitted to give rise to those received symbols to determine the departures of the received symbols from symbols that could actually have been transmitted. An absolute-value circuit 496 determines the absolute value of each departure, which is supplied to an accumulator 512 that accumulates the absolute values of the N most recent departures of the received symbols from symbol that could actually have been transmitted.

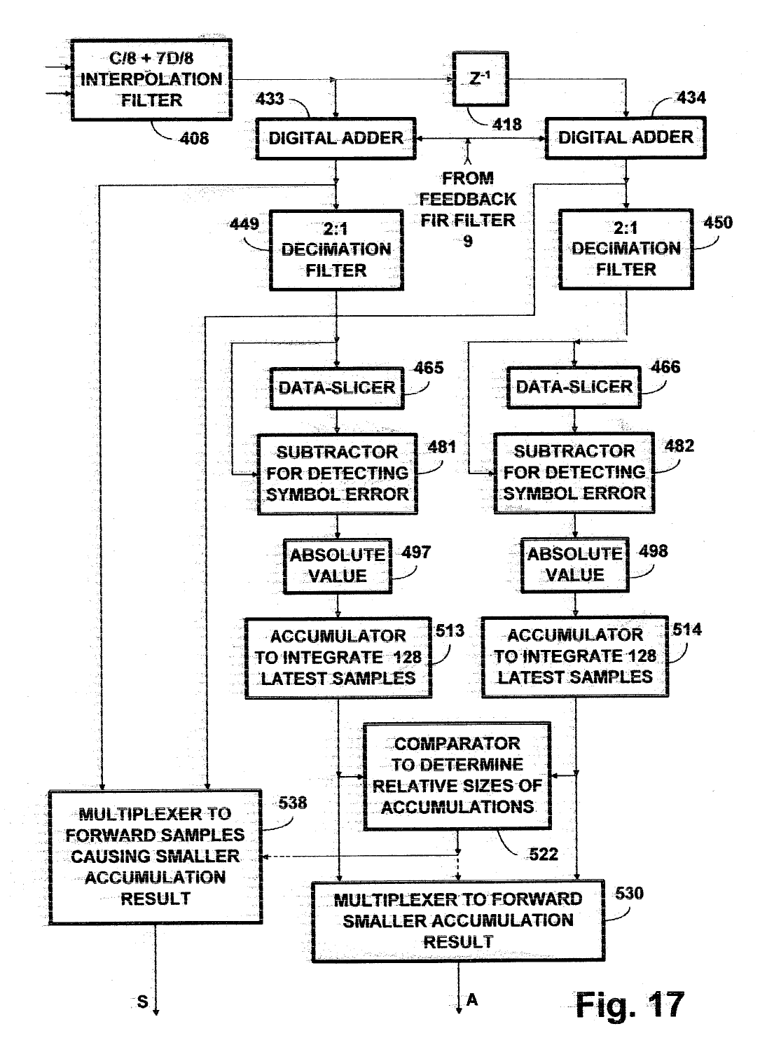

A comparator 521 compares the accumulation results from the accumulators 511 and 512 to generate a control bit that is a ZERO or a ONE depending on whether or not the accumulation the results arising from the thirteenth candidate equalizer output signal is judged to be smaller than the accumulation results arising from the fourteenth candidate equalizer output signal. A multiplexer 529 is connected for receiving as a first of two input signals thereto the accumulation results from the accumulator 511, for receiving as the second of the two input signals thereto the accumulation results from the accumulator 512, and for receiving the control bit from the comparator 521 as a control signal for determining which of the two input signals to the multiplexer 529 shall be reproduced in the output signal from the multiplexer 529. Responsive to the control bit from the comparator 521 being ZERO, the accumulation results from the accumulator 511 are reproduced in the multiplexer 529 output signal. Responsive to the control bit from the comparator 521 being ONE, the accumulation results from the accumulator 512 are reproduced in the multiplexer 529 output signal. The multiplexer 529 output signal is supplied as A (for accumulation) output signal from the FIG. 16 decision circuitry to be compared with the A output signal of the FIG. 17 decision circuitry the second-stage decision circuitry shown in FIG. 21.

A multiplexer 537 is connected for receiving as its two input signals the thirteenth candidate equalizer output signal from the digital adder 431 and the fourteenth candidate equalizer output signal from the digital adder 432. The multiplexer 537 is connected for receiving a control bit from the comparator 521 as a control signal, which control bit determines which of the input signals to the multiplexer 537 shall be reproduced in the output signal S (for samples) from the multiplexer 537. Responsive to the control bit from the comparator 521 being ZERO, the thirteenth candidate equalizer output signal from the digital adder 431 is reproduced in the multiplexer 537 output signal S. Responsive to the control bit from the comparator 521 being ONE, the fourteenth candidate equalizer output signal from the digital adder 432 is reproduced in the multiplexer 537 output signal S.

In FIG. 17 the digital adder 433 combines the feedback FIR filter 9 response with the interpolation filter 408 response to generate fifteenth candidate equalizer output signal sampled at twice baud rate and applied as input signal to a 2:1 decimation filter 449. The response of the 2:1 decimation filter 449 is a fifteenth candidate equalizer output signal sampled at baud rate and applied as input signal to a data-slicer 465. The data-slicer 465 generates estimates of the symbols actually transmitted to give rise to the symbols to the fifteenth candidate equalizer output signal sampled at baud rate. A digital subtractor 481 differentially combines the symbols received in the fifteenth candidate equalizer output signal and the corresponding estimates of the symbols actually transmitted to give rise to those received symbols to determine the departure of the received symbols from symbols that could actually have been transmitted. An absolute-value circuit 497 determines the absolute value of each departure, which is supplied to an accumulator 513 that accumulates the absolute values of a prescribed number N of the most recent departures of received symbols from symbols that could actually have been transmitted.

Similarly, the digital adder 434 combines the feedback FIR filter 9 response with the interpolation filter 408 response as delayed by the one-sample digital delay 418 to generate a sixteenth candidate equalizer output signal sampled at twice baud rate applied as input signal to a 2:1 decimation filter 450. The response of the 2:1 decimation filter 450 is a sixteenth candidate equalizer output signal sampled at baud rate and applied as input signal to a data-slicer 466. The data-slicer 466 generates estimates of the symbols actually transmitted to give rise to the symbols in the sixteenth candidate equalizer output signal sampled at baud rate. A digital subtractor 480 differentially combines the symbols received in the sixteenth candidate equalizer signal and the corresponding estimates of the symbols actually transmitted to give rise to those received symbols to determine then departures of the received symbols from symbols that could actually have been transmitted. An absolute value circuit 498 determines the absolute values of each departure, which is supplied to an accumulator 514 that accumulates the absolute values of the N most recent-departures of the received symbols from symbols that could actually have been transmitted.

A comparator 522 compares the accumulation results from the accumulators 513 and 514 to generate a control bit that is a ZERO or a ONE depending on whether or not the accumulation results arising from the fifteenth candidate equalizer output signal is judged to be smaller than the accumulation results arising from the sixteenth candidate equalizer output signal. A multiplexer 530 is connected for receiving as a first of to input signals thereto the accumulation results from the accumulator 513, for receiving as the second of two input signals thereto the accumulation results from the accumulator 514, and for receiving the control bit from the comparator 522 as a control signal from determining which of the two input signals to the multiplexer 530 shall be reproduced in the output signal from the multiplexer 530. Responsive to the control bit from the comparator 522 being ZERO, the accumulation results from the accumulator 513 are reproduced in the multiplexer output signal. Responsive to the control bit from the comparator 522 being ONE, the accumulation rising from the accumulator 514 are reproduced in the multiplexer 530 output signal. The multiplexer 530 output signal is supplied as A (for accumulation) output signal from the FIG. 17 decision circuitry to be compared with the A output signal of the FIG. 16 decision circuit in the second-stage decision circuitry shown in FIG. 21.

A multiplexer 538 is connected for receiving as its two input signals the fifteenth candidate equalizer output signal from the digital adder 433 and the sixteenth candidate equalizer output signal from the digital adder 434. The multiplexer 538 is connected for receiving a control bit from the comparator 522 as a control signal, which control bit determines which of the input signals to the multiplexer 538 shall be reproduced in the output signal S (for samples) from the multiplexer 538. Responsive to the control bit from the comparator 522 being ZERO, the fifteenth candidate equalizer output signal from the digital adder 433 is reproduced in the multiplexer 538 output signal S. Responsive to the control bit from the comparator 522 being ONE, the sixteenth candidate equalizer output signal from the digital adder 434 is reproduced in the multiplexer 538 output signal S.

FIGS. 18, 19, 20 and 21 shown the second stages of the tree-type selection apparatus. FIG. 18 shows second-stage decision circular 61 responsive to the first-stage decision circuitry of FIGS. 10 and 11. A comparator 611 within the decision circuitry 61 compares the A output signals from the FIG. 10 circuitry and from the FIG. 11 circuitry to generate a control bit. This control bit is a ZERO or a ONE depending on whether or not the A output signal from the FIG. 10 circuitry is judged to be smaller than the A output signal from the FIG. 11 circuitry. A multiplexer 612 with the decision circuitry 61 is connected for receiving as its two input signals the A output signals from the FIG. 10 circuitry and from the FIG. 11 circuitry. The multiplexer 612 is further connected for receiving the control bit from the comparator 611 as a control signal that determines which of the two input signals to the multiplexer 612 shall be reproduced in the multiplexer 61 output signal. Responsive to the control bit from the comparator 611 being ZERO, the A output signal from the FIG. 10 circuitry is reproduced in the multiplexer 612 output signal. Responsive to the control bit from the comparator 611 being ONE, the A output signal from the FIG. 11 circuitry is reproduced in the multiplexer 612 output signal. The multiplexer 612 output signal is supplied as AA output signal from the FIG. 18 apparatus.

A multiplexer 613 within the decision circuitry 61 is connected for receiving as its two input signals the S output signals from the FIG. 10 circuitry and from the FIG. 11 circuitry. The multiplexer 613 is further connected for receiving the control bit from the comparator 611 as a control signal that determines which of the two input signals to the multiplexer 613 shall be reproduced in the output signal from the multiplexer 613. Responsive to the control bit from the comparator 611 being ZERO, the S output signal from the FIG. 10 circuitry is reproduced in the multiplexer 613 output signal. Responsive to the control bit from the comparator 611 being ONE, the S output signal from the FIG. 11 circuitry is reproduced in the multiplexer 613 output signal. The multiplexer 613 output signal is supplied as SS output signal from the FIG. 18 apparatus.

FIG. 19 shows second-stage decision circuitry 62 responsive to the first stage decision circuitry of FIGS. 12 and 13. A comparator 621 within the decision circuitry 62 compares the A output signals from the FIG. 12 circuitry and from the FIG. 13 circuitry to generate a control bit. This control bit is a ZERO or a ONE depending on whether or not the A output signal from the FIG. 12 circuitry is judged to be smaller than the A output signal from the FIG. 13 circuitry. A multiplexer 622 within the decision circuitry 62 is connected for receiving as its two input signals the A output signals from the FIG. 12 circuitry and from the FIG. 13 circuitry. The multiplexer 622 is further connected for receiving the control bit from the comparator 621 as a control signal that determines which of the two input signals to the multiplexer 622 shall be reproduced in the multiplexer 622 output signal. Responsive to the control bit from the comparator 621 being ZERO, the A output signal from the FIG. 12 circuitry is reproduced in the multiplexer 622 output signal. Responsive to the control bit from the comparator 621 being ONE, the A output signal from the FIG. 13 circuitry is reproduced in the multiplexer 622 output signal. The multiplexer 622 output signal is supplied as AA output signal from the FIG. 19 apparatus.

A multiplexer 623 within the decision circuitry 62 is connected for receiving as its two input signals the S output signals from the FIG. 12 circuitry and from the FIG. 13 circuitry. The multiplexer 623 is further connected for receiving the control bit from the comparator 621 as a control signal that determines which of the two input signals to the multiplexer 623 shall be reproduced in the output signal from the multiplexer 623. Responsive to the control bit from the comparator 621 being ZERO, the S output signal from the FIG. 12 circuitry is reproduced in the multiplexer 623 output signal. Responsive to the control bit from the comparator 621 being ONE, the S output signal from the FIG. 13 circuitry is reproduced in the multiplexer 623 output signal. The multiplexer 623 output signal is supplied as SS output signal from the FIG. 19 apparatus.

FIG. 20 shows second stage decision circuitry 63 responsive to the first-stage decision circuitry of FIGS. 14 and 15. A comparator 631 within the decision circuitry 63 compares the A output signals from the FIG. 14 circuitry and from the FIG. 15 circuitry to generate a control bit. This control bit is a ZERO or a ONE depending on whether or not the A output signal from the FIG. 14 circuitry is judged to be smaller than the A output signal from the FIG. 15 circuitry. A multiplexer 632 within the decision circuitry 63 is connected for receiving as its two input signals the A output signals from the FIG. 14 circuitry and from the FIG. 15 circuitry. The multiplexer 632 is further connected for receiving the control bit from the comparator 631 as a control signal that determines which of the two input signals to the multiplexer 632 shall be reproduced in the multiplexer 632 output signal. Responsive to the control bit from the comparator 631 being ZERO, the A output signal from the FIG. 14 circuitry is reproduced in the multiplexer 632 output signal. Responsive to the control bit from the comparator 631 being ONE, the A output signal from the FIG. 15 circuitry is reproduced in the multiplexer 632 output signal. The multiplexer 632 output signal is supplied as AA output signal from the FIG. 20 apparatus.

A multiplexer 633 within the decision circuitry 63 is connected for receiving as its two input signals the S output signals from the FIG. 14 circuitry and from the FIG. 15 circuitry. The multiplexer 633 is further connected for receiving the control bit from the comparator 631 as a control signal that determines which of the two input signals to the multiplexer 633 shall be reproduced in the output signal from the multiplexer 633. Responsive to the control bit from the comparator 631 being ZERO; the S output signal from the FIG. 14 circuitry is reproduced in the multiplexer 633 output signal. Responsive to the control bit from the comparator 631 being ONE, the S output signal from the FIG. 15 circuitry is reproduced in the multiplexer 633 output signal. The multiplexer 633 output signal is supplied as SS output signal from the FIG. 20 apparatus.

FIG. 21 shows second-stage decision circuitry 64 responsive to the first-stage decision circuitry of FIGS. 16 and 17. A comparator 641 within the decision circuitry 64 compares the A output signals from the FIG. 16 circuitry and from the FIG. 17 circuitry to generate a control bit. This control bit is a ZERO or a ONE depending on whether or not the A output signal from the FIG. 16 circuitry is judged to be smaller than the A output signal from the FIG. 17 circuitry. A multiplexer 642 within the decision circuitry 64 is connected for receiving as its own input signals the A output signals from the FIG. 16 circuitry and from the FIG. 17 circuitry. The multiplexer 642 is further connected for receiving the control bit from the comparator 641 as a control signal that determines which of the two input signals to the multiplexer 642 shall be reproduced in the multiplexer 642 output signal. Responsive to the control bit from the comparator 641 being ZERO, the A output signal from the FIG. 16 circuitry is reproduced in the multiplexer 642 output signal. Responsive to the control bit from the comparator 641 being ONE, the A output signal from the FIG. 17 circuitry is reproduced in the multiplexer 642 output signal. The multiplexer 642 output signal is supplied as AA output signal from the FIG. 21 apparatus.

A multiplexer 643 within the decision circuitry 64 is connected for receiving as its two input signals the output signals from the FIG. 16 circuitry and from the FIG. 17 circuitry. The multiplexer 643 is further connected for receiving the control bit from the comparator 641 as a control signal that determines which of the two input signals to the multiplexer 643 shall be reproduced in the output signal from the multiplexer 643. Responsive to the control bit from the comparator 641 being ZERO, the S output signal from the FIG. 16 circuitry is introduced in the multiplexer 643 output signal. Responsive to the control bit from the comparator 641 being ONE, the S output signal from the FIG. 17 circuitry is reproduced in the multiplexer 643 output signal. The multiplexer 643 output signal is supplied as SS output signal from the FIG. 21 apparatus.

FIGS. 22 and 23 show the third stages of the tree-type selection apparatus. FIG. 22 shows third-stage decision circuitry 65 responsive to the second-stage decision circuitry 61 of FIG. 18 and to the second-stage decision circuitry 62 of FIG. 19. A comparator 651 within the decision circuitry 65 compares the AA output signals from the FIG. 18 circuitry and from the FIG. 19 circuitry to generate a control bit this control bit is a ZERO or a ONE depending on whether or not the AA output signal from the FIG. 18 circuitry is judged to be smaller than the AA output signal from the FIG. 19 circuitry. A multiplexer 652 within the decision circuitry 65 is connected for receiving as its two input signals the AA output signals from the FIG. 18 circuitry and from the FIG. 19 circuitry. The multiplexer 652 is further connected or receiving the control bit from the comparator 651 as a control signal that determines which of the two input signals to the multiplexer 652 shall be reproduced in the multiplexer 652 output signal. Responsive to the control bit from the comparator 651 being ZERO, the AA output signal from the FIG. 18 circuitry is reproduced in the multiplexer 652 output signal. Responsive to the control bit from the comparator 651 being ONE, the AA output signal from the FIG. 19 circuitry is reproduced in the multiplexer 652 output signal. The multiplexer 652 output signal is supplied as AAA output signal from the FIG. 22 apparatus.

A multiplexer 653 within the decision circuitry 65 is connected for receiving as its two input signals the SS output signals from the FIG. 18 circuitry and from the FIG. 19 circuitry. The multiplexer 653 is further connected for receiving the control bit from the comparator 651 as a control signal that determines which of the two input signals to the multiplexer 653 shall be reproduced in the output signal from the multiplexer 653. Responsive to the control bit from the comparator 651 being ZERO, the SS output signal from the FIG. 18 circuitry is reproduced in the multiplexer 653 output signal. Responsive to the control bit from the comparator 651 being ONE, the SS output signal from the FIG. 19 circuitry is reproduced in the multiplexer 653 output signal. The multiplexer 653 output signal is supplied as SSS output signal from the FIG. 22 apparatus.

FIG. 23 shows third-stage decision circuitry 66 responsive to the second-stage decision circuitry 63 of FIG. 20 and to the second-stage decision circuitry 64 of FIG. 21. A comparator 661 within the decision circuitry 66 compares the AA output signals from the FIG. 20 circuitry and from the FIG. 21 circuitry to generate a control bit. This control bit is a ZERO or a ONE depending on whether or not the AA output signal from the FIG. 20 circuitry is judged to be smaller that the AA output signal from the FIG. 21 circuitry. AA multiplexer 662 within the decision circuitry 66 is connected for receiving as its two input signals the AA output signals from the FIG. 20 circuitry and from the FIG. 21 circuitry. The multiplexer 662 is further connected for receiving the control bit from the comparator 661 as a control signal that determines which of the two input signals to the multiplexer 662 shall be reproduced in the multiplexer 662 output signal. Responsive to the control bit from the comparator 661 being ZERO, the AA output signal from the FIG. 20 circuitry is reproduced in the multiplexer 662 output signal. Responsive to the control bit from the comparator 661 being ONE, the AA output signal from the FIG. 21 circuitry is reproduced in the multiplexer 662 output signal. The multiplexer 662 output signal is supplied as AAA output signal from the FIG. 23 apparatus.

A multiplexer 663 will not be the decision circuitry 66 is connected for determining as its two input signals the SS output signals from the FIG. 20 circuitry and from the FIG. 21 circuitry. The multiplexer 663 is further connected for receiving the control bit from the comparator 661 as a control signal that determines which of the two input signals to the multiplexer 663 shall be reproduced in the output signal from the multiplexer 663. Responsive to the control bit from the comparator 661 being ZERO, and SS output signal from the FIG. 20 circuitry is reproduced in the multiplexer 663 output signal. Responsive to the control bit from the comparator 661 being ONE, the SS output signal from the FIG. 21 circuitry is reproduced in the multiplexer 663 output signal. The multiplexer 663 output signal is supplied as SSS output signal from the FIG. 23 apparatus.

FIG. 24 shows how fourth-stage decision circuits 67 implements a selection between SSS output signals from the third-stage decision circuitry 65 of FIG. 22 and from the decision circuitry 66 of FIG. 23. A comparator 671 within the decision circuitry 67 compares the AAA output signals from the decision circuits 65 and from the decision circuitry 66 to generate a control bit. The control bit is a ZERO or a ONE depending on whether or not the AAA output signal from the decision circuitry 65 is judged to be smaller than the AAA output signal from the decision circuit 66. A multiplexer 672 within the decision circuitry 67 is connected for receiving as its two input signals the SSS output signals from the decision circuitry 65 and from the decision circuitry 66. The multiplexer 672 is further connected for receiving the control bit from the comparator 671 as a control signal that determines which of the two input signals to the multiplexer 672 shall be reproduced in the multiplexer 672 output signal. Responsive to the control bit from the comparator 671 being ZERO, the SSS output signal from the decision circuitry 65 is reproduced in the multiplexer 672 output signal. Responsive to the control bit from the comparator 661 being ONE, the SSS output signal from the decision circuitry 66 is reproduced in the multiplexer 672 output signal.

The multiplexer 672 output signal is supplied as output signal from the fourth-stage decision circuitry 67, which output signal is applied as input signal of the 2:1 decimation filter 6 and to a digital delay circuit 116. The candidate twice-baud-rate equalizer response selected as multiplexer 672 output signal is decimated by the 2:1 decimation filter 6 to provide baud-rate equalizer output signal, suitable for application to the data-slicer 7 as input signal thereto. The circuitry 8 re-samples the baud-rate data-slicer 7 response to twice baud rate to generate an over-sampled data-slicer response. This over-sampled data-slicer response is applied as input signal to the feedback FIR filter 9. Rather than the feedback FIR filter 9 response being applied as summand input signal to a single digital adder 5 as shown in FIG. 1, the feedback FIR filter 9 response is applied as summand input signal to each of the digital adders 410-434 in FIGS. 10-17.

The 2:1 decimation filter 6 response is supplied as input signal to a trellis decoder 10, which operates as a symbol decoder for supplying data to the rest of the receiver. The trellis coder 14 codes the data recovered by the trellis decoder 10 to generate symbols used as estimates of the symbols that the transmitter broadcast to receivers. These symbols are supplied to circuitry 15 for re-sampling them to twice baud rate. The samples of equalizer response supplied at twice baud rate as output signal from the digital adder 5 are delayed by digital delay circuitry 16. The delay circuitry 116 compensates for the latent delay of the cascade connection of the 2:1 decimation filler 6, the trellis decoder 10, the trellis coder 14 and the circuitry 15 for re-sampling the trellis coder 14 output signal to twice baud rate. The error detector 17 generates reception error measurements by comparing the delayed twice-baud-rate equalizer response supplied by the delay circuitry 116 with the twice-baud-rate symbol stream supplied by the circuitry 15 for re-sampling the trellis coder 14 output signal. The reception errors detected by the error detector 17 are applied as multiplicand input signal to the digital multiplier 18, for multiplication by a factor μ. The digital multiplier 18 is connected to supply is product output signal as a further input signal to the filter coefficients computer 13, which uses the error measurements in the data-directed method of computing adjustments to the weighting coefficients of the FIR filters 3 and 9.

FIG. 25 shows a species 1100 of the slave phase-tracker 11 that is particularly suited to use in a receiver using a master phase-tracker 400 as shown in FIG. 9. The twice-baud-rate response of the PAM receiver 2 is supplied as input signal E to the slave phase-tracking circuit 1100. A one-sample digital delay 1101 in the phase-tracking circuitry 1110 delays the twice-baud-rate response of the PAM receiver 2 by one-half a symbol epoch to generate a signal F. The E and F signals are applied as input signals to interpolation filters 1102, 1103, 1104, 1105, 1106, 1107 and 1108. The E signal is applied as input signal to shim delay circuitry that supplies delayed E signal as an input signal to circuitry 1110 for selecting phase-tracker output signal. The delay in E signal introduced by the shim delay circuitry 1109 compensates for the latent delay in each of the interpolation filters 1102, 1103, 1104, 1105, 1106, 1107 and 1108. The shim delay circuitry 1109 response is additionally delayed one-half a symbol epoch by a one-sample digital delay 1111 and then is supplied as a further input signal to the circuitry 1110. The interpolation filter 1102 generates a 7E/8+F/8 response to the E and F signals, which response is supplied as a further input signal to the circuitry 1110. The interpolation filter 1102 response is delayed one-half a symbol epoch by a one-sample digital delay 1112 and then is supplied as a further input signal to the circuit 1110. The interpolation filter 1103 generates a 3E/4+F/4 response to the E and F signals, which response is supplied as a further input signal to the circuit with 1110. The interpolation filter 1103 response is delayed one-half a symbol epoch by a one-sample digital delay 1113 and then is supplied as a further input signal to the circuitry 1110. The interpolation filter 1104 generates a 5E/8+3F/8 response to the E and F signals, which response is supplied as a further input signal to the circuitry 1110. The interpolation filter 1104 response is delayed one-half a symbol epoch by a one-sample digital delay 1114 and then is supplied as a further input signal to the circuitry 1110. The interpolation filter 1105 generates a E/2+F/2 response to the E and F signals, which response is supplied as a further input signal to the circuitry 1110. The interpolation filter 1105 response is delayed one-half a symbol epoch by a one-sample digital delay 1115 and then is supplied as a further input signal to the circuitry 1110. The interpolation filter 1106 generates a 3E/8+5F/8 response to the E and F signals, which response is supplied as a further input signal to the circuitry 1110. The interpolation filter 1106 response is delayed one-half a symbol epoch by a one-sample digital delay 1116 and then is supplied as a further input signal to the circuitry 1110. The interpolation filter 1107 generates a E/4+3F/4 response to the C and D signals, which response is supplied as a further input signal to circuitry 1110. The interpolation filter 1107 response is delayed one-half a symbol epoch by a one-sample digital delay 1117 and then is supplied as a further input signal of the circuitry 1110. The interpolation filter 1108 generates a 7E/8+F/8 response to the E and F signals, which response is supplied as a further input signal to tie circuitry 1110. The interpolation filter 1108 response is delayed one-half a symbol epoch by a one-sample digital delay 1118 and then is supplied as a further input signal to the circuitry 1110.

The circuitry 1110 for selecting phase-tracker output signal receives sixteen input signals, each a different phased sampling of the twice-baud-rate response of the PAM receiver 2. These sixteen input signals are candidate phase-tracker responses. The circuitry 1110 comprises a tree of multiplexers for selecting the candidate phase-tracker response corresponding to the candidate phase-tracker response selected by the tree of multiplexers 531-538, 613, 623, 633, 643, 653, 663 and 672 in the circuitry 400 for selecting equalizer output signal. The tree of multiplexers in the circuitry 1110 are controlled by respective ones of the control bits furnished from the comparator 515-522, 611, 621, 631, 641, 651, 661 and 671 in the same way the tree of multiplexers 531-538, 613, 623, 633, 643, 653, 663 and 672 in the circuitry 400 are controlled by respective ones of these control bits. The candidate phase-tracer response that the circuitry 1110 selects as its phase-tracker output signal is supplied as input signal to the CIR circuitry extraction circuitry 12.

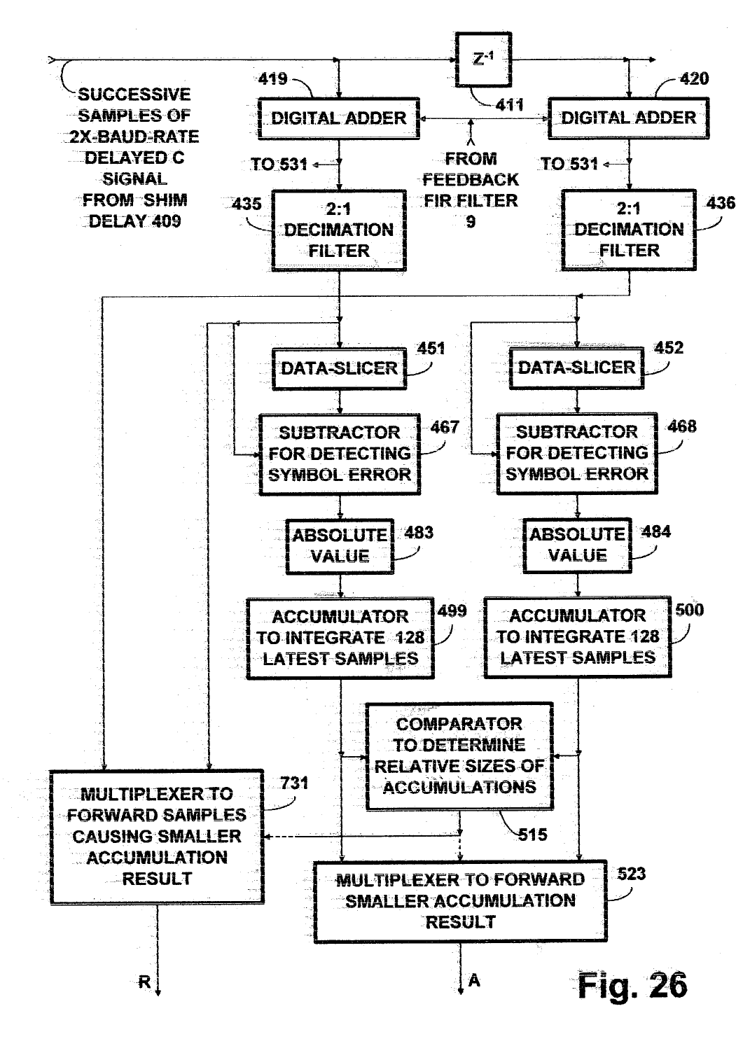

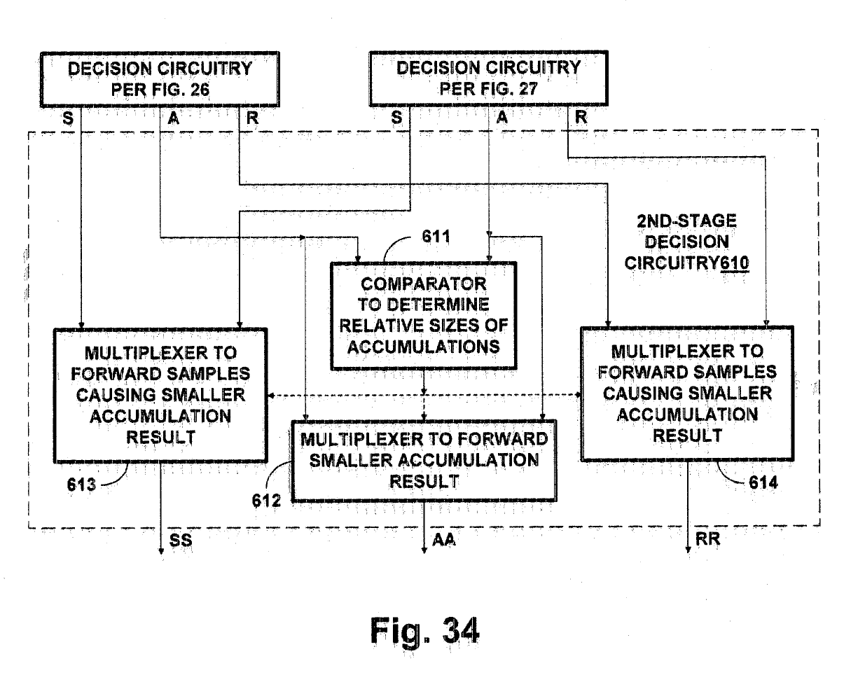

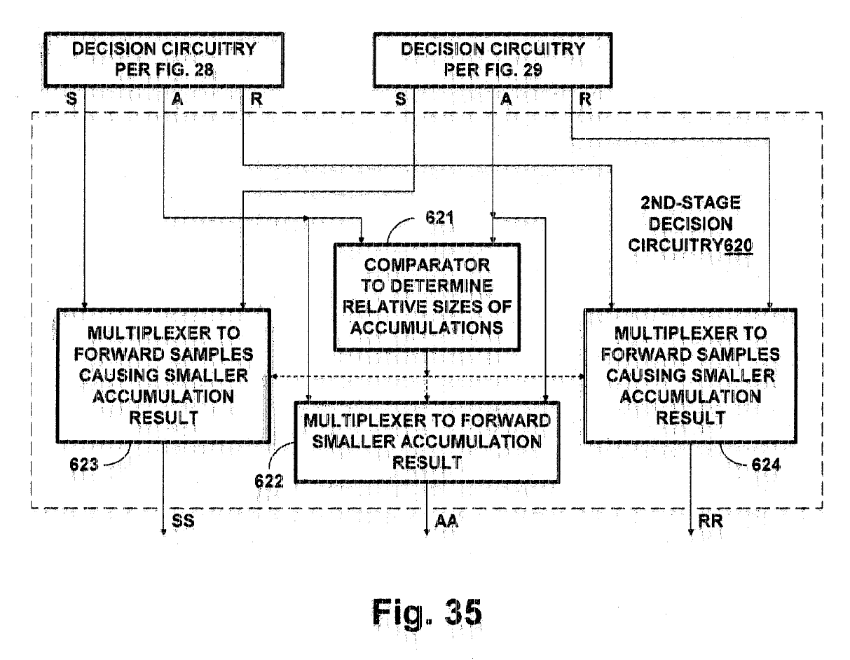

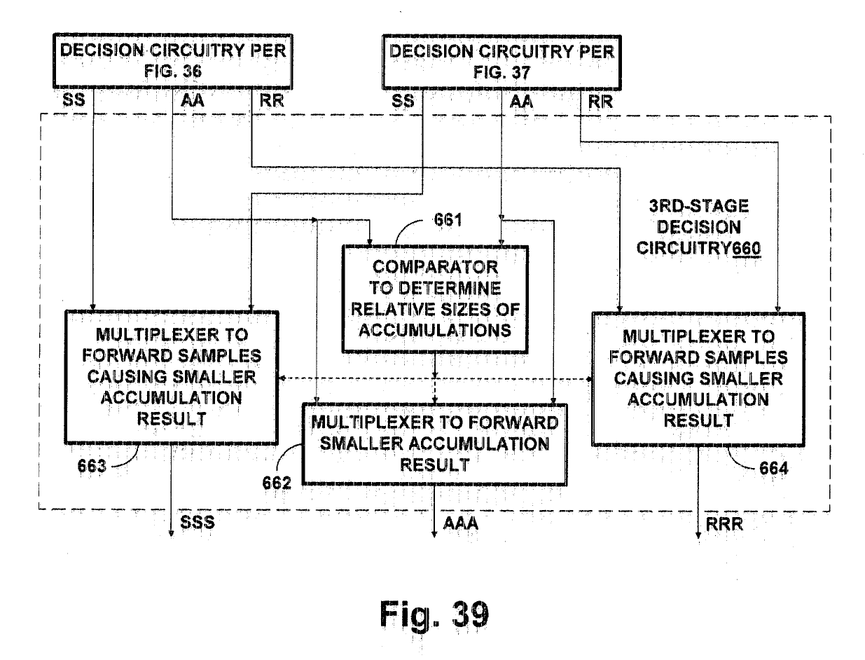

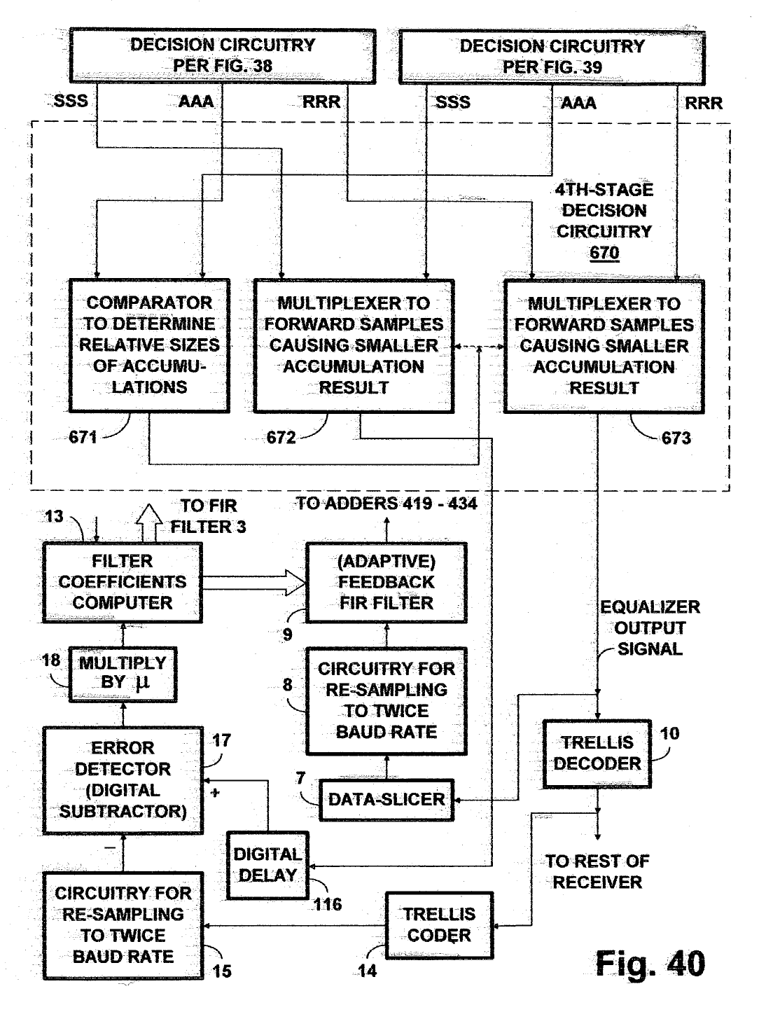

FIGS. 26 through 40 shown details of the selection circuitry that can also be included in the FIG. 9 phase-tracker modification of the FIG. 1 receiver. One of the sixteen candidate equalizer output signals sampled at baud rate that are supplied from the 2:1 decimation filters 435-450 is selected by this further selection circuitry for application as respective input signals to tie data-slicer 7 are to be trellis adder 10. Such selection of the baud-rate equalizer output signal avoids errors that can occur using the 2:1 decimation filter 6 to generate baud-rate equalizer output signal in response to the twice-baud-rate equalizer output signal supplied from the fourth-stage decision circuitry 67. The produced for selecting the baud-rate equalizer output signals also of tree type, beginning from the top with a first stage of reducing the sixteen trial responses to eight trial responses, using first-stage decision circuitry shown in FIGS. 26, 27, 28, 29, 30, 31, 32 and 33. This first stage of reducing the number of trial responses is followed by a second stage of reducing the eight trial responses to four trial responses, using apparatuses shown in FIGS. 34, 35, 36 and 37. This second stage of reducing the number of trial responses is followed by a third stage of reducing the four trial responses to two trial responses, using apparatuses shown in FIGS. 38 and 39. This third stage of reducing thee number of trial responses is followed by a four stage of reducing the two trial responses to a single final response, using apparatus shown in FIG. 40.

FIG. 26 shows modification of the FIG. 10 first-stage decision circuitry to further include a multiplexer 731 connected for receiving as its two input signals the first candidate equalizer output signal from the 2:1 decimation filter 435 and the second candidate equalizer output signal from the 2:1 decimation filter 436. The multiplexer 731 is connected for receiving a control bit from the comparator 515 as a control signal, which control bit determines which of the input signals to the multiplexer 731 shall be reproduced in the output signal R from the multiplexer 731. Responsive to the control bit from the comparator 515 being ZERO, the first candidate equalizer output signal from the 2:1 decimation filter 435 is reproduced in the multiplexer 731 output signal R. Responsive to the control bit from the comparator 515 being ONE, the second candidate equalizer output signal from the 2:1 decimation filter 436 is reproduced in the multiplexer 731 output signal R.

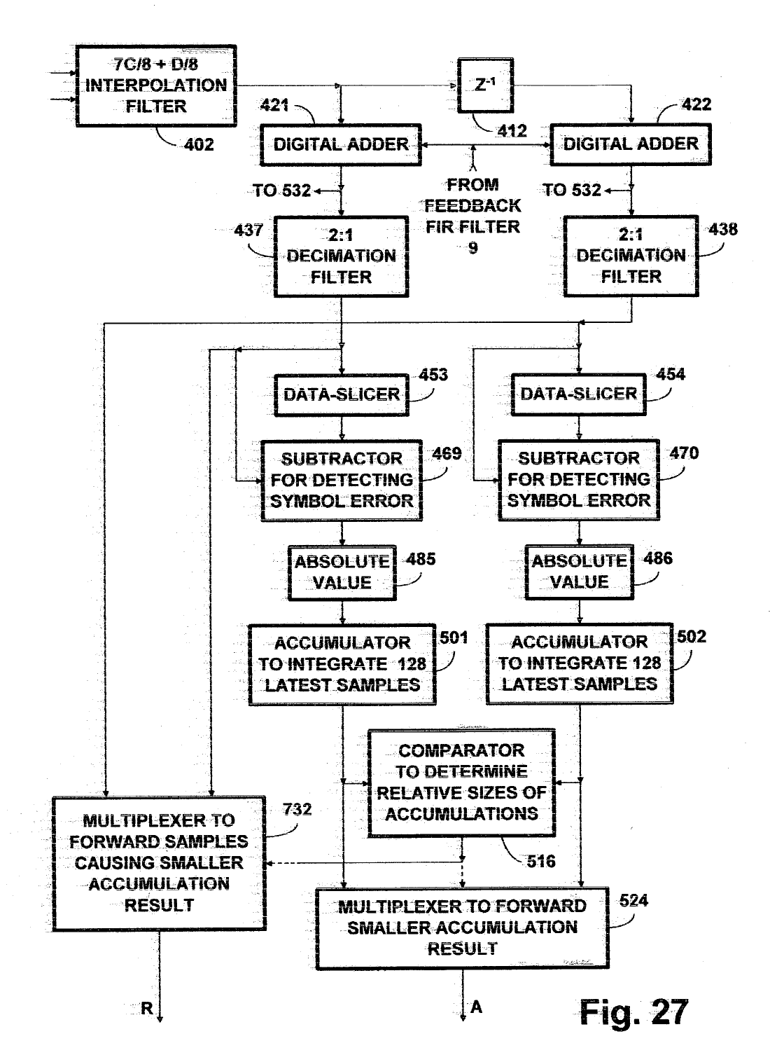

FIG. 27 shows modification of the FIG. 11 first-stage decision circuitry to further include a multiplexer 732 connected for receiving as its two input signals the third candidate equalizer output signal from the 2:1 decimation filter 437 and the fourth candidate equalizer output signal from the 2:1 decimation filter 439. The multiplexer 732 is connected for receiving a control bit from the comparator 516 as a control signal, which control bit determines which of the input signals to the multiplexer 732 shall be reproduced in the output signal R from the multiplexer 732. Responsive to the control bit from the comparator 516 being ZERO, the third candidate equalizer output signal from the 2:1 decimation filter 437 is reproduced in the multiplexer 732 output signal R. Responsive to the control bit from the comparator 516 being ONE, the fourth candidate equalizer output signal from the 2:1 decimation filter 438 is reproduced in the multiplexer 732 output signal R.

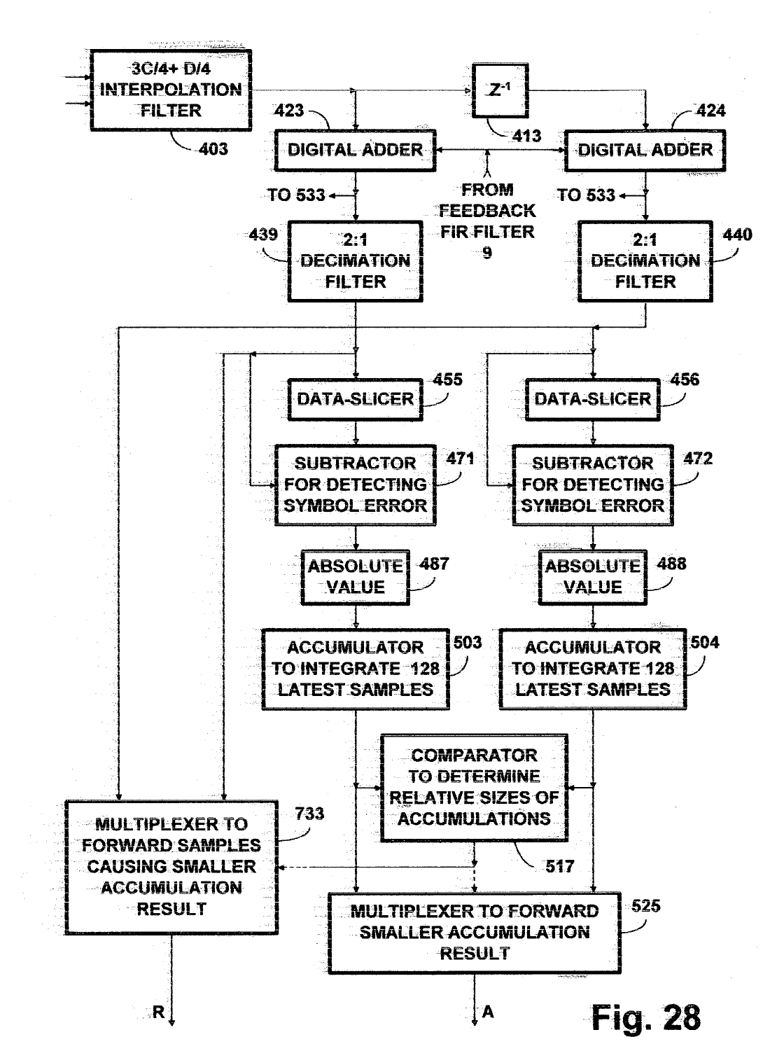

FIG. 28 shows modification of the FIG. 12 first-stage decision circuitry to further include a multiplexer 733 connected for receiving as it two input signals the fifth candidate equalizer output signal from the 2:1 decimation filter 439 and the sixth candidate equalizer output signal from the 2:1 decimation filter 440. The multiplexer 733 is connected for receiving a control bit from the comparator 517 as a control signal, which control bit determines which of the input signals to the multiplexer 733 shall be reproduced in the output signal R from the multiplexer 733. Responsive to the control bit from the comparator 517 being ZERO, the fifth candidate equalizer output signal from the 2:1 decimation filter 439 is reproduced in the multiplexer 733 output signal R. Responsive to the control bit from the comparator 517 being ONE, the sixth candidate equalizer output signal from the 2:1 decimation filter 440 is reproduced in the multiplexer 733 output signal R.

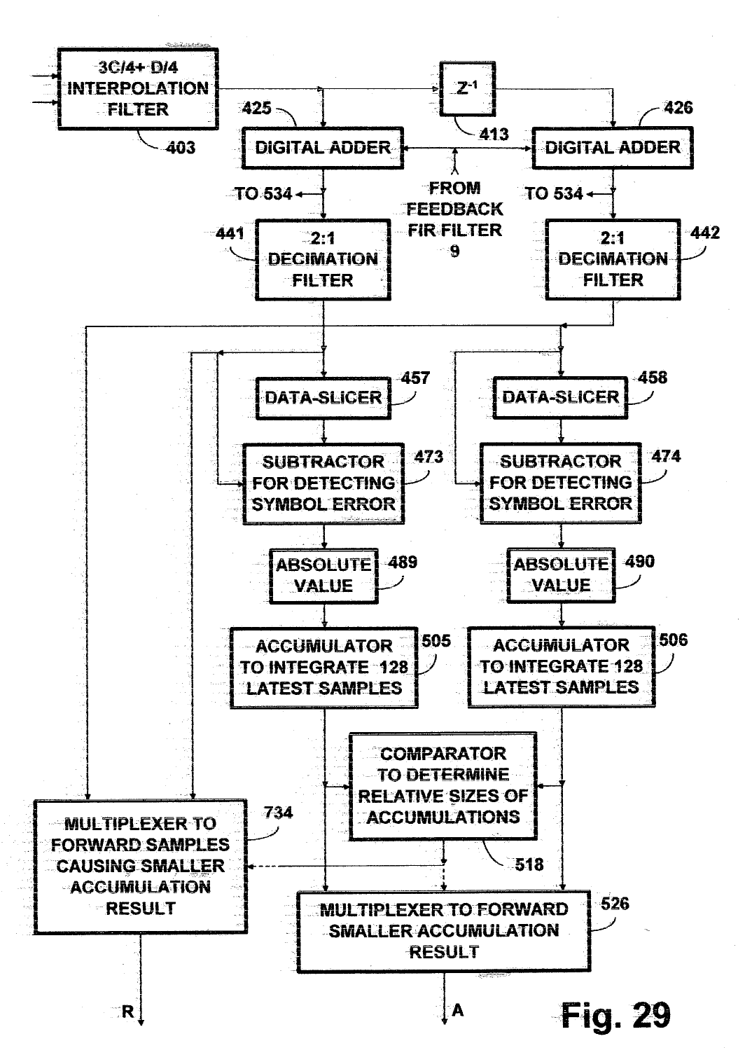

FIG. 29 shows modification of the FIG. 13 first-stage decision circuitry to further include a multiplexer 734 connected for receiving as its two input signals the seventh candidate equalizer output signal from the 2:1 decimation filter 441 and the eighth candidate equalizer output signal from the 2:1 decimation filter 442. The multiplexer 734 is connected for receiving a control bit from the comparator 518 as a control signal, which control bit determines which of the input signals to the multiplexer 734 shall be reproduced in the output signal from the multiplexer 734. Responsive to the control bit from the comparator 517 is being ZERO, the seventh candidate equalizer output signal from the 2:1 decimation filter 441 is reproduced in the multiplexer 734 output signal R. Responsive to the control bit from the comparator 518 being ONE, the eighth candidate equalizer output signal from the 2:1 decimation filter 442 is reproduced in the multiplexer 734 output signal R.

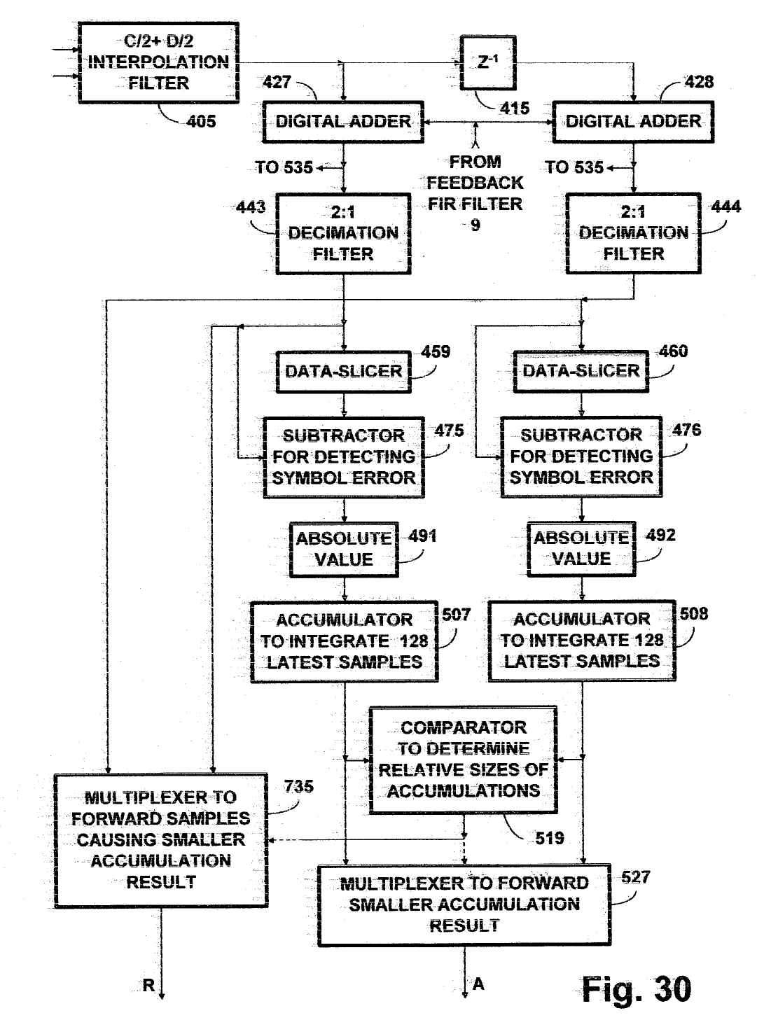

FIG. 30 shows modification of the FIG. 14 first-stage decision circuitry to further include a multiplexer 735 connected for receiving as its two input signals the ninth candidate equalizer output small from the 2:1 decimation filter 443 and the tenth candidate equalizer output signal from the 2:1 decimation filter 444. The multiplexer 735 is connected for receiving a control bit from the comparator 519 as a control signal, which control bit determines which of the input signals to the multiplexer 735 shall be reproduced in the output signal R from the multiplexer 735. Responsive to the control bit from the comparator 519 be in ZERO, the ninth candidate equalizer output signal from the 2:1 decimation filter 443 is reproduced in the multiplexer 735 output signal R. Responsive to the control bit from the comparator 519 being ONE, the tenth candidate equalizer output signal from the 2:1 decimation filter 444 is reproduced in the multiplexer 735 output signal R.

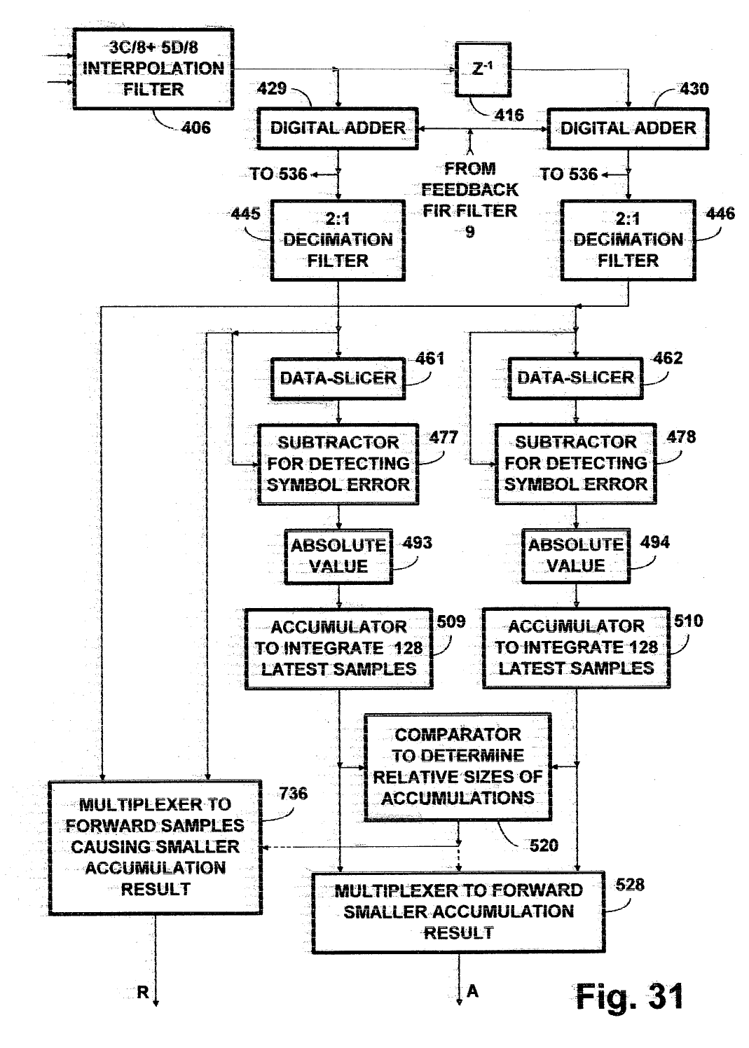

FIG. 31 shows modification of the FIG. 15 first-stage decision circuitry to further include a multiplexer 736 connected for receiving as its two input signals the eleventh candidate equalizer output signal from the 2:1 decimation filter 445 and the twelfth candidate equalizer output signal from the 2:1 decimation filter 446. The multiplexer 736 is connected for receiving a control bit from the comparator 520 as a control signal, which control bit determines which of the input signals to the multiplexer 736 shall be reproduced in the output signal R from the multiplexer 736. Responsive to the control bit from the comparator 520 being ZERO, the eleventh candidate equalizer output signal from the 2:1 decimation filter 445 is reproduced in the multiplexer 736 output signal R. Responsive to the control bit from the comparator 520 being ONE, the twelfth candidate equalizer output signal from the 2:1 decimation filter 446 is reproduced in the multiplexer 736 output signal R.

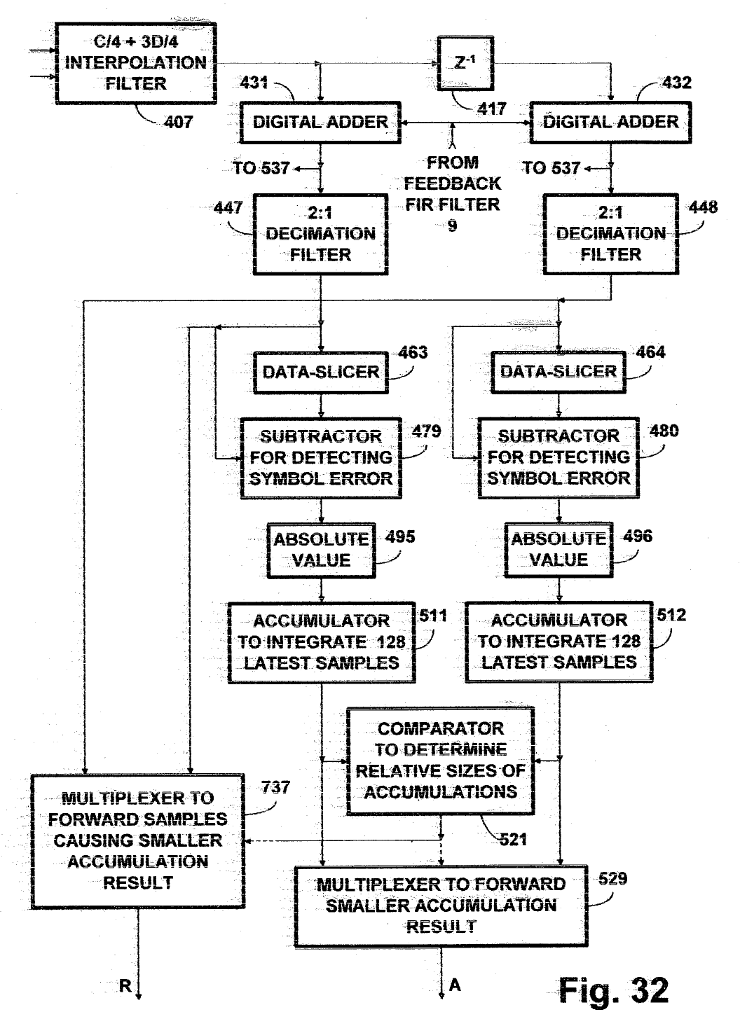

FIG. 32 shows modification of the FIG. 16 first-stage decision circuitry to further include a multiplexer 737 connected for receiving as its two input signals the thirteenth candidate equalizer output signal from the 2:1 decimation filter 447 and the fourteenth candidate equalizer output signal from the 2:1 decimation filter 448. The multiplexer 737 is connected for receiving a control bit from the comparator 521 as a control signal, which control bit determines which of the input signals to the multiplexer 737 shall be reproduced in the output signal R from the multiplexer 737. Responsive to the control bit from the comparator 521 being ZERO, the thirteenth candidate equalizer output signal from the 2:1 decimation further 447 is reproduced in the multiplexer 737 output signal R. Responsive to the control bit from the comparator 521 being ONE, the fourteenth candidate equalizer output signal from the 2:1 decimation 448 is reproduced in the multiplexer 737 output signal R.

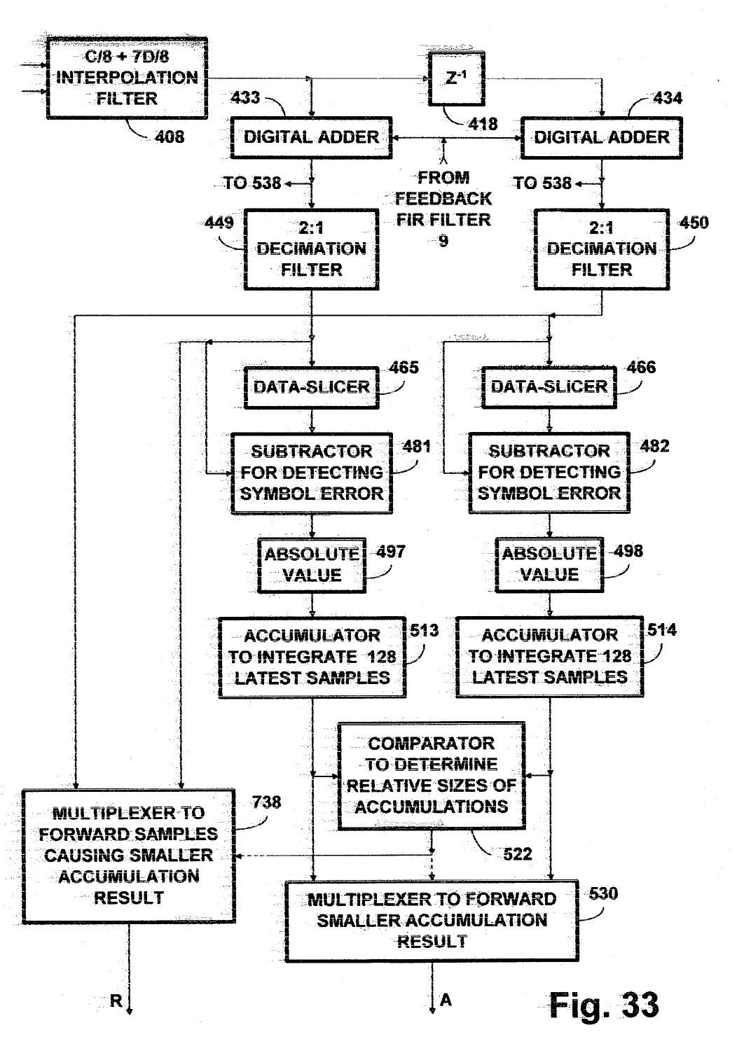

FIG. 33 shows modification of the FIG. 17 first-stage decision circuitry to further include a multiplexer 738 connected for receiving as its two input signals the fifteenth candidate equalizer output signal from the 2:1 decimation filter 449 and the sixteenth candidate equalizer output signal from the 2:1 decimation filter 450. The multiplexer 738 is connected for receiving a control bit from the comparator 522 as a control signal, which control bit determines which of the input signals to the multiplexer 738 shall be reproduced in the output signal R from the multiplexer 738. Responsive to the control bit from the comparator 522 being ZERO, the fifteenth candidate equalizer output signal from the 2:1 decimation filter 449 is reproduced in the multiplexer 738 output signal R. Responsive to the control bit from the comparator 522 being ONE, the sixteenth candidate equalizer output signal from the 2:1 decimation filter 450 is reproduced in the multiplexer 738 output signal R.

FIG. 34 shows second-stage decision circuitry 610 that is a modification of the FIG. 18 second-stage decision circuitry 61 to further include a multiplexer 643 connected for receiving as its two input signals the R output signals from the FIG. 26 first-stage decision circuitry and from the FIG. 26 first-stage decision circuitry. The multiplexer 613 is connected for receiving a control bit from the comparator 611 as a control signal, which control bit determines which of the input signals to the multiplexer 613 shall be reproduced in the output signal RR from the multiplexer 613. Responsive to the control bit from the comparator 611 being ZERO, the R output signal from the FIG. 26 first-stage decision circuitry is reproduced in the multiplexer 613 output signal RR. Responsive to the control bit from the comparator 611 being ONE, the R output signal from the FIG. 27 first-stage decision circuitry is reproduced in the multiplexer 613 output signal RR.

FIG. 35 shows second-stage decision circuitry 620 that is a modification of the FIG. 19 second-stage decision circuitry 62 to further include a multiplexer 623 connected for receiving as its two input signals the R output signals from the FIG. 28 first-stage decision circuitry and from the FIG. 29 first-stage decision circuitry. The multiplexer 623 is connected for receiving a control bit from the comparator 621 as a control signal, which control bit determines which of the input signals to the multiplexer 623 shall be reproduced in the output signal RR from the multiplexer 623. Responsive to the control bit from the comparator 621 being ZERO, the R output signal from the FIG. 28 first-stage decision circuitry is reproduced in the multiplexer 623 output signal RR. Responsive to the control hit from the comparator 621 being ONE, the R output signal from the FIG. 29 first-stage decision circuitry is reproduced in the multiplexer 623 output signal RR.

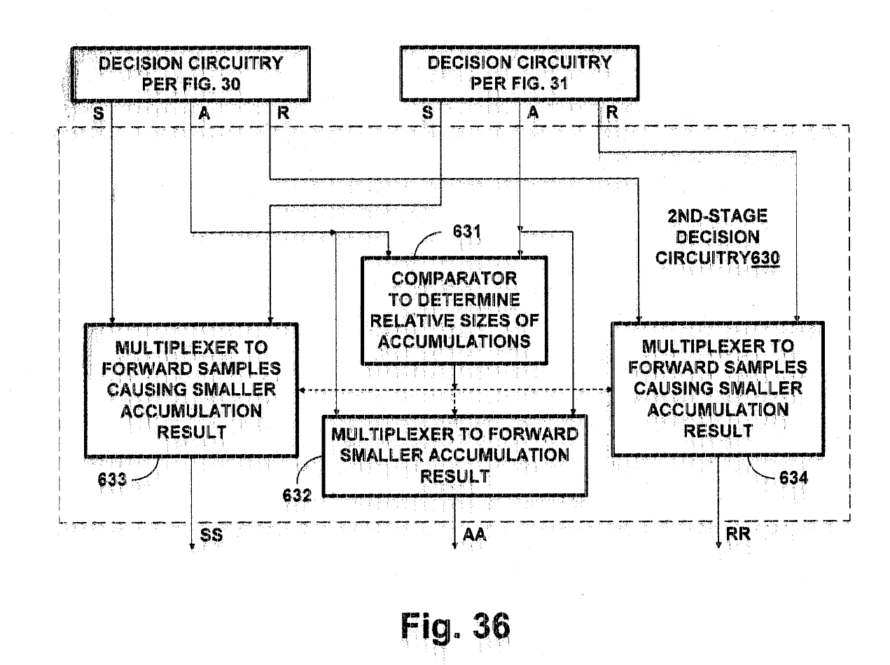

FIG. 36 shows second-stage decision circuitry 630 that is a modification of the FIG. 20 second-stage decision circuitry 63 to further include a multiplexer 633 connected for receiving as its two input signals the R output signals from the FIG. 30 first-stage decision circuitry and from the FIG. 31 first-stage decision circuitry. The multiplexer 633 is connected for receiving a control bit from the comparator 631 as a control signal, which control bit determines which of the input signals to the multiplexer 633 shall be reproduced in the output signal RR from the multiplexer 633. Responsive to the control bit from the comparator 631 being ZERO, the R output signal from the FIG. 30 first-stage decision circuitry is reproduced in the multiplexer 633 output signal RR. Responsive to the control bit from the comparator 631 being ONE, the R output signal from the FIG. 31 first-stage decision circuitry is reproduced in the multiplexer 633 output signal RR.

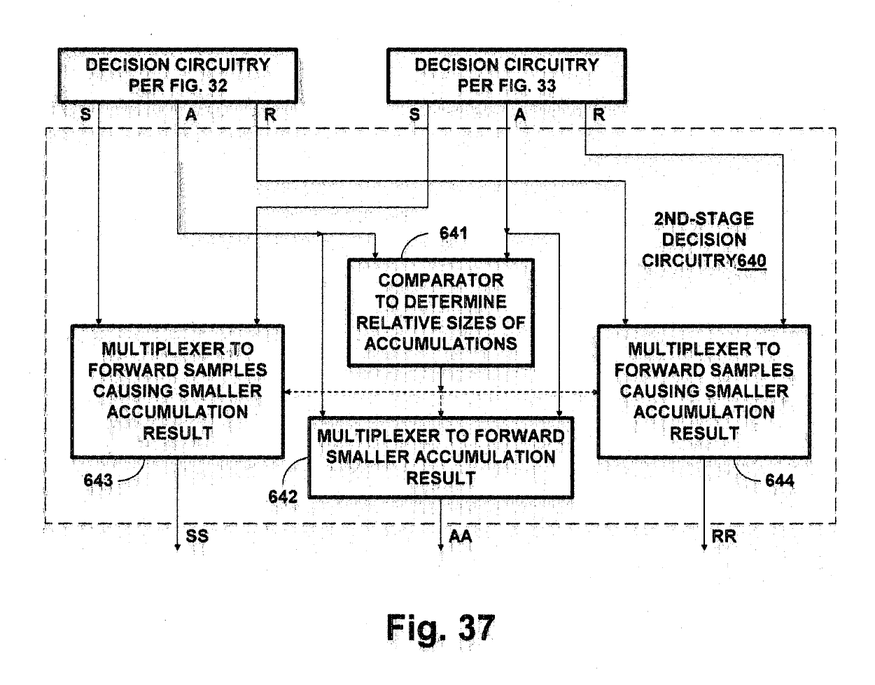

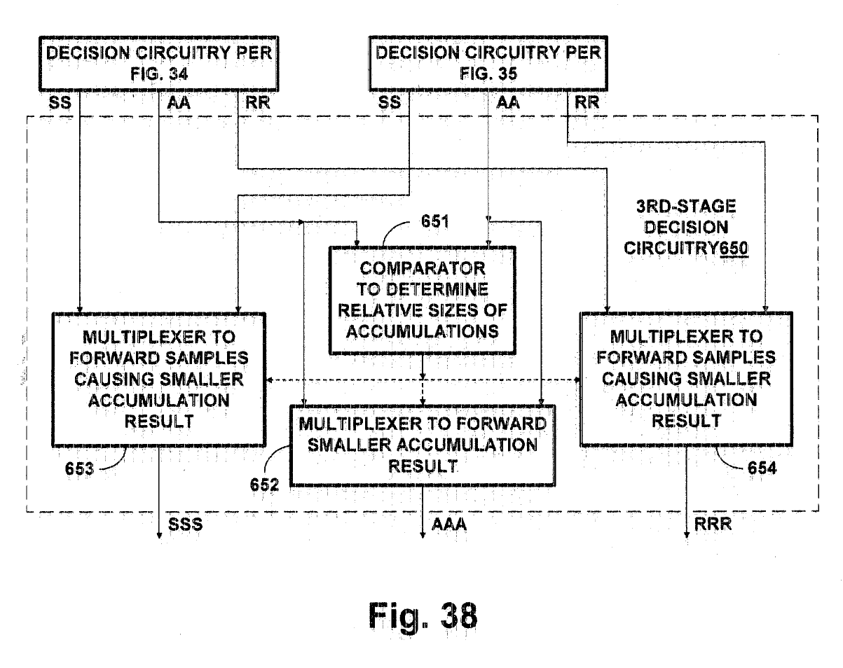

FIG. 37 shows second-stage decision circuitry 640 that is a modification of the FIG. 21 second-stage decision circuitry 64 to further include a multiplexer 643 connected for receiving as its two input signals the R output signals from the FIG. 32 first-stage decision circuitry and from the FIG. 33 first-stage decision circuitry. The multiplexer 643 is connected for receiving a control bit from the comparator 641 as a control signal, which control bit determines which of the input signals to the multiplexer 643 shall be reproduced in the output signal RR from the multiplexer 643. Responsive to the control bit from the comparator 641 being ZERO, the R output signal from the FIG. 32 first-stage decision circuitry is reproduced in the multiplexer 643 output signal RR. Responsive to the control bit from the comparator 641 being ONE, the R output signal from tie FIG. 33 first-stage decision circuitry is reproduced in the multiplexer 643 output signal RR.

FIG. 38 shows third-stage decision circuitry 650 that is a modification of the FIG. 22 third-stage decision circuitry 65 to further include a multiplexer 653 connected for receiving as its two input signals the RR output signals from the FIG. 34 second-stage decision circuitry and from the FIG. 35 second-stage decision circuitry. The multiplexer 653 is connected for receiving a control bit from the comparator 651 as a control signal, which control bit determines which of the input signals to the multiplexer 653 shall be reproduced in the output signal RRR from the multiplexer 653. Responsive to the control bit from the comparator 651 being ZERO, the RR output signal from the FIG. 34 second-stage decision circuitry is reproduced in the multiplexer 653 output signal RRR. Responsive to the control bit from the comparator 651 being ONE, the RR output signal from the FIG. 35 second-stage decision circuitry is reproduced in the multiplexer 653 output signal RRR.

FIG. 39 shows third-stage decision circuitry 660 that is a modification of the FIG. 23 third-stage decision circuitry 66 to further include a multiplexer 663 connected for receiving as its two input signals the RR output signals from the FIG. 36 second-stage decision circuitry and from the FIG. 37 second-stage decision circuitry. The multiplexer 663 is connected for receiving a control bit from the comparator 661 as a control signal, which control bit determines which of the input signals to the multiplexer 663 shall be reproduced in the output signal RRR from the multiplexer 663. Responsive tote control bit from the comparator 661 being ZERO, the RR output signal from the FIG. 36 second-stage decision circuitry is reproduced in the multiplexer 663 output signal RRR. Responsive to the control bit from the comparator 661 being ONE, the RR output signal from the FIG. 37 second-stage decision circuitry is reproduced in the multiplexer 663 output signal RRR.

FIG. 40 shows fourth-stage decision circuitry 670 that is a modification of the FIG. 24 fourth-stage decision circuitry 67 to further include a multiplexer 673 connected for receiving as its two input signals the RRR output signals from the FIG. 38 third-stage decision circuitry and from the FIG. 39 third-stage decision circuitry. The multiplexer 673 is connected for receiving a control bit from the comparator 671 as a control signal, which control bit determines which of the input signals to the multiplexer 673 shall be reproduced in its output signal. Responsive to the control bit from the comparator 671 being ZERO, the RRR output signal from the FIG. 38 third-stage decision circuitry is reproduced in the multiplexer 673 output signal. Responsive to the control bit from the comparator 671 being ONE, the RRR output signal from the FIG. 39 third-stage decision circuitry is reproduced in the multiplexer 673 output signal. The multiplexer 73 output signal is the baud-rate equalizer output signal selected for application to the data-slicer 7 as its input signal and to the trellis decoder 10 as its input signal.

The data-slicers 451-466 are “simple” data slicers, so they will not be subject to the generation of running errors that would distort the histogram contents of the accumulators 499-514. Selecting one of the data-slices 451-466 to be decision-feedback signal, rather than using the data-slicer 7 to generate decision-feedback signal, is possible. However, it is preferable to generate decision-feedback signal using the data-slicer 7 with the data-slicer 7 including a “smart” data-slicer 44 as well as a “simple” data-slicer 07. This is because such a data-slicer 7 makes fewer mistakes in data-slicing than just a “simple” data-slicer does.

In the claims which follow, the term “digital adder” is to be interpreted as a generic term that comprises apparatus for subtracting a subtrahend input digital signal from a minuend input digital signal to generate a difference output digital signal.

1. In combination:
a receiver for supplying digital samples of a baseband demodulation response to the pulse amplitude modulation of said selected radio-frequency carrier, which pulse amplitude modulation provides symbol coding of digital data;
first adaptive digital filtering with adjustable weighting coefficients, connected for receiving said baseband demodulation response as its input signal and for supplying its response to said baseband demodulation response;
second adaptive digital filtering with adjustable weighting coefficients, connected for receiving a feedback signal as its input signal and for supplying its response to said feedback signal;
apparatus for adjusting the sampling of the response of said first adaptive digital filtering to generate an adjusted first adaptive digital filtering response providing for minimal intersymbol interference in an equalizer response to said baseband demodulation response;
apparatus for combining the adjusted first adaptive digital filtering response with the second adaptive digital filtering response to generate said equalizer response to said baseband demodulation response;
apparatus for adapting the adjustable weighting coefficients of said first adaptive digital filtering and said second adaptive digital filtering to equalize symbol coding in said equalizer response; and
circuitry for deriving said feedback signal from said equalizer response.

2. The combination set forth in claim 1, further comprising:
apparatus for adjusting the sampling of the baseband demodulation response to generate an adjusted baseband demodulation response, said apparatus for adjusting the sampling of the baseband demodulation response making its adjustment of the sampling of the base band demodulation response similarly to the adjustment of the sampling of the response of said first adaptive digital filtering made by said apparatus for adjusting the sampling of the response of said first adaptive digital filtering; and
CIR extraction circuitry connected for extracting information concerning channel impulse response (CIR) from said adjusted baseband demodulation response.

3. The combination set forth in claim 1, wherein said circuitry for deriving said feedback signal from said equalizer response comprises:
apparatus for data-slicing said equalizer response as sampled to the baud rate of said pulse amplitude modulation, thereby to generate a decision-feedback signal which is sampled to the clock rate of said second adaptive digital filtering and used as part of the feedback signal applied to said second adaptive digital filtering as its input signal.

4. The combination set forth in claim 2, wherein said circuitry for deriving said feedback signal from said equalizer response comprises:
a simple data-slicer connected for data-slicing said equalizer response as sampled to the baud rate of said pulse amplitude modulation and thereby generating a simple-data slicer response;
a smart data slicer connected for data-slicing said equalizer response as sampled to the baud rate of said pulse amplitude modulation and thereby generating a smart-data-slicer response;
a burst error detector connected for comparing said smart-data-slicer response and said simple-data-slicers response to detect the occurrence of burst error in said smart data-slicer response;
a data-slicing results selector connected for reproducing said simple-data-slicer response as its selection result only when said burst error detector detects the occurrence of burst error in said smart data-slicer response and for selecting said smart-data-slicer response as its selection result when said burst error detector does not detect the occurrence of burst error in said smart data-slicer response; and
a feedback selector for selecting at appropriate times synchronizing signal symbols as said feedback signal and for selecting at other times the selection result from said data-slicing results selector as said feedback signal.

5. The combination set forth in claim 2, wherein said circuitry for deriving said feedback signal from said equalizer response comprises:
a simple data-slicer connected for data-slicing said equalizer response as sampled to the baud rate of said pulse amplitude modulation and thereby generating a simple-data-slicer response;
a smart data slicer connected for data-slicing said equalizer response as sampled to the baud rate of said pulse amplitude modulation and thereby generating a smart-data-slicer response;
a burst error detector connected for comparing said smart-data-slicer response and said simple-data-slicer response to detect the occurrence of burst error in said smart-data-slicer response;
a decision- or linear-feedback selector connected for reproducing said equalizer response as sampled to the baud rate of said pulse amplitude modulation as its selection result only when said burst error detector detects the occurrence of burst error in said smart-data-slicer response and for reproducing said smart-data-slicer response as its selection result when said burst error detector does not detect the occurrence of burst error in said smart data-slicer response; and
a feedback selector for selecting at appropriate times synchronizing signal symbols as said feedback signal and for selecting at other times the selection result from said decision- or linear-feedback selector as said feedback signal.

6. In combination:
a receiver for supplying digital samples of a first baseband signal descriptive of the pulse amplitude modulation of a selected radio-frequency carrier, which pulse amplitude modulation provides symbol coding of digital data;
first adaptive digital filtering with adjustable weighting coefficients, connected for receiving said digital samples of said first baseband signal as its input signal, and connected for supplying digital samples of a second baseband signal as its response to said first baseband signal;
a first digital adder for combining digital samples of a third baseband signal with digital samples of a fourth baseband signal, to generate digital samples of a fifth baseband signal;
a data-slicer for quantizing baud-rate digital samples of said fifth baseband signal to generate a sixth baseband signal;
second adaptive digital filtering with adjustable weighting coefficients, connected for receiving as its input signal digital samples of said fifth baseband signal, and connected for supplying the digital samples of said third baseband signal as its response to said sixth baseband signal;
apparatus for adapting the adjustable weighting coefficients of said first adaptive digital filtering and said second adaptive digital filtering to equalize symbol coding of said fifth baseband signal;
circuitry for reproducing said digital data from said fifth baseband-signal; and
a first phase-tracker, connected for receiving as is input signal said second baseband signal supplied as the response of said first adaptive digital filtering, and connected for supplying digital samples of said fourth baseband signal as re-sampled response of said second baseband signal, the phasing of the re-sampling of said second baseband signal by said first phase-tracker being controlled so as to reduce intersymbol interference in the symbol coding of said fifth baseband signal.

7. The combination set forth in claim 6, further comprising:
a second phase-tracker, connected for receiving as its input signal said first baseband signal supplied as input signal to said first adaptive digital filtering, and connected for supplying digital samples of a seventh baseband signal as re-sampled response of said first baseband signal the phasing of the re-sampling of said first baseband signal by said second phase-trackers being controlled to correspond to the phasing of the re-sampling of said second baseband signal by said first phase-tracker; and
CIR extraction circuitry for extracting information concerning channel impulse response (CIR) from said seventh baseband signal, said CIR extraction circuitry connected for receiving as its input signal said digital samples of said seventh baseband signal supplied from said second phase-tracker.

8. The combination set forth in claim 7; wherein said receiver is constructed for supplying said digital samples of said first baseband signal at a double baud rate twice the baud rate of said pulse amplitude modulation, as a demodulation response to the pulse amplitude modulation of said selected radio frequency carrier; wherein said first adaptive digital filtering is connected for responding to said digital samples of said first baseband signal received as its input signal to supply the digital samples of said second baseband signal at said double baud rate; wherein said second adaptive digital filtering is connected for responding to said digital samples of said sixth baseband signal received as its input signal at said double baud rate to supply the digital samples of said third baseband signal at said double baud rate; wherein said first phase-tracker is constructed for supplying said digital samples of said fourth baseband signal at said double baud rate; and wherein said first digital adder is connected for combining the digital samples of said third baseband signal supplied at said double baud rate with the digital samples of said fourth baseband signal supplied at said double baud rate to generate digital samples of said fifth baseband signal at said double baud rate; said combination further comprising:
a first 2:1 decimation filter for decimating said digital samples of said fifth baseband signal received at said double baud rate to generate a decimated fifth baseband signal at the baud rate of said pulse amplitude modulation, said first 2:1 decimation filter connected for supplying said eliminated fifth baseband signal to said data-slicer as input signal thereto; and
circuit for re-sampling said sixth baseband signal to said double baud rate for application to said second adaptive digital filtering as input signal thereto.

9. The combination of claim 8, wherein said first adaptive digital filtering is connected for responding to real-only said first baseband signal to supply real-only said second baseband signal, and wherein said first phase-tracker comprises:
a first phase-splitter connected for converting said real-only second baseband signal to a complex eighth baseband signal with respective real and imaginary components;
a first error detector for measuring the departures of digital samples of said fifth baseband signal from corresponding digital samples of said sixth baseband signal;
apparatus for averaging the departures measured-by said error detector over time and scaling the average to generate a direct-component error signal;
a second digital adder connected to combine the real component of said complex eighth baseband signal with said direct-component error signal, for generating a complex ninth baseband signal having a real component without substantial zero-frequency content and having an imaginary component corresponding to the imaginary component of said complex eighth baseband signal;
a source of complex tenth baseband signal with respective real and imaginary components the vector sum of which would be a constant-amplitude signal with the phase thereof being determined by a phase-control signal;
a first digital complex multiplier connected for receiving said complex ninth baseband signal as a multiplicand input signal, for receiving said complex tenth baseband signal as a multiplier input signal, and for supplying a complex eleventh baseband signal as a product output signal, said complex eleventh baseband signal having a real component supplied to said first digital ladder as said fourth baseband signal and having an imaginary component;
first digital delay circuitry connected for delaying the imaginary component of said complex eleventh baseband signal;
a Hilbert filter connected for generating a Hilbert response to said third baseband signal;
a third digital adder connected for combining the Hilbert response to said third baseband signal with the imaginary component of said complex eleventh baseband signal, as delayed by said first digital delay circuitry, to generate digital samples of a third digital adder sum output signal;
a second 2:1 decimation filter connected for responding to said digital samples of said third digital adder sum output signal to generate digital samples of an output signal from said second 2:1 decimation filter supplied at the baud rate of said pulse amplitude modulation;
a second data-slicer for quantizing baud-rate digital samples of said output signal from said second 2:1 decimation filter to generate an output signal from said second data-slicer;
a second error detector for measuring the departures of digital samples of the input signal of said second data-slicer from corresponding digital samples of the output signal of said second data-slicer;
second digital delay circuitry connected for delaying the departures of digital samples of said fifth baseband signal from corresponding digital samples of said sixth baseband signal measured by said first error detector, so they align temporally with the departures of digital samples of the input signal of said second data-slicer from corresponding digital samples of the output signal of said second data-slicer measured by said second error detector;
read-only memory storing phase-error look-up tables, said read-only memory partially addressed by the departures of digital samples of the input signal of said second data-slicer from corresponding digital samples of the output signal of said second data-slicer measured by said second error detector,
said read-only memory partially addressed by the departures of digital samples of said fifth baseband signal from corresponding digital samples of said sixth baseband signal measured by said first error detector and delayed by said second digital delay circuitry;
a phase-tracker loop filter connected for lowpass filtering the phase errors read from said read-only memory to generate a phase-tracker loop filter response; and
an accumulator for integrating said phase-tracker loop filter response to generate said phase-control signal.

10. The combination of claim 9, wherein said second phase tracker comprises:
a second phase-splitter connected for converting said real-only first baseband signal to a complex twelfth baseband signal with respective real amid imaginary components; and
a half a digital complex multiplier connected for receiving said complex twelfth baseband signal as a multiplicand input signal for receiving said complex tenth baseband signal as a multiplexer input signal, and for supplying a real-only product output signal as said seventh baseband signal applied as input signal to said CIR extraction circuitry.

11. The combination of claim 8, wherein said first adaptive digital filtering is connected for responding to complex said first baseband signal to supply complex said second baseband signal, and wherein said first phase-tracker comprises:
a first error detector for measure the departures of digital samples of said fifth baseband signal from corresponding digital samples of said sixth baseband signal;
apparatus for averaging tie departures measured by said error detector over time and scaling the average to generate a direct component error signal;
a second digital adder connected to combine the real component of said complex second baseband signal with said direct-component error signal, for generating a complex eighth baseband signal having a real component without substantial zero-frequency content and having an imaginary component corresponding to the imaginary component of said complex second baseband signal;
a source of complex ninth baseband signal with respective real and imaginary components the vector sum of which would be a constant-amplitude signal with the phase thereof being determined by a phase-control signal;
a first digital complex multiplier connected for receiving said complex eighth baseband signal as a multiplicand input signal for receiving said complex ninth baseband signal as a multiplier input signal, and for supplying a complex tenth baseband signal as a product output signal, said complex tenth baseband signal hating a real component supplied to said fist digital adder as said fourth baseband signal and having an imaginary component;
first digital delay circuitry connected for delaying the imaginary component of said complex tenth baseband signal;
a Hilbert filter connected for generating a Hilbert response to said third baseband signal;
a third digital adder connected for combining the Hilbert response to said third baseband signal with the imaginary component of said complex tenth baseband signal, as delayed by said first digital delay circuitry, to generate digital samples of a sum output signal sampled from said third digital adder;
a second 2:1 decimation filter connected for responding to said digital samples of said sum output signal supplied from said third digital adder to generate digital samples of an output signal from said second 2:1 decimation filter supplied at the baud rate of said pulse amplitude modulation;
a second data-slicer for quantizing baud-rate digital samples of said output signal from said second 2:1 decimation filter to generate an output signal from said second data-slicer;
a second error detector for measuring the departures of digital samples of the input signal of said second data-slicer from corresponding digital samples of the output signal of said second data-slicer;
second digital delay circuitry connected for delaying the departures of digital samples of said fifth baseband signal from corresponding digital samples of said sixth baseband signal measured by said first error detector, so they align temporally with the departures of digital samples of the input signal of said second data-slicer from corresponding digital samples of the output signal of said second data-slicer measured by said second error detector;
read-only memory storing phase-error look-up tables, said read-only memory partially addressed by the departures of digital samples of the input signal of said second data-slicer from corresponding digital samples of the output signal of said second data-slicer measured by said second error detector,
said read-only memory partially addressed by the departures of digital samples of said fifth baseband signal from corresponding digital samples of said sixth base band signal measured by said first error detector and delayed by said second digital delay circuitry;
a phase-tracker loop filter connected for lowpass filtering the phase errors read from said read-only memory to generate a phase-tracker loop filter response; and
an accumulator for integrating said phase-tracker loop filter response to generate said phase-control signal

12. The combination of claim 11, wherein said second phase tracker comprises:
a half a digital complex multiplier connected for receiving said complex first baseband signal as a multiplicand input signal, for receiving said complex ninth baseband signal as a multiplier input signal, and for supplying a real-only product output signal as said seventh baseband signal applied as input signal to said CIR extraction circuitry.

13. The combination of claim 7; wherein said receiver is constructed for supplying said digital samples of complex said first baseband signal at the baud rate of said pulse amplitude modulation, as a demodulation response to the pulse amplitude modulation of said selected radio-frequency carrier; wherein said first adaptive digital filtering is connected for responding to said digital samples of said complex first baseband signal received as its input signal to supply the digital samples of said complex second baseband signal at said baud rate; wherein said second adaptive digital filtering is connected for responding to said digital samples of said sixth baseband signal received as its input signal at said baud rate to supply the digital samples of said third baseband signal at said baud rate; wherein said first adaptive digital filtering is connected for responding to digital samples of complex said first baseband signals the baud rate of said pulse amplitudes modulation to supply digital samples of complex said second baseband signal, and wherein said first phase-tracker comprises:
a first error detector for measuring the departures of digital samples of said fifth baseband signal from corresponding digital samples of said sixth baseband signal;
apparatus for averaging the departures measured by said error detector over time and scaling the average to generate a direct component error signal;
a second digital adder connected to combine the real component of said complex second baseband signal with said direct-component error signal, for generating a complex eighth baseband signal having a real component without substantial zero-frequency content and having an imaginary component corresponding to the imaginary component of said complex second baseband signal;
a source of complex ninth baseband signal with respective real and imaginary components the vector sum of which would be a constant-amplitude signal and the phase of which is determined by a phase-control signal;
a first digital complex multiplier connected for receiving said complex eighth baseband signal as a multiplicand input signal, for receiving said complex ninth baseband signal as a multiplier input signal, and for supplying a complex tenth baseband signal as a product output signal, said complex tenth baseband signal having a real component supplied to said first digital adder as said fourth baseband signal and having an imaginary component;
first digital delay circuitry connected for delaying the imaginary component of said complex tenth baseband signal;
a Hilbert filter connected for generating a Hilbert response to said third baseband signal;
a third digital adder connected for combining the Hilbert response to said third baseband signal with the imaginary component of said complex tenth baseband signal, as delayed by said first digital delay circuitry, to generate digital samples of a sum output signal from said third digital adder;
a second data-slicer for quantizing baud-rate digital samples of said sum output signal from said third digital adder to generate an output signal from said second data-slicer;
a second error detector for measuring the departures of digital samples of the input signal of said second data-slicer from corresponding, digital samples of the output signal of said second data-slicer;
second digital delay circuitry connected for delaying the departures of digital samples of said fifth baseband signal from corresponding digital samples of said sixth baseband signal measured by said first error detector, so they align temporally with the departures of digital samples of the input signal of said second data-slicer from corresponding digital samples of the output signal of said second data-slicer measured by said second error detector;
read-only memory storing phase-error look-up tables, said read-only memory partially addressed by the departures of digital samples of the input signal of said second data-slicer from corresponding digital samples of the output signal of said second data-slicer measured by said second error detector, said read-only memory partially addressed by the departures of digital samples of said fifth baseband signal from corresponding digital samples of said sixth baseband signal measured by said first error detector and delayed by said second digital delay circuitry;
a phase-tracker loop filter connected for lowpass filtering the phase errors read from said read-only memory to generate a phase-tracker loop filter response; and
an accumulator for integrating said phase-tracker loop filter response to generate said phase-control signal.

14. The combination of claim 13, wherein said second phase-tracker comprises:
a half a digital complex multiplier connected for receiving said complex first baseband signal as a multiplicand input signal, for receiving said complex ninth baseband signal as a multiplier input signal, and for supplying a real-only product output signal as said seventh baseband signal applied as input signal to said CIR extraction circuitry.

15. In combination:
a receiver for supplying digital samples of a baseband demodulation response to the pulse amplitude modulation of said selected radio-frequency carrier, which pulse amplitude modulation provides symbol coding of digital data, said digital samples of said baseband demodulation response being supplied at a double baud rate that is twice the baud rate of said pulse amplitude modulation;
first adaptive digital filtering with adjustable weighting coefficients, connected for receiving said baseband demodulation response as its input signal, and connected for supplying at said double baud rate digital samples of its response to said baseband demodulation response;
apparatus for re-sampling the response of said first adaptive digital filtering with a plurality P of different sampling phases to generate P respective re-sampled first adaptive digital filtering responses each sampled at said double baud rate, P-being a positive integer greater than one;
circuitry for re-sampling a to said double baud rate a decision-feedback signal generated at the baud rate of said pulse amplitude modulation, thereby to generate a re-sampled decision-feedback signal;
second adaptive digital filtering with adjustable weighting coefficients, connected for receiving a re-sampled decision-feedback signal as its input signal, and connected for supplying at said double baud rate digital samples of its response to said re-sampled decision-feedback signal;
a plurality P in number of digital adders originally numbered first through P^{th}, each connected for receiving said second adaptive digital filtering response as one of its summand input signals, each connected for receiving a respective one of said P re-sampled first adaptive digital filtering responses as another of its summand input signals, and each connected for supplying at said double baud rate digital samples of a respective sum output signal;
a plurality P in number of 2:1 decimation filters originally numbered first through P^{th}, each connected for receiving the sum output signal of the digital adder with corresponding ordinal number and for supplying a respective decimation response to that sum output signal;
a plurality P in number of data-slicers ordinary numbered first through P^{th}, each data-slicer connected for receiving as its respective input signal the decimation response of said 2:1 decimation filter with corresponding ordinal number and for quantizing that decimation response to generate a respective output signal for that said data-slicer;
a plurality P in number of error detectors ordinary numbered first through P^{th}, each error detector connected for measuring how much the input and output signals of said data-slicer with corresponding ordinal number depart from each other and for supplying the absolute value of the resulting measurement as a respective output signal for that said error detector;
a plurality P in number of accumulators ordinally numbered first through P^{th}, each connected for accumulating over a prescribed period of time the respective output signal of said error detector with corresponding ordinal number and for supplying the accumulation result;
apparatus for adapting the adjustable weighting coefficients of said first adaptive digital filtering and said second adaptive digital filtering to equalize symbol coding of an equalizer output signal selected from the respective sum output signals of said plurality of digital adders ordinally numbered first through P^{th};
comparison circuitry for determining by comparison which of the accumulators ordinally numbered first through P^{th} supplies the smallest accumulation result;
first selection circuitry for reproducing the respective sum output signal of a selected one of said digital adders ordinally numbered first through P^{th}, the selected one of said digital adders ordinally numbered first through P^{th} having the same ordinal number as said accumulator determined by said comparison circuitry to supply the smallest accumulation result, the sum output signal reproduced by said first selection circuitry providing said equalizer output signal as sampled at said double baud rate;
apparatus for generating a decision-feedback signal as its response to said equalizer output signal;
circuitry for re-sampling said decision-feedback signal to said double baud rate to generate said re-sampled decision-feedback signal supplied to said second adaptive digital filtering as the input signal thereof.

16. The combination of claim 15, wherein said apparatus for generating a decision-feedback signal comprises:
a (P+1)^{th} 2:1 decimation filter connected for receiving said equalizer output signal sampled at said double baud rate and for supplying as its decimation response said equalizer output signal re-sampled to the baud rate of said pulse amplitude modulation; and
a (P+1)^{th} data-slicer connected for receiving as its input signal the decimation response of said (P+1)^{th} 2:1 decimation filter and for supplying a decision-feedback signal as its response to its said input signal.

17. The combination of claim 15, wherein, wherein said apparatus for generating a decision-feedback signal comprises:
second selection circuitry for reproducing the respective decimation response of a selected one of said 2:1 decimation filters ordinally numbered first through P^{th}, the selected one of said 2:1 decimation filters ordinally numbered first through P^{th} having the same original number as said accumulator determined by said comparison circuitry to supply the smallest accumulation results the decimation response reproduced by said second selection circuitry providing said equalizer output signal as sampled at the baud rate of said pulse amplitude modulation; and
a (P+1)^{th} data-slicer connected for receiving as its input signal the decimation response of said selected one of said 2:1 decimation filters ordinally numbered first through P^{th} and for supplying a decision-feedback signal as its response to its said input signal.
